(19) United States
(12) Patent Application Publication
(10) Pub. No.: US 2023/0024469 A1
(43) Pub. Date: Jan. 26, 2023

(54) SEMICONDUCTOR DEVICE, ELECTRONIC APPARATUS, AND METHOD FOR MANUFACTURING SEMICONDUCTOR DEVICE

(71) Applicant: SONY SEMICONDUCTOR SOLUTIONS CORPORATION, KANAGAWA (JP)

(72) Inventors: MASAKI IWAMOTO, KUMAMOTO (JP); KOUHEI SONODA, KUMAMOTO (JP)

(21) Appl. No.: 17/642,891

(22) PCT Filed: Jul. 6, 2020
(86) PCT No.: PCT/JP2020/026363

§ 371 Date: Mar. 14, 2022

(30) Foreign Application Priority Data
Sep. 20, 2019 (JP) 2019-171510

(51) Int. Cl. H01L 27/146; G03F 9/00; H01L 23/544; H01L 21/66

(52) U.S. Cl. CPC H01L 27/14636; G03F 9/7076; G03F 9/7084; H01L 23/544; H01L 27/14621; H01L 22/20; H01L 27/14685; H01L 2223/54426

(57) ABSTRACT

A semiconductor device capable of improving the quality of a pixel region, an electronic apparatus including the semiconductor device, and a method for manufacturing the semiconductor device are to be provided. The present technology provides a semiconductor device that includes: a first substrate in which a pixel region including a pixel having a photoelectric conversion unit is formed; and a second substrate in which a logic circuit that processes a signal output from the pixel region is formed, the first substrate and the second substrate being stacked. In the semiconductor device, at least one of marks including a mark to be used in an exposure process during the manufacture of the semiconductor device and/or a mark to be used in an inspection process for the semiconductor device is formed in a first region that is a region between a first scribe region that is a peripheral portion of the first substrate and the pixel region and/or in a second region that is a region between a second scribe region that is a peripheral portion of the second substrate and a region corresponding to the pixel region in the second substrate.

### TECHNICAL FIELD

The technology according to the present disclosure (the technology will be hereinafter also referred to as “the present technology”) relates to a semiconductor device, an electronic apparatus, and a method for manufacturing the semiconductor device. More specifically, the technology relates to a semiconductor device and the like having a pixel region including pixels having a photoelectric conversion unit.

### BACKGROUND ART

Patent Document 1 discloses a solid-state imaging device (a semiconductor device) in which alignment marks and positional difference detection marks are formed in the circuit region formed around the pixel region.

In the photolithography process including the exposure process at the time of the manufacture of the solid-state imaging device, the alignment marks and the positional difference detection marks are used in determining the positions of a reticle and a semiconductor substrate (a wafer), and the elements in the pixel region and the circuit region are then formed.

### CITATION LIST

### Patent Document

Patent Document 1: Japanese Patent Application Laid-Open No. 2003-249640

### SUMMARY OF THE INVENTION

### Problems to be Solved by the Invention

In the solid-state imaging device disclosed in Patent Document 1, however, there is room for improvement in terms of the quality of the pixel region.

Therefore, the present technology aims to provide a semiconductor device capable of improving the quality of the pixel region, an electronic apparatus including the semiconductor device, and a method for manufacturing the semiconductor device.

### Solutions to Problems

According to a first aspect, the present technology provides

a semiconductor device that includes:

a first substrate in which a pixel region including a pixel having a photoelectric conversion unit is formed; and

a second substrate in which a logic circuit that processes a signal output from the pixel region is formed,

in which the first substrate and the second substrate are stacked, and

at least one of marks including a mark to be used in an exposure process during the manufacture of the semiconductor device and/or a mark to be used in an inspection process for the semiconductor device is formed in a first region that is a region between a first scribe region that is a peripheral portion of the first substrate and the pixel region and/or in a second region that is a region between a second scribe region that is a peripheral portion of the second substrate and a region corresponding to the pixel region in the second substrate.

The first substrate may have a structure in which a semiconductor substrate and a wiring layer are stacked, the semiconductor substrate including a first semiconductor region in which the photoelectric conversion unit is formed and a second semiconductor region in which the photoelectric conversion unit is not formed, and the at least one of the marks may be formed in the second semiconductor region and/or in the wiring layer in the first region.

The first substrate may have a structure in which a semiconductor substrate and a light condensing layer are stacked, the semiconductor substrate including a first semiconductor region in which the photoelectric conversion unit is formed and a second semiconductor region in which the photoelectric conversion unit is not formed, the light condensing layer including a region in which a light condensing unit that condenses light onto the photoelectric conversion unit is formed and a region in which the light condensing unit is not formed, and the at least one of the marks may be formed in the second semiconductor region and/or in a region of the light condensing layer in which the light condensing unit is not formed, in the first region.

The light condensing layer may include at least one of a lens layer, or a color filter layer disposed between the lens layer and the semiconductor substrate.

The second substrate may have a structure in which a semiconductor substrate and a wiring layer are stacked, the logic circuit being formed in the semiconductor substrate, and the at least one of the marks may be formed in the semiconductor substrate and/or in the wiring layer in the second region.

The at least one of the marks may be formed at a position closer to the pixel region than to the first scribe region in the first region.

The at least one of the marks may be formed at a position closer to the region corresponding to the pixel region than to the second scribe region in the second region.

At least one of a wiring line or a circuit element may be formed in the first region, and the at least one of the marks may be formed in a region between the at least one of the wiring line or the circuit element and the pixel region in the first region.

At least one of a wiring line or a circuit element may be formed in the second region, and the at least one of the marks may be formed in a region between the at least one of the wiring line or the circuit element and a region corresponding to the pixel region in the second region.

The at least one of the marks may include a plurality of marks, and the plurality of marks may be arrayed along an outer periphery of the pixel region.

The at least one of the marks may include a plurality of marks, and the plurality of marks may be arrayed along an outer periphery of a region corresponding to the pixel region.

At least one of marks including a mark to be used in an exposure process during manufacture of the semiconductor device and/or a mark to be used in an inspection process for the semiconductor device may be formed in the first scribe region.

The at least one of the marks may be formed at a position on an inner peripheral side of the first scribe region.

At least one of marks including a mark to be used in an exposure process during manufacture of the semiconductor device and/or a mark to be used in an inspection process for the semiconductor device may be formed in the second scribe region.

The at least one of the marks may be formed at a position on an inner peripheral side of the second scribe region.

The at least one of the marks may include at least one of an alignment mark, a positional difference detection mark, or a line-width measurement mark.

The present technology also provides an electronic apparatus including the semiconductor device.

According to a second aspect, the present technology provides

a semiconductor device that includes

a substrate including:

a pixel region including a pixel having a photoelectric conversion unit; and

a circuit region formed around the pixel region,

in which at least one of marks including a mark to be used in an exposure process during the manufacture of the semiconductor device and/or a mark to be used in an inspection process for the semiconductor device is formed in an intermediate region that is a region between the pixel region and the circuit region.

In this case, the substrate may have a structure in which a semiconductor substrate and a wiring layer are stacked, the photoelectric conversion unit and a circuit element of the circuit region being formed in the semiconductor substrate, and the at least one of the marks may be formed in a first region and/or in a second region in the intermediate region, the first region being a region in which the photoelectric conversion unit and the circuit element in the semiconductor substrate are not formed, the second region being a region in the wiring layer in the intermediate region.

The at least one of the marks may be formed at a position closer to the pixel region than to the circuit region in the first region.

The at least one of the marks may be formed at a position closer to the pixel region than to the circuit region in the second region.

The at least one of the marks may include a plurality of marks, and the plurality of marks may be arrayed along an outer periphery of the pixel region in the first region.

The at least one of the marks may include a plurality of marks, and the plurality of marks may be arrayed along an outer periphery of the pixel region in the second region.

The at least one of the marks may include a plurality of marks, a portion of the plurality of marks may be formed in the intermediate region, and the other portion of the plurality of marks may be formed in a scribe region that is a peripheral portion of the substrate.

The other portion of the plurality of marks may be formed in an inner peripheral portion of the scribe region.

Further, the present technology provides an electronic apparatus including the semiconductor device.

According to a third aspect, the present technology provides

a method for manufacturing a semiconductor device including a substrate that includes:

a pixel region in which pixels including photoelectric conversion units are arrayed; and

a circuit region formed around the pixel region,

the method including a divided exposure process of dividing an exposure region on a semiconductor substrate as part of the substrate or on a layer stacked on the semiconductor substrate into a plurality of regions, and individually exposing each divided region,

the divided exposure process including:

a first exposure process of exposing one region of the plurality of regions, using a first reticle having a first mark formation pattern for forming at least one first mark in an intermediate region between the pixel region and the circuit region;

an aligning process of aligning a second reticle with another region of the plurality of regions with reference to at least a portion of the first mark, the second reticle having a second mark formation pattern for forming at least one second mark in the intermediate region between the pixel region and the circuit region; and

a second exposure process of exposing the another region, using the second reticle.

In this case, the first reticle may have a pattern for forming a portion of the pixel region and/or a portion of the circuit region, and the second reticle may have a pattern for forming the other portion of the pixel region and/or the other portion of the circuit region.

According to a fourth aspect, the present technology provides

a method for manufacturing a semiconductor device including a substrate that includes:

a pixel region in which pixels including photoelectric conversion units are arrayed; and

a circuit region formed around the pixel region,

the method including:

a first exposure process of exposing an exposure region on a semiconductor substrate as part of the substrate or on a layer stacked on the semiconductor substrate, using a first reticle having a mark formation pattern for forming a mark in an intermediate region between the pixel region and the circuit region;

a process of stacking another layer on the semiconductor substrate or the layer;

an aligning process of aligning a second reticle with an exposure region on the another layer with reference to at least a portion of the mark, the second reticle having a pattern for forming a portion of the pixel region and/or a portion of the circuit region, the exposure region on the another layer corresponding to the exposure region; and

a second exposure process of exposing the exposure region on the another material layer, using the second reticle.

In this case, the first reticle may have a pattern for forming the other portion of the pixel region and/or the other portion of the circuit region.

According to a fifth aspect, the present technology provides

a method for manufacturing a semiconductor device including a substrate in which a pixel region is formed, pixels including photoelectric conversion units being arrayed in the pixel region,

the method including a divided exposure process of dividing an exposure region on a semiconductor substrate as part of the substrate or on a layer stacked on the semiconductor substrate into a plurality of regions, and individually exposing each divided region,

the divided exposure process including:

a first exposure process of exposing one region of the plurality of regions, using a first reticle having a first mark formation pattern for forming at least one first mark in a region between the pixel region and a scribe region that is a peripheral portion of the substrate;

an aligning process of aligning a second reticle with another region of the plurality of regions with reference to at least a portion of the first mark, the second reticle having a second mark formation pattern for forming at least one second mark in the region between the pixel region and the scribe region that is the peripheral portion of the substrate; and

a second exposure process of exposing the another region, using the second reticle.

In this case, the first reticle may have a pattern for forming a portion of the pixel region, and the second reticle may have a pattern for forming the other portion of the pixel region.

According to a sixth aspect, the present technology provides

a method for manufacturing a semiconductor device including a substrate in which a pixel region is formed, pixels including photoelectric conversion units being arrayed in the pixel region,

the method including:

a first exposure process of exposing an exposure region on a semiconductor substrate as part of the substrate or on a layer stacked on the semiconductor substrate, using a first reticle having a mark formation pattern for forming a mark in a region between the pixel region and a scribe region that is a peripheral portion of the substrate;

a process of stacking another layer on the semiconductor substrate or the layer;

an aligning process of aligning a second reticle with an exposure region on the another layer with reference to at least a portion of the mark, the second reticle having a pattern for forming a portion of the pixel region, the exposure region on the another layer corresponding to the exposure region; and

a second exposure process of exposing the exposure region on the another layer, using the second reticle.

In this case, the first reticle may have a pattern for forming the other portion of the pixel region.

### BRIEF DESCRIPTION OF DRAWINGS

FIG. 1 is a block diagram showing an example configuration of a camera apparatus including a solid-state imaging device according to a first embodiment.

FIG. 2A is a plan view schematically showing a solid-state imaging device according to a first comparative example. FIG. 2B is a plan view schematically showing the solid-state imaging device according to the first embodiment.

FIG. 3 is a diagram showing part of a cross-section of the solid-state imaging device according to the first embodiment.

FIG. 4A is a plan view of an example configuration of an alignment mark. FIG. 4B is a cross-sectional view of the example configuration of an alignment mark.

FIG. 5 is a flowchart for explaining a device formation process.

FIG. 6 is a flowchart for explaining a mark formation process in the device formation process.

FIG. 7A is a process cross-sectional view (part 1) showing a process of forming main scale marks in a wafer. FIG. 7B is a process cross-sectional view (part 2) showing the process of forming main scale marks in a wafer. FIG. 7C is a process cross-sectional view (part 3) showing the process of forming main scale marks in a wafer. FIG. 7D is a process cross-sectional view (part 4) showing the process of forming main scale marks in a wafer.

FIG. 8A is a process cross-sectional view (part 1) showing a process of forming sub scale marks in a wafer. FIG. 8B is a process cross-sectional view (part 2) showing the process of forming sub scale marks in a wafer. FIG. 8C is a process cross-sectional view (part 3) showing the process of forming sub scale marks in a wafer. FIG. 8D is a process cross-sectional view (part 4) showing the process of forming sub scale marks in a wafer.

FIG. 9A is a plan view schematically showing a process of forming marks in the left half of an exposure region on a wafer.

FIG. 9B is a plan view schematically showing a process of forming marks in the right half of the exposure region on a wafer.

FIG. 10 is a flowchart for explaining an element/wiring-line formation process in the device formation process.

FIG. 11A is a plan view schematically showing a state in which the left half of one layer of a pixel region and the left half of one layer of a circuit region are formed in the left half of the exposure region in the element/wiring-line formation process. FIG. 11B is a plan view schematically showing a state in which the left half of one layer of the pixel region is formed in the left half of the exposure region in the element/wiring-line formation process.

FIG. 12A is a plan view schematically showing a state in which the right half of one layer of the pixel region and the right half of one layer of the circuit region are formed in the exposure region in the element/wiring-line formation process.

FIG. 12B is a plan view schematically showing a state in which the right half of one layer of the pixel region is formed in the exposure region in the element/wiring-line formation process.

FIG. 13 is a diagram showing part of a cross-section of a solid-state imaging device according to a first modification of the first embodiment.

FIG. 14 is a diagram showing part of a cross-section of a solid-state imaging device according to a second modification of the first embodiment.

FIG. 15 is a diagram showing part of a cross-section of a solid-state imaging device according to a third modification of the first embodiment.

FIG. 16 is a diagram showing part of a cross-section of a solid-state imaging device according to a fourth modification of the first embodiment.

FIG. 17 is a plan view schematically showing a solid-state imaging device according to a second embodiment.

FIG. 18 is a diagram showing part of a cross-section of the solid-state imaging device according to the second embodiment.

FIG. 19 is a plan view schematically showing a solid-state imaging device according to a modification of the second embodiment.

FIG. 20 is a plan view schematically showing a solid-state imaging device according to a third embodiment.

FIG. 21 is a plan view schematically showing a solid-state imaging device according to a first modification of the third embodiment.

FIG. 22 is a plan view schematically showing a solid-state imaging device according to a second modification of the third embodiment.

FIG. 23 is a plan view schematically showing a solid-state imaging device according to a third modification of the third embodiment.

FIG. 24 is a plan view schematically showing a solid-state imaging device according to a fourth modification of the third embodiment.

FIG. 25A is a plan view schematically showing a solid-state imaging device according to a second comparative example. FIG. 25B is a plan view schematically showing a solid-state imaging device according to a fourth embodiment.

FIG. 26 is a plan view schematically showing a solid-state imaging device according to a fifth embodiment.

FIG. 27 is a diagram showing part of a cross-section of the solid-state imaging device according to the fifth embodiment.

FIG. 28 is a plan view schematically showing a solid-state imaging device according to a first modification of the fifth embodiment.

FIG. 29 is a diagram showing part of a cross-section of a solid-state imaging device according to a second modification of the fifth embodiment.

FIG. 30 is a diagram showing part of a cross-section of a solid-state imaging device according to a third modification of the fifth embodiment.

FIG. 31 is a diagram showing part of a cross-section of a solid-state imaging device according to a fourth modification of the fifth embodiment.

FIG. 32 is a plan view schematically showing a solid-state imaging device according to a fifth modification of the fifth embodiment.

FIG. 33 is a diagram showing part of a cross-section of the solid-state imaging device according to the fifth modification of the fifth embodiment.

FIG. 34 is a diagram showing part of a cross-section of a solid-state imaging device according to a sixth modification of the fifth embodiment.

FIG. 35 is a diagram showing part of a cross-section of a solid-state imaging device according to a seventh modification of the fifth embodiment.

FIG. 36 is a diagram showing part of a cross-section of a solid-state imaging device according to an eighth modification of the fifth embodiment.

FIG. 37 is a diagram showing part of a cross-section of a solid-state imaging device according to a ninth modification of the fifth embodiment.

FIG. 38A is a plan view of a first example configuration of a positional difference detection mark. FIG. 38B is a cross-sectional view of the first example configuration of a positional difference detection mark.

FIG. 39A is a plan view of a sub scale mark of a second example configuration of a positional difference detection mark.

FIG. 39B is a plan view of the second example configuration of a positional difference detection mark. FIG. 39C is a cross-sectional view of the second example configuration of a positional difference detection mark.

FIG. 40A is a plan view of an example configuration of a line-width measurement mark. FIG. 40B is a cross-sectional view of the example configuration of a line-width measurement mark.

FIG. 41 is a diagram showing examples of use of the solid-state imaging devices of the first to fifth embodiments (including the modifications of the respective embodiments) to which the present technology is applied.

FIG. 42 is a functional block diagram of an example of an electronic apparatus according to a sixth embodiment to which the present technology is applied.

FIG. 43 is a block diagram schematically showing an example configuration of a vehicle control system.

FIG. 44 is an explanatory diagram showing an example of installation positions of external information detectors and imaging units.

FIG. 45 is a diagram schematically showing an example configuration of an endoscopic surgery system.

FIG. 46 is a block diagram showing an example of the functional configurations of a camera head and a CCU.

### MODES FOR CARRYING OUT THE INVENTION

The following is a detailed description of preferred embodiments of the present technology, with reference to the accompanying drawings. Note that, in this specification and the drawings, components having substantially the same functional configurations are denoted by the same reference numerals, and explanation of them will not be repeated. The embodiments described below are typical embodiments of the present technology, and do not narrow the interpretation of the scope of the present technology. In this specification, even in a case where it is described that each semiconductor device, each electronic apparatus, and each semiconductor device manufacturing method according to the present technology exhibits a plurality of effects, each semiconductor device, each electronic apparatus, and each semiconductor device manufacturing method according to the present technology is only required to exhibit at least one effect. The advantageous effects described in this specification are merely examples, and the advantageous effects of the present technology are not limited to them and may include other effects.

Further, explanation will be made in the following order.

1. Overall configuration of a camera apparatus including a solid-state imaging device according to a first embodiment of the present technology

2. Introduction

3. Solid-state imaging device according to the first embodiment of the present technology

(1) Configuration of the solid-state imaging device

(2) Operation of the solid-state imaging device

(3) Method for manufacturing the solid-state imaging device

(4) Effects of the method for manufacturing the solid-state imaging device

(5) Effects of the solid-state imaging device

4. Solid-state imaging devices according to first to fourth modifications of the first embodiment of the present technology

5. Solid-state imaging device according to a second embodiment of the present technology

6. Solid-state imaging device according to a modification of the second embodiment of the present technology

7. Solid-state imaging device according to a third embodiment of the present technology

8. Solid-state imaging device according to a first modification of the third embodiment of the present technology

9. Solid-state imaging device according to a second modification of the third embodiment of the present technology

10. Solid-state imaging device according to a third modification of the third embodiment of the present technology

11. Solid-state imaging device according to a fourth modification of the third embodiment of the present technology

12. Solid-state imaging device according to a fourth embodiment of the present technology

13. Solid-state imaging device according to a fifth embodiment of the present technology

14. Solid-state imaging device according to a first modification of the fifth embodiment of the present technology

15. Solid-state imaging device according to a second modification of the fifth embodiment of the present technology

16. Solid-state imaging device according to a third modification of the fifth embodiment of the present technology

17. Solid-state imaging device according to a fourth modification of the fifth embodiment of the present technology

18. Solid-state imaging device according to a fifth modification of the fifth embodiment of the present technology

19. Solid-state imaging device according to a sixth modification of the fifth embodiment of the present technology

20. Solid-state imaging device according to a seventh modification of the fifth embodiment of the present technology

21. Solid-state imaging device according to an eighth modification of the fifth embodiment of the present technology

22. Solid-state imaging device according to a ninth modification of the fifth embodiment of the present technology

23. Modifications common to each embodiment of the present technology

24. Sixth embodiment of the present technology (an example of an electronic apparatus)

25. Examples of use of solid-state imaging devices to which the present technology is applied

26. Other examples of use of solid-state imaging devices to which the present technology is applied

27. Example applications to mobile structures

28. Example application to an endoscopic surgery system

1. <Overall Configuration of a Camera Apparatus Including a Solid-State Imaging Device According to a First Embodiment of the Present Technology>

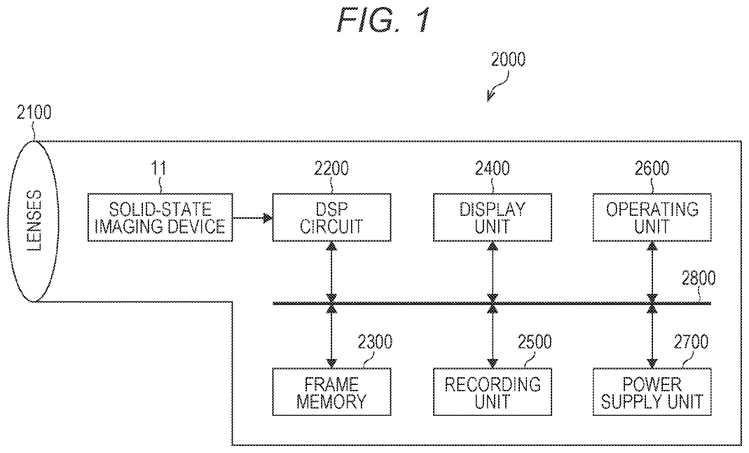

FIG. 1 is a block diagram showing an example configuration of a camera apparatus 2000 (an example of an electronic apparatus) including a solid-state imaging device 11 (a semiconductor device) according to a first embodiment of the present technology. The camera apparatus 2000 shown in FIG. 1 includes an optical unit 2100 formed with lenses and the like, and a DSP circuit 2200 that is a camera signal processing device, in addition to the solid-state imaging device 11. The camera apparatus 2000 also includes a frame memory 2300, a display unit (display device) 2400, a recording unit 2500, an operating unit 2600, and a power supply unit 2700. The DSP circuit 2200, the frame memory 2300, the display unit 2400, the recording unit 2500, the operating unit 2600, and the power supply unit 2700 are connected to one another via a bus line 2800.

The optical unit 2100 gathers incident light (image light) from an object, and forms an image on the imaging surface of the solid-state imaging device 11. The solid-state imaging device 11 converts the amount of the incident light, which has been gathered as the image on the imaging surface by the optical unit 2100, into an electrical signal for each pixel, and outputs the electrical signal as a pixel signal.

The display unit 2400 is formed with a panel display device such as a liquid crystal panel or an organic electro-luminescence (EL) panel, for example, and displays a moving image or a still image formed by the solid-state imaging device 11. The DSP circuit 2200 receives a pixel signal output from the solid-state imaging device 11, and performs processing for displaying the pixel signal on the display unit 2400. The recording unit 2500 records a moving image or a still image formed by the solid-state imaging device 11 on a recording medium, such as a video tape or a digital versatile disk (DVD).

When operated by a user, the operating unit 2600 issues operating instructions as to various functions of the solid-state imaging device 11. The power supply unit 2700 supplies various power sources as the operating power sources for the DSP circuit 2200, the frame memory 2300, the display unit 2400, the recording unit 2500, and the operating unit 2600, as appropriate.

2. <Introduction>

In an image sensor (a solid-state imaging device) that is a kind of semiconductor device, the quality of the pixel region in which pixels each having a photoelectric conversion unit are arrayed directly affects the quality of a captured image, and therefore, there is a demand for further quality improvement. There is also a demand for further improvement in productivity in the case of mass production of image sensors.

In general, image sensors are manufactured by photolithography including an exposure process.

In the photolithography, a series of processes for stacking layers (a semiconductor film and an insulating film, for example) as the material layers, exposure, and etching are repeatedly performed, to form photoelectric conversion units, circuit elements, wiring lines, and the like.

In a case where divided exposure (joint exposure) for exposing an exposure region divided into a plurality of regions on a wafer is performed in the photolithography, if the number of divisions is large, the exposure tact time and the number of times joining is performed between the divided regions increase accordingly. Increases in the exposure tact time and the number of times joining is performed directly lead to a decrease in throughput (productivity). Further, divided exposure requires a high joining accuracy. Therefore, in a case where the number of divisions is large, it is difficult to improve the quality of the pixel region.

Also, in the photolithography, the upper layer pattern is superimposed on the lower layer pattern at the time of exposure. However, if the superimposition accuracy is low, the quality of the pixel region is degraded.

Furthermore, there is a demand for further improvement in the inspection accuracy in an inspection process such as the film thickness measurement after the processing of image sensors. This inspection accuracy particularly affects yield (productivity).

In view of this, the inventor of the present technology came up with novel layouts of the marks to be used in the exposure process at the time of the manufacture of image sensors and/or the marks to be used in the inspection process, so as to increase the productivity of image sensors and enhance the quality of the pixel region, as will be described later in detail.

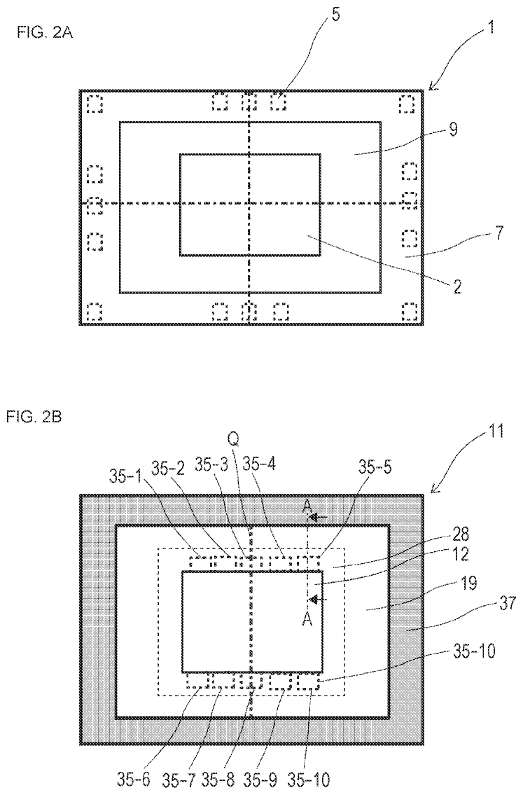

For example, in a solid-state imaging device 1 of a first comparative example shown in FIG. 2A, alignment marks, positional difference detection marks, line-width measurement marks, and the like are formed only in a scribe region 7 (a region far away from the pixel region 2) located on the outer peripheral side of a circuit region 9 around the pixel region 2. For this reason, it is not possible to increase the accuracy of alignment between a reticle and an exposure region on the wafer during the exposure process at the time of manufacture of the solid-state imaging device 1, the positional difference detection accuracy, the thickness measurement accuracy during the inspection process, and the like. Therefore, it is difficult to increase the quality of the pixel region 2.

Therefore, in the present technology, as shown in FIG. 2B, alignment marks, positional difference detection marks, line-width measurement marks, and the like are formed in the vicinity of the pixel region 12, for example, so that information about the positions closer to the pixel region 12 can be obtained. In this case, in particular, the accuracy of alignment between a reticle and an exposure region on the wafer during the exposure process at the time of formation of the pixel region 12, the positional difference detection accuracy, the thickness measurement accuracy during the inspection process, and the like can be increased, and thus, the quality of the pixel region 2 can be made higher.

In the description below, the present technology is explained in detail with reference to several embodiments.

3. <Solid-State Imaging Device According to the First Embodiment of the Present Technology>

(1) Configuration of the Solid-State Imaging Device

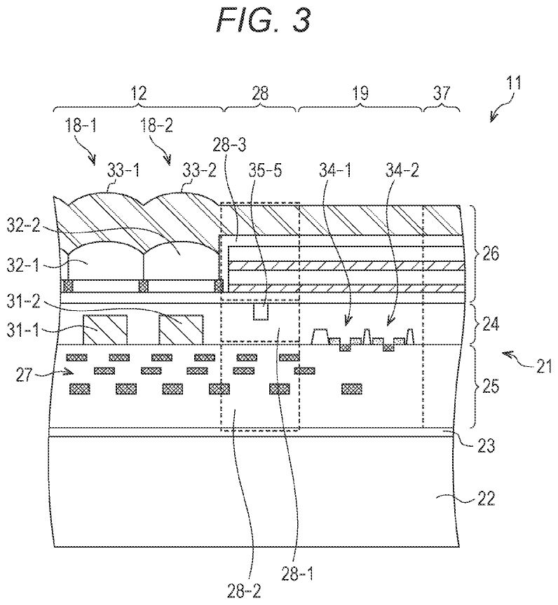

FIG. 2B is a plan view schematically showing the solid-state imaging device 11 according to the first embodiment. FIG. 3 is a diagram schematically showing part of a cross-section of the solid-state imaging device 11 according to the first embodiment (a cross-sectional view taken along line A-A defined in FIG. 2B). In the description below, the upper side in FIG. 3 will be referred to as the “upper side”, and the lower side in FIG. 3 will be referred to as the “lower side”.

The solid-state imaging device 11 has a substrate 21 that includes a pixel region 12 and a circuit region 19 located around the pixel region 12. The solid-state imaging device 11 is called an “image sensor” in general terms. As shown in FIG. 2B, the solid-state imaging device 11 as a whole has a rectangular external shape in a plan view, for example. The solid-state imaging device 11 is a medium-sized image sensor, for example.

The pixel region 12 has a rectangular external shape in a plan view, for example. The circuit region 19 has a rectangular frame-like external shape surrounding the pixel region 12, for example.

In the solid-state imaging device 11, the region combining the pixel region 12 and the circuit region 19 in a plan view (the region excluding a scribe region 37 (the shaded portion) in FIG. 2B) is the exposure region during the exposure process (in the example shown FIG. 2B, the exposure process is the process that is performed when the pixel region 12 and the circuit region 19 are simultaneously produced; the same applies in the cases described later) at the time of manufacture. Also, in the solid-state imaging device 11, the region (the scribe region 37 (the shaded portion) in FIG. 2B) having a rectangular frame-like shape in a plan view on the outer peripheral side of the circuit region 19 is the non-exposure region during the exposure process at the time of manufacture. That is, in the solid-state imaging device 11, at least the scribe region 37 is the non-exposure region.

On the other hand, the solid-state imaging device 1 of the first comparative example shown in FIG. 2A has the same chip size as the solid-state imaging device 11 according to the first embodiment, and the entire surface thereof is the exposure region. That is, in the solid-state imaging device 1 of the first comparative example, marks need to be formed in the scribe region 7, the exposure region at least during the exposure process during which the marks are formed is larger than the exposure region of the solid-state imaging device 11. Where the exposure region is larger, the number of divisions of the exposure region is larger when divided exposure is performed, for example (in FIG. 2A, the number of divisions is four: the exposure region is divided into four regions by two dot-and-dash lines perpendicular to each other). In the solid-state imaging device 1 shown in FIG. 2A, one corner of each of the four divided regions (rectangular regions) obtained by dividing the exposure region overlaps the pixel region 2. This puts a restriction on the layout of the marks, allowing formation of the marks only at three corners of each divided region, for example.

In the solid-state imaging device 11 shown in FIG. 2B, on the other hand, the exposure region at least during the exposure process during marks are formed is smaller than that in the solid-state imaging device 1 at least by the amount equivalent to the area of the scribe region 37, and the number of divisions at the time of divided exposure can be made smaller, for example (in FIG. 2B, the number of divisions is two: the exposure region is divided into two regions by one dot-and-dash line). In this case, marks can be formed at the four corners of each of the two divided regions (rectangular regions) obtained by dividing the exposure region, for example.

Further, where the exposure region that is the region to be exposed is smaller by a larger amount than the exposure range that is set by the specification and the standard of the exposure device, the exposure device can be more effectively made to achieve a higher resolution and a smaller size.

As shown in FIG. 3, the substrate 21 includes a semiconductor substrate 24, a wiring layer 25 disposed on the lower side of the semiconductor substrate 24, and a light condensing layer 26 disposed on the upper side of the semiconductor substrate 24.

That is, the solid-state imaging device 11 is a single-plate image sensor having a single semiconductor substrate.

The substrate 21 is supported by a support substrate 22 via a joining layer 23 from the lower side.

The light condensing layer 26 has a structure that includes a color filter layer including a plurality of color filters 32 (two color filters 32-1 and 32-2 are shown in FIG. 3, for example) disposed on the upper side of the semiconductor substrate 24, and a lens layer including a plurality of on-chip lenses 33 (two on-chip lenses 33-1 and 33-2 are shown in FIG. 3, for example) disposed on the upper side of the color filter layer.

The pixel region 12 has a rectangular external shape in a plan view as shown in FIG. 2B, and includes a plurality of pixels 18 (two pixels 18-1 and 18-2 are shown in FIG. 3, for example) two-dimensionally arranged (for example, arranged in a matrix) as shown in FIG. 3.

The pixel region 12 further includes the wiring layer 25 on the lower side of the region in which the plurality of pixels 18 is formed.

Each pixel 18 is a back-illuminated pixel that is illuminated with light from the side of the back surface, which is the surface (upper surface) opposite to the front surface that is the surface (lower surface) on the side of the wiring layer 25 of the semiconductor substrate 24.

As shown in FIG. 3, each pixel 18 includes a photoelectric conversion unit 31 (a photodiode, for example; two photoelectric conversion units 31-1 and 31-2 are shown in FIG. 3, for example) formed in the semiconductor substrate 24, a color filter 32 formed on the upper side of the semiconductor substrate 24, and an on-chip lens 33 formed on the upper side of the color filter 32. The color filter 32 and the on-chip lens 33 of each pixel 18 are also collectively referred to as a “light condensing unit”.

Here, in the semiconductor substrate 24, each photoelectric conversion unit 31 is formed on the lower surface (front surface) side of the semiconductor substrate 24.

The photoelectric conversion unit 31 of each pixel 18 forms part of the semiconductor substrate 24. The color filter 32 of each pixel 18 forms part of the color filter layer described above. The on-chip lens 33 of each pixel 18 forms part of the lens layer described above.

The circuit region 19 has a rectangular frame-like external shape in a plan view as shown in FIG. 2B, and includes active elements 34 (transistors, for example; two active elements 34-1 and 34-2 are shown in FIG. 3, for example) as circuit elements formed in the semiconductor substrate 24.

The circuit region 19 further includes the wiring layer 25 on the lower side of the region in which the active elements 34 of the semiconductor substrate 24 are formed.

Here, in the semiconductor substrate 24, each active element 34 is formed on the lower surface (front surface) side of the semiconductor substrate 24.

Note that, here, the circuit region 19 may also include a region outside the pixel region 12 in the light condensing layer 26 (a region having substantially no light condensing functions, or a region in which the light condensing unit of the light condensing layer 26 is not formed).

The circuit region 19 includes a control circuit that controls the photoelectric conversion unit 31 of each pixel 18, and a logic circuit (a digital circuit) that processes an electrical signal (an analog signal) photoelectrically converted by the photoelectric conversion unit 31 of each pixel 18.

Note that the circuit region 19 may include only either the control circuit or the logic circuit described above.

As shown in FIG. 3, in the wiring layer 25, a plurality of wiring lines 27 for connecting elements formed in the semiconductor substrate 24 is disposed in an interlayer insulating film. A drive signal for controlling drive of the control circuit in the circuit region 19 is supplied via the plurality of wiring lines 27, and an electrical signal (an analog signal) output from each pixel 18 is output to the logic circuit in the circuit region 19.

In the wiring layer 25, The wiring lines 27 are formed with copper (Cu), aluminum (Al), tungsten (W), or the like, for example. The interlayer insulating film is formed with a silicon oxide film, a silicon nitride film, or the like, for example. Each of the plurality of wiring layers 27 and the interlayer insulating film may be formed with the same material in all the layers, or may be formed with two or more materials in different layers.

As shown in FIGS. 2B and 3, a plurality of (ten, for example) marks 35 (35-1 to 35-10) to be used in the exposure process at the time of manufacture of the solid-state imaging device 11 is formed in an intermediate region 28 that is a region between the pixel region 12 and the circuit region 19.

In FIGS. 2B and 3, each mark 35 is schematically shown (as a simple quadrangle) for convenience sake.

The intermediate region 28 includes a first region 28-1 (a region having a rectangular frame-like shape in a plan view) between the region in which the plurality of photoelectric conversion units 31 is formed and the circuit region 19 in the semiconductor substrate 24, a second region 28-2 (a region having a rectangular frame-like shape in a plan view) corresponding to the first region 28-1 in the wiring layer 25, and a third region 28-3 (a region having a rectangular frame-like shape in a plan view) between the pixel region 12 and the circuit region 19 in the light condensing layer 26.

As shown in FIG. 3 as an example, the ten marks 35 are formed in the first region 28-1.

Specifically, the ten marks 35 are arrayed along the outer periphery of the pixel region 12 as shown in FIG. 2B.

More specifically, of the ten marks 35, five marks 35 are arrayed along one long side of the pixel region 12, and the remaining five marks 35 are arrayed along the other long side of the pixel region 12.

In an example, of the five marks 35 arrayed along one long side of the pixel region 12, the center mark 35-3 is a positional difference detection mark, and the other four marks 35-1, 35-2, 35-4, and 35-6 are alignment marks.

In an example, of the five marks 35 arrayed along the other long side of the pixel region 12, the center mark 35-8 is a positional difference detection mark, and the other four marks 35-6, 35-7, 35-9, and 35-10 are alignment marks.

The respective positional difference correction marks 35-3 and 35-8 are disposed at the opposite ends of a dot-and-dash line Q that divides the solid-state imaging device 11 into two equal parts in the long-side direction and extends in the short-side direction in a plan view (see FIG. 2B).

Note that the positional relationship between the respective marks 35 may be interchanged. Here, the types (of usage) of the marks are two types (for alignment and for positional difference detection). However, the types of the marks may be one, or three or more types (alignment marks, positional difference detection marks, and line-width measurement marks, for example).

As shown in FIG. 3, in the semiconductor substrate 24, each mark 35 is formed on the upper surface (back surface) side of the semiconductor substrate 24, for example.

As shown in FIG. 2B, each mark 35 is disposed at a position closer to the pixel region 12 than to the circuit region 19 in the intermediate region 28.

Note that each mark 35 may be disposed at a position closer to the circuit region 19 than to the pixel region 12 in the intermediate region 28, for example, or may be disposed at an intermediate position between the pixel region 12 and the circuit region 19 in the intermediate region 28, for example.

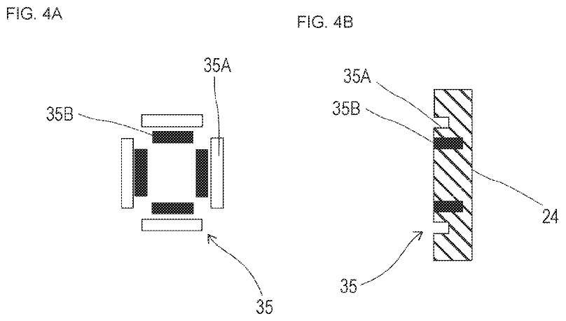

FIG. 4A shows a plan view of an example configuration of a mark 35 (an alignment mark). FIG. 4B shows a cross-sectional view of an example configuration of a mark 35 (an alignment mark).

As shown in FIGS. 4A and 4B, each alignment mark includes a main scale mark and a sub scale mark.

The main scale mark as an example includes four grooves 35A that are formed in the semiconductor substrate 24, a resist, or a material layer (such as an insulating film, a metal film, or an oxide film as the material of the wiring layer 25, a color filter material or a lens material as the material of the light condensing layer 26, for example) so as to surround four sides of the center point (in FIGS. 4A and 4B, the grooves are formed in the semiconductor substrate 24), for example. Note that the main scale mark may be protrusions, instead of grooves formed in the semiconductor substrate 24, a resist, or a material layer.

In the solid-state imaging device 11 as a product, the sub scale mark includes four impurity layers 35B that are formed so as to surround the four sides of the center point in the region surrounded by the main scale mark in the semiconductor substrate 24, for example. The impurity layers 35B are formed by implanting impurities into the wafer (a silicon substrate, for example) to be the material of the semiconductor substrate 24, for example. To identify the impurity layers 35B, it is necessary to perform a special process for making the impurities visible.

On the other hand, in the stage of being used as the reference for alignment in the exposure process, the sub scale mark is recesses or protrusions that are formed in/on a resist for impurity implantation, a metal film, an oxide film, an insulating film, a color filter material, a lens material, or the like, for example.

Each positional difference detection mark also includes a main scale mark and a sub scale mark that are similar to the above.

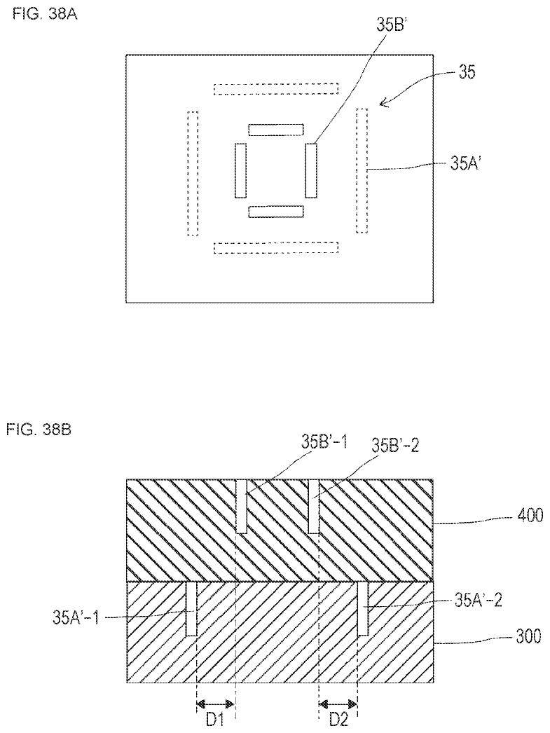

FIG. 38A is a plan view of a mark 35 (a first example configuration of a positional difference detection mark). FIG. 38B is a cross-sectional view of the mark 35 (the first example configuration of a positional difference detection mark).

The positional difference detection mark includes a main scale mark formed in a lower layer 300 and a sub scale mark formed in an upper layer 400. That is, the positional difference detection mark is a mark for detecting a positional difference between patterns (a positional difference between upper and lower patterns) at the time of superimposed exposure.

The main scale mark includes four grooves 35A′ that are formed in the lower layer 300 so as to surround the center point (in FIG. 38B, only grooves 35A′-1 and 35A′-2 are shown).

The sub scale mark includes four grooves 35B′ that are formed in the upper layer 400 so as to surround the center point in the region on the inner side of the main scale mark (in FIG. 38B, only grooves 35B′-1 and 35B′-2 are shown).

In the positional difference detection mark, as shown in FIG. 38B, the amount of positional difference between the upper and lower patterns can be calculated from the difference between the distance D1 between the groove 35A′-1 of the main scale mark and the groove 35B′-1 of the sub scale mark, and the distance D2 between the groove 35A′-2 of the main scale mark and the groove 35B′-2 of the sub scale mark.

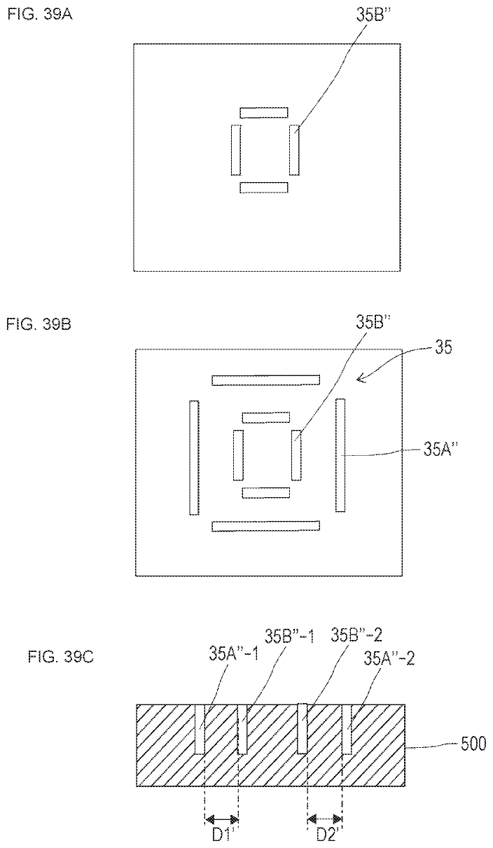

FIG. 39A is a plan view of the sub scale mark of a mark 35 (a second example configuration of a positional difference detection mark). FIG. 39B is a plan view of the mark 35 (the second example configuration of a positional difference detection mark). FIG. 39C is a cross-sectional view of the mark 35 (the second example configuration of a positional difference detection mark).

The positional difference detection mark includes a main scale mark and a sub scale mark that are formed in the same layer 500. That is, the positional difference detection mark is a mark for detecting a positional difference between patterns (a positional difference between patterns adjacent to each other in the horizontal direction) at the time of divided exposure.

The main scale mark includes four grooves 35A″ that are formed in the layer 500 so as to surround the four sides of the center point (in FIG. 39C, only grooves 35A″-1 and 35A″-2 are shown).

The sub scale mark includes four grooves 35B″ that are formed in the layer 500 so as to surround the four sides of the center point in the region surrounded by the main scale mark (in FIG. 39C, only grooves 35B″-1 and 35B″-2 are shown).

In the positional difference detection mark, as shown in FIG. 39B, the amount of positional difference between the patterns horizontally adjacent to each other can be calculated from the difference between the distance D1′ between the groove 35A″-1 of the main scale mark and the groove 35B″-1 of the sub scale mark, and the distance D2 between the groove 35A″-2 of the main scale mark and the groove 35B″-2 of the sub scale mark.

In the positional difference detection mark, after the sub scale mark is formed at the time of exposure of one exposure region among the one and the other regions obtained by dividing the exposure region (see FIG. 39A), for example, the main scale mark is formed at the time of exposure of the other regions (see FIG. 39B).

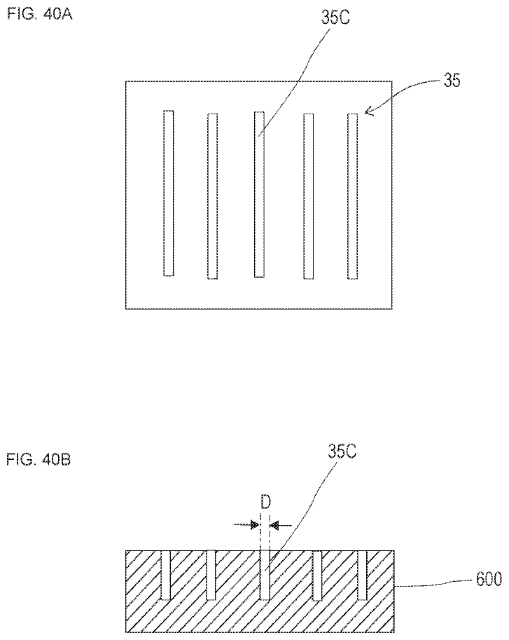

FIG. 40A is a plan view of a mark 35 (an example configuration of a line-width measurement mark). FIG. 40B is a cross-sectional view of the mark 35 (the example configuration of a line-width measurement mark).

The line-width measurement mark includes grooves 35C formed in a layer 600. In the layer 600, dummy grooves for shape stabilization are formed in addition to the grooves 35C.

In the line-width measurement mark, line-width measurement can be performed with reference to a distance D that is the width of each groove 35C shown in FIG. 40B.

(2) Operation (Actions) of the Solid-State Imaging Device

Light (image light) from an object enters each pixel 18 of the solid-state imaging device 11. The light that has entered each pixel 18 then enters the on-chip lens 33 of the pixel 18, and is condensed. The light condensed by the on-chip lens 33 then enters the corresponding color filter 32. The light transmitted through the color filter 32 then enters the corresponding photoelectric conversion unit 31.

The photoelectric conversion unit 31 photoelectrically converts the incident light. The current (the electrical signal) photoelectrically converted by the photoelectric conversion unit 31 is sent to the circuit region 19, and a predetermined process and a predetermined calculation are performed.

(3) Method for Manufacturing the Solid-State Imaging Device

In the description below, a method for manufacturing the solid-state imaging device 11 is explained.

The solid-state imaging device 11 is manufactured with a semiconductor manufacturing apparatus. The semiconductor manufacturing apparatus as an example includes an exposure device (of a step-and-repeat type or a step-and-scan type) that includes a light source, a projection optical system, a reference microscope, a wafer stage, and two reticle stages 1 and 2. The reticle stages and the projection optical system are designed to move in an integrated manner.

Specifically, the solid-state imaging device 11 performs the first half of the sensor formation process (the front end of line: FEOL) on an epitaxial layer formed on a wafer 200 (a silicon substrate, for example). The FEOL is the first half of the process before the semiconductor manufacturing process, and is performed mainly for manufacturing the elements in a Si substrate by a transistor forming process, ion injection (implantation), annealing, and the like.

Note that the second half of the sensor formation process (the back end of line: BEOL) is the second half of the process before the semiconductor manufacturing process, and refers to the wiring process, particularly from the formation of wiring lines to the step before the joining.

The flow of the above-mentioned process (the FEOL to the BEOL) before the semiconductor manufacturing process is now roughly described. First, an epitaxial layer is formed on the wafer 200 to be the material of the semiconductor substrate 24, and a plurality of photoelectric conversion units 31 (photodiodes, for example) and the circuit region 19 are formed. Next, an insulating film to be the material of the interlayer insulating film of the wiring layer 25 is formed on the back surface side of the wafer 200, and is subjected to etching. A metal film is then buried therein, so that a wiring layer is formed. This step is repeated a plurality of times. After that, a color filter layer and a lens layer are sequentially stacked on the front surface side of the wafer 200.

Here, the solid-state imaging device 11 is manufactured in the following manner: a plurality of solid-state imaging devices 11 is integrally generated in series on the single wafer 200 in the above-mentioned process before the semiconductor manufacturing process, and is then separated into individual chip-like solid-state imaging devices 11.

As described above, in the solid-state imaging device 11, which is a medium-size image sensor, the entire exposure region can be collectively exposed (through one shot) with an exposure device having a wide exposure range. However, an exposure device with a wide exposure range normally has a lower resolution and a larger alignment error than those of an exposure device with a narrow exposure range. Therefore, an exposure device with a wide exposure range cannot cope with the miniaturization these days, and is not suitable for increasing the quality of a solid-state imaging device. In view of this, divided exposure for exposing an exposure region a plurality of times is performed in this embodiment as described below in detail.

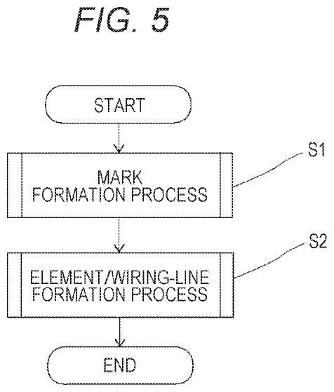

The elements (such as photodiodes, color filters, and on-chip lenses, for example) constituting the pixel region 12, and the elements (such as transistors, for example) constituting the circuit region 19 of the solid-state imaging device 11 are generated in a device formation process (a process to be performed through a FEOL and a BEOL) in which a photolithography process is repeatedly performed. In an example, the device formation process is performed by the control unit of the semiconductor manufacturing apparatus according to the following procedures shown in a flowchart in FIG. 5.

In the first step S1, a mark formation process is performed. The mark formation process will be described later in detail.

In the next step S2, an element/wiring-line formation process is performed. In the element/wiring-line formation process, elements and wiring lines are formed using the marks formed in the mark formation process. The element/wiring-line formation process will be described later in detail.

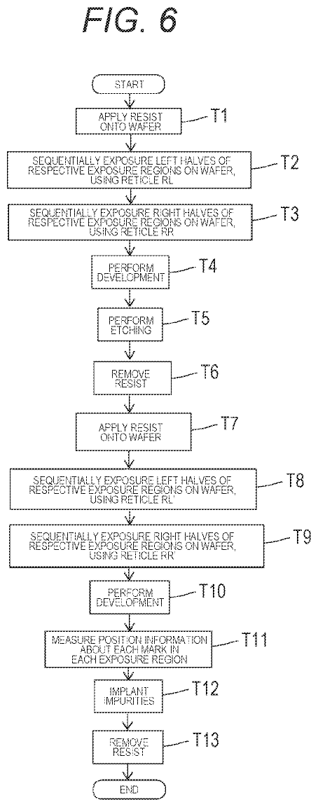

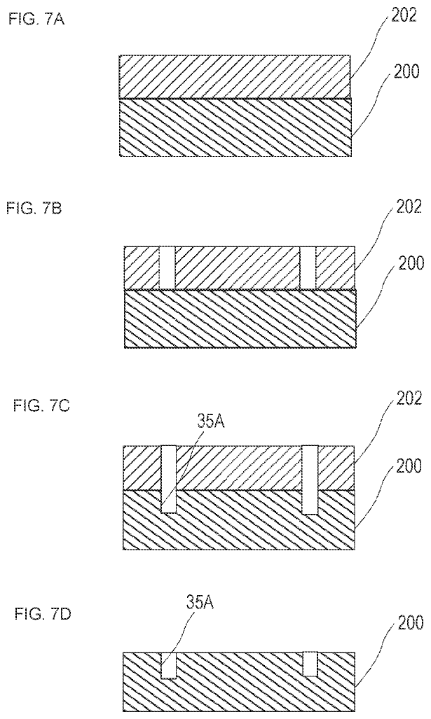

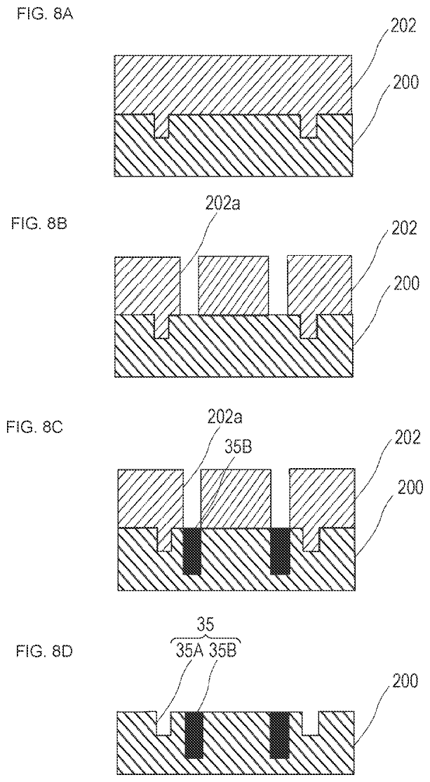

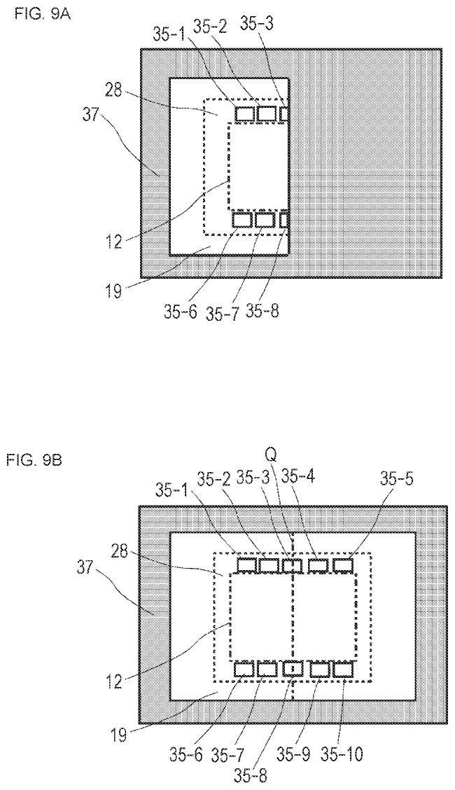

In the description below, the above “mark formation process” (step S1 in FIG. 5) is explained with reference to a flowchart shown in FIG. 6, FIGS. 7A to 7D, FIGS. 8A to 8D, and FIGS. 9A and 9B. FIGS. 7A to 7D are process cross-sectional views showing a series of processes for generating the main scale marks of an alignment mark. FIGS. 8A to 8D are process cross-sectional views showing a series of processes for generating the sub scale marks of an alignment mark. FIG. 9A is a plan view showing a state in which the left half (the left half portion) of the exposure region is exposed to form marks 35. FIG. 9B is a plan view showing a state in which the right half (the right half portion) of the exposure region is exposed to form marks 35.

In the first step T1, as shown in FIG. 7A, a resist 202 (a positive resist in this example) is applied onto the wafer 200 (a silicon substrate, for example) to be the material of the semiconductor substrate 24.

In the next step T2, the left halves (the portion on the left side of the dot-and-dash line Q in FIG. 2; the same applies in the description below) of the respective exposure regions (the exposure region for each one chip) of the wafer 200 are sequentially exposed with a reticle RL. The respective exposure regions (rectangular regions in this example) of the wafer 200 are two-dimensionally arranged in the same direction. The reticle RL has a light shielding pattern (or a light transmitting pattern) for forming the respective main scale marks of first alignment marks 35-1, 35-2, 35-6, and 35-7, and the left halves of the respective main scale marks of the positional difference detection marks 35-3 and 35-8. Here, the alignment marks formed in the left half of the exposure region are referred to as the “first alignment marks” (the same applies in the description below).

Specifically, the reticle stage 1 on which the reticle RL is placed and the wafer stage on which the wafer 200 is placed are moved relatively to each other, to perform aligning so that the reticle RL and the left half of the exposure region face each other. Here, the alignment is performed with the use of grid lines and reference marks formed beforehand on the wafer 200, and reference marks formed beforehand on the reticle RL. After that, the left half of the exposure region is irradiated with exposure light emitted from the light source through the reticle RL and the projection optical system. As a result, a latent image for generating the respective main scale marks of the first alignment marks 35-1, 35-2, 35-6, and 35-7, and the left halves of the respective main scale marks of the positional difference detection marks 35-3 and 35-8 is formed.

A series of operations as described above are sequentially performed for each exposure region.

In the next step T3, the right halves (the portion on the right side of the dot-and-dash line Q in FIG. 2; the same applies in the description below) of the respective exposure regions of the wafer 200 are sequentially exposed with a reticle RR. The reticle RR has a light shielding pattern (or a light transmitting pattern) for forming the respective main scale marks of second alignment marks 35-4, 35-5, 35-9, and 35-10, and the right halves of the respective main scale marks of the positional difference detection marks 35-3 and 35-8. Note that the alignment marks formed in the right half of the exposure region are referred to as the “second alignment marks” (the same applies in the description below).

Specifically, the reticle stage 2 on which the reticle RR is placed and the wafer stage on which the wafer 200 is placed are moved relatively to each other, to perform aligning so that the reticle RR and the right half of the exposure region face each other. Here, the reticle RR and the right half of the exposure region are aligned on the basis of the main scale marks of the first alignment marks 35-1, 35-2, 35-6, and 35-7 formed in the left half of the exposure region formed in step T2. After that, a positional difference between the reticle RR and the right half of the exposure region is detected on the basis of the left halves of the respective main scale marks of the positional difference detection marks 35-3 and 35-8 formed in the left half of the exposure region. The relative positions of the reticle stage 2 and the wafer stage are then adjusted on the basis of the detection result, so that the positional difference is corrected. After that, the right half of the exposure region is irradiated with exposure light emitted from the light source through the reticle RL and the projection optical system. As a result, a latent image for generating the respective main scale marks of the second alignment marks 35-4, 35-5, 35-9, and 35-10, and the right halves of the respective main scale marks of the positional difference detection marks 35-3 and 35-8 is formed.

A series of operations as described above are sequentially performed for each exposure region.

In the next step T4, development is performed. Specifically, each exposure region is developed with a developer, to form a resist pattern for forming the main scale marks of the respective first alignment marks, the main scale marks of the respective second alignment marks, and the main scale marks of the respective positional difference detection marks (see FIG. 7(B)).

In the next step T5, etching is performed. Specifically, etching is performed on each exposure region of the wafer 200, using the resist pattern formed as a mask in step T4 (see FIG. 7C).

In the next step T6, the resist is removed (see FIG. 7D). As a result, the main scale marks of the respective first alignment marks, the main scale marks of the respective second alignment marks, and the main scale marks of the respective positional difference detection marks are generated. Here, the main scale mark of each alignment mark is formed with a plurality of grooves 35A formed in the wafer 200. Each positional difference detection mark is also formed with a plurality of grooves formed in the wafer 200.

In the next step T7, a resist 202 (a positive resist in this example) is applied onto the wafer 200 (see FIG. 8A).

In the next step T8, the left halves of the respective exposure regions of the wafer 200 are sequentially exposed with a reticle RL′. The reticle RL′ has a light shielding pattern (or a light transmitting pattern) for forming the respective sub scale marks of the first alignment marks 35-1, 35-2, 35-6, and 35-7, and the left halves of the respective sub scale marks of the positional difference detection marks 35-3 and 35-8.

Specifically, the reticle stage 1 on which the reticle RL′ is placed and the wafer stage on which the wafer 200 is placed are moved relatively to each other, to perform aligning so that the reticle RL′ and the left half of the exposure region face each other. Here, the reticle RL′ and the left half of the exposure region are aligned on the basis of the main scale marks of the first alignment marks 35-1, 35-2, 35-6, and 35-7 formed in the left half of the exposure region formed in step T2. After that, a positional difference between the reticle RL′ and the half of the exposure region is detected on the basis of the left halves of the respective main scale marks of the positional difference detection marks 35-3 and 35-8 formed in the left half of the exposure region. The relative positions of the reticle stage 2 and the wafer stage are then adjusted on the basis of the detection result, so that the positional difference is corrected. After that, the left half of the exposure region is irradiated with exposure light emitted from the light source through the reticle RL′ and the projection optical system. As a result, a latent image for generating the respective sub scale marks of the first alignment marks 35-1, 35-2, 35-6, and 35-7, and the left halves of the respective sub scale marks of the positional difference detection marks 35-3 and 35-8 is formed.

A series of operations as described above are sequentially performed for each exposure region.

In the next step T9, the right halves of the respective exposure regions of the wafer 200 are sequentially exposed with a reticle RR′. The reticle RR′ has a light shielding pattern (or a light transmitting pattern) for forming the respective sub scale marks of the second alignment marks 35-4, 35-5, 35-9, and 35-10, and the right halves of the respective sub scale marks of the positional difference detection marks 35-3 and 35-8.

Specifically, the reticle stage 2 on which the reticle RR′ is placed and the wafer stage on which the wafer 200 is placed are moved relatively to each other, to perform aligning so that the reticle RR′ and the right half of the exposure region face each other. Here, the reticle RR′ and the right half of the exposure region are aligned on the basis of the respective main scale marks of the first alignment marks 35-4, 35-5, 35-9, and 35-10 formed in the right half of the exposure region formed in step T2. After that, a positional difference between the reticle RR′ and the right half of the exposure region is detected on the basis of the right halves of the respective main scale marks of the positional difference detection marks 35-3 and 35-8 formed in the right half of the exposure region. The relative positions of the reticle stage 2 and the wafer stage are then adjusted on the basis of the detection result, so that the positional difference is corrected. After that, the right half of the exposure region is irradiated with exposure light emitted from the light source through the reticle RR′ and the projection optical system. As a result, a latent image for generating the respective sub scale marks of the second alignment marks 35-4, 35-5, 35-9, and 35-10, and the right halves of the respective sub scale marks of the positional difference detection marks 35-3 and 35-8 is formed.

A series of operations as described above are sequentially performed for each exposure region.

In the next step T10, development is performed. Specifically, each exposure region is developed with a developer, to form a resist pattern having grooves 202a for forming the sub scale marks of the respective first alignment marks, the sub scale marks of the respective second alignment marks, and the sub scale marks of the respective positional difference detection marks (see FIG. 8B).

In the next step T11, the position information about each mark in each exposure region is measured. Specifically, while the wafer stage on which the wafer 200 is placed is moved, the grooves 202a in the resist pattern for forming the main scale mark and the sub scale mark of each mark are observed with the reference microscope, and the position information about the marks is measured and stored into a memory.

In the next step T12, impurities are implanted. Specifically, impurities (the material of the impurity layers 35B) are implanted into the wafer 200 through the grooves 202a in the resist pattern for forming the sub scale marks (see FIG. 8C).

In the next step T13, the resist is removed (see FIG. 8D). As a result, the sub scale marks of the first alignment marks, the sub scale marks of the second alignment marks, and the sub scale marks of the positional difference detection marks are generated. The sub scale marks of the respective alignment marks are formed with the impurity layers 35B. The sub scale marks of the respective positional difference detection marks are also formed with impurity layers.

As a result, the main scale marks and the sub scale marks of the first alignment marks, the main scale marks and the sub scale marks of the second alignment marks, and the main scale marks and the sub scale marks of the positional difference detection marks are generated in the wafer 200.

Note that, in the resist pattern that is used in the mark formation process, the resist for forming the main scale marks may be a negative resist so that protrusions are formed as the main scale marks, or the resist for forming the sub length marks may be a negative resist so that protrusions are formed as the sub scale marks.

Alternatively, instead of the above example mark layout, the example mark layout described below may be adopted, for example. In this example mark layout, of the ten marks 35 formed along the outer periphery of the pixel region 10, the center marks 35-3 and 35-8 are the positional difference detection marks (the second example configuration of the positional difference detection marks shown in FIG. 39) for detecting a positional difference between the latent image formed in the left half and the latent image formed in the right half of the exposure region. Further, in this example mark layout, the marks 35-1, 35-2, 35-6, and 35-7 formed in the left half of the exposure region are the positional difference detection marks (the first example configuration of a positional difference detection mark shown in FIG. 38) for detecting a positional difference between the latent image formed in the left half of the exposure region of an unexposed layer (the upper layer) and the latent image formed in the left half of the exposure region of an exposed layer (the lower layer). Further, in this example mark layout, the marks 35-4, 35-5, 35-9, and 35-10 formed in the right half of the exposure region are the positional difference detection marks (the first example configuration of a positional difference detection mark shown in FIG. 38) for detecting a positional difference between the latent image formed in the right half of the exposure region of an unexposed layer (the upper layer) and the latent image formed in the right half of the exposure region of an exposed layer (the lower layer).

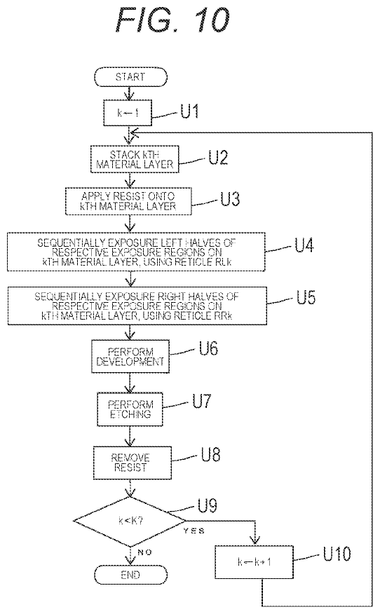

In the description below, the “element/wiring-line process” mentioned above is explained with reference to a flowchart shown in FIG. 10.

In the first step U1, k is set at 1.

In the next step U2, the kth material layer (a semiconductor film, an insulating film, or the like, for example) is stacked. Here, k represents the order of a material layer to be stacked on the wafer 200 (more precisely, an insulating film formed on the wafer 200). That is, the first material layer is the layer that is first stacked on the insulating film formed on the wafer 200.

Here, the kth material layer to be stacked on the front surface side (one surface side) of the wafer 200 is the semiconductor film to be the material of the semiconductor substrate 24 when 1≤k≤x, and is the insulating film to be the interlayer insulating film 27 when k is between (x+1) and (x+4), for example. Further, the kth material to be stacked on the back surface side (the other surface side) of the wafer 200 after the wafer 200 is reversed is the color filter material to be the color filters 32 when k=x+5, and is the lens material to be the on-chip lenses 33 when k=x+6.

In the next step U3, a resist is applied onto the kth material layer.

In the next step U4, the left halves of the respective exposure regions on the kth material layer are sequentially exposed with a reticle RLk. The reticle RLk has a light shielding pattern (or a light transmitting pattern) for forming one layer of the left half of the pixel region 12 and/or one layer of the left half of the circuit region 19.

Specifically, the reticle stage 1 on which the reticle RLk is placed and the wafer stage on which the wafer 200 is placed are moved relatively to each other, to perform aligning so that the reticle RLk and the left half of the exposure region face each other. Here, the reticle RLk and the left half of the exposure region are aligned with each other, on the basis of the position information about the first alignment marks measured in the mark formation process described above. After that, a positional difference between the reticle RLk and the left half of the exposure region is detected on the basis of the position information about the positional difference detection marks measured in the mark formation process. The relative positions of the reticle stage 1 and the wafer stage are then adjusted on the basis of the detection result, so that the positional difference is corrected.

After that, the left half of the exposure region is irradiated with exposure light emitted from the light source through the reticle RLk and the projection optical system. As a result, a latent image of one layer of the left half of the pixel region 12 and/or one layer of the left half of the circuit region 19 is formed.

A series of operations as described above are sequentially performed for each exposure region.

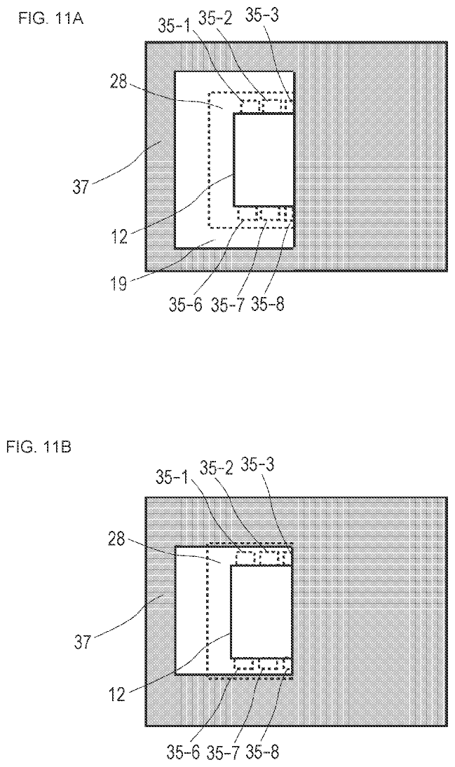

FIG. 11A is a process diagram showing a state in which the left half of the exposure region is exposed when the kth material layer includes the region to be one layer of the pixel region 12 and the region to be one layer of the circuit region 19. In FIG. 11A, the white portion indicates the left half of the exposure region.

FIG. 11B is a process diagram showing a state in which the left half of the exposure region is exposed when the kth material layer includes only the region to be one layer of the pixel region 12. In FIG. 11B, the white portion indicates the left half of the exposure region.

In FIG. 11B, the kth material layer does not include the region to be one layer of the circuit formation 19, and each mark 35 is formed in the intermediate region 28. As can be seen from this, the left half of the exposure region can be made smaller than the left half of the exposure region in FIG. 11A.

In the next step U5, the right halves of the respective exposure regions on the kth material layer are sequentially exposed with a reticle RRk. The reticle RRk has a light shielding pattern (or a light transmitting pattern) for forming one layer of the right half of the pixel region 12 and/or one layer of the right half of the circuit region 19.

Specifically, the reticle stage 2 on which the reticle RRk is placed and the wafer stage on which the wafer 200 is placed are moved relatively to each other, to perform aligning so that the reticle RRk and the right half of the exposure region face each other. Here, the reticle RRk and the right half of the exposure region are aligned with each other, on the basis of the position information about the second alignment marks measured in the mark formation process. After that, a positional difference between the reticle RRk and the right half of the exposure region is detected on the basis of the position information about the positional difference detection marks measured in the mark formation process. The relative positions of the reticle stage 2 and the wafer stage are then adjusted on the basis of the detection result, so that the positional difference is corrected.

After that, the right half of the exposure region is irradiated with exposure light emitted from the light source through the reticle RRk and the projection optical system. As a result, a latent image for forming one layer of the right half of the pixel region 12 and/or one layer of the right half of the circuit region 19 is formed.

A series of operations as described above are sequentially performed for each exposure region.

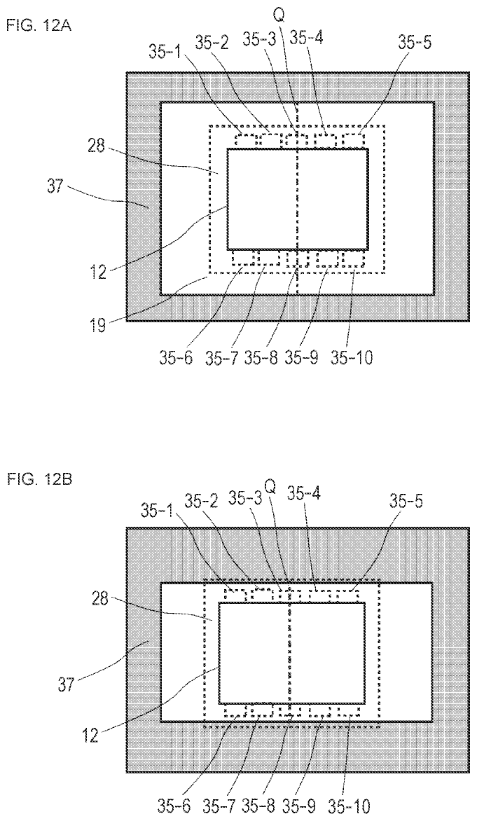

FIG. 12A is a process diagram showing a state in which the right half of the exposure region is exposed when the kth material layer includes the region to be one layer of the pixel region 12 and the region to be one layer of the circuit region 19. In FIG. 12A, the white portion indicates the exposure region.

FIG. 12B is a process diagram showing a state in which the right half of the exposure region is exposed when the kth material layer includes only the region to be one layer of the pixel region 12. In FIG. 12B, the white portion indicates the exposure region.

In FIG. 12B, the kth material layer does not include the region to be one layer of the circuit formation 19, and each mark 35 is formed in the intermediate region 28. As can be seen from this, the exposure region can be made smaller than the exposure region in FIG. 12A.

In the next step U6, development is performed.

Specifically, the latent image formed on the resist on the kth material layer is developed with a developer, to form a resist pattern for generating one layer of the pixel region 12 and/or one layer of the circuit region 19.

In the next step U7, etching is performed. Specifically, etching is performed on the kth material layer, the mask being the resist pattern formed in step U6. As a result, one layer of the pixel region 12 and/or one layer of the circuit region 19 are generated.

In the next step U8, the resist is removed. As a result, one layer of the pixel region 12 and/or one layer of the circuit region 19 are exposed.

In the next step U9, a check is made to determine whether or not k<K. Here, K indicates the total number of material layers to be stacked on the wafer. That is, the Kth material layer is the material layer to be stacked on the wafer at the end. If the determination result here is positive, the process moves on to step U10. If the determination result here is negative, the flow comes to an end.

In step U10, k is incremented. After step U10 is carried out, the process returns to step U2.

By the device formation process described above, the chips of a plurality of solid-state imaging devices 11 are integrally generated in series.

After that, in the plurality of solid-state imaging devices 11 that is integrally formed in series, the scribe lines to be the outer peripheries of scribe regions are formed in a scribing process during the process after the semiconductor manufacturing process. Cutting is then performed along the scribe lines in a dicing process (devices are separated from one another), and thus, chip-like individual solid-state imaging devices 11 are obtained.

Note that the device formation process shown in FIG. 5 includes the mark formation process for forming only the marks 35, which is a so-called zero-layer process, and the element/wiring-line formation process for forming the elements and the wiring lines. However, the element formation and/or the wiring line formation may be performed at the same time as the mark formation.

For example, the left half of the exposure region on the wafer 200 or on the material layer stacked on the wafer 200 may be exposed with the use of reticles for forming the left half of the pixel region 12 and/or the left half of the circuit region 19 and the marks 35, to simultaneously form latent images for generating the elements and the marks 35.

For example, the right half of the exposure region on the wafer 200 or on the material layer stacked on the wafer 200 may be exposed with the use of reticles for forming the right half of the pixel region 12 and/or the right half of the circuit region 19 and the marks 35, to simultaneously form latent images for generating the elements and the marks 35.

However, in the device formation process, the marks 35 can be used for aligning (joining, or superimposing) at a time of exposure of a larger number of material layers, if the timing to form the marks 35 is closer to the initial stage.

(4) Effects of the Method for Manufacturing the Solid-State Imaging Device

The above-described method for manufacturing the solid-state imaging device 11 according to the first embodiment of the present technology is a method for manufacturing a solid-state imaging device having the substrate 21 that includes the pixel region 12 in which the pixels 18 including the photoelectric conversion units 31 are arrayed, and the circuit region 19 formed around the pixel region 12.

According to a first aspect, the method for manufacturing the solid-state imaging device 11 includes a divided exposure process in which an exposure region on the wafer 200 (a semiconductor substrate) as a portion of the substrate 21 or on a material layer stacked on the wafer 200 is divided into a plurality of regions, and each of the divided regions is exposed separately. The divided exposure process includes a first exposure process for exposing one region (the left half of the exposure region, for example; the same applies in the description below) of the plurality of regions, using a first reticle (the reticle RL or RL′, for example) having a first mark formation pattern for forming the respective main scale marks of a plurality of first marks (the first alignment marks 35-1, 35-2, 35-6, 35-7, and 35-8, and the left halves of the positional difference detection marks 35-3 and 35-8; the same applies in the description below) in the intermediate region 28 between the pixel region 12 and the circuit region 19. The method for manufacturing the solid-state imaging device 11 further includes: an aligning process for aligning a second reticle (the reticle RR or RR′, for example) and another region (the right half of the exposure region; the same applies in the description below) of the plurality of regions on the basis of at least a portion of each first mark, the second reticle having a second mark formation pattern for forming a plurality of second marks (the second alignment marks 35-4, 35-5, 35-9, and 35-10, and the right halves of the positional difference detection marks 35-3 and 35-8; the same applies in the description below) in the intermediate region 28 between the pixel region 12 and the circuit region 19; and a second exposure process for exposing the another region, using the second reticle.

In this case, the first reticle may have a pattern for forming a portion of the pixel region 12 and/or a portion of the circuit region 19, and the second reticle may have a pattern for forming the other portion of the pixel region 12 and/or the other portion of the circuit region.

By the method for manufacturing the solid-state imaging device 11 according to the first aspect, the second reticle and the another region of the exposure region are aligned with each other on the basis of a portion of the first alignment marks, and thus, alignment accuracy can be increased. As a result, the accuracy of joining the latent image corresponding to the pattern of the first reticle formed in the one region of the exposure region to the latent image corresponding to the pattern of the second reticle formed in the another region of the exposure region is increased, and thus, the quality of the pixel region 12 can be enhanced.

According to a second aspect, the above-described method for manufacturing the solid-state imaging device 11 according to the first embodiment of the present technology also provides a semiconductor device manufacturing method that includes: a first exposure process for exposing an exposure region on the wafer 200 (a silicon substrate, for example) as a portion of the substrate 21 or on a material layer stacked on the wafer 200, using a first reticle having a mark formation pattern for forming the marks 35 in the intermediate region 28 between the pixel region 12 and the circuit region 19; a process for stacking another material layer on the wafer 200 or on the material layer; an aligning process for aligning a second reticle having a pattern for forming a portion of the pixel region 12 and/or a portion of the circuit region 19 with the corresponding exposure region of the another material layer, on the basis of at least a portion of the marks 35; and a second exposure process for exposing the exposure region of the another material layer, using the second reticle.

In this case, the first reticle may have a pattern for forming the other portion of the pixel region 12 and/or the other portion of the circuit region 19.

By the method for manufacturing the solid-state imaging device 11 according to the second aspect, the exposure region, which corresponds to the exposure region of the material layer, of the another material layer stacked on the material layer is aligned with the second reticle, on the basis of at least a portion of the marks 35. Thus, the alignment accuracy can be increased. As a result, the accuracy of superimposition between the latent image patterns formed in the exposure region is increased, and thus, the quality of the pixel region 12 can be enhanced.

(5) Effects of the Solid-State Imaging Device

The solid-state imaging device 11 according to the first embodiment of the present technology described above has the substrate 21 including the pixel region 12 in which the pixels 18 including the photoelectric conversion units 31 are arrayed, and the circuit region 19 formed around the pixel region 12. In the intermediate region 28 that is a region between the pixel region 12 and the circuit region 19, at least one mark to be used during the exposure process at the time of manufacture of the semiconductor device and/or at least one mark 35 to be used during the semiconductor device inspection process are formed.

As a result, during the exposure process at the time of manufacture and/or the inspection process, the exposure process at the time of manufacture and/or the inspection process can be performed with reference to the marks 35. Thus, the quality of the pixel region 12 can be increased (for example, the accuracy of layout formation in the pixel region 12 can be increased).

On the other hand, in a case where the marks are formed in the scribe region, for example, the distances between the pixel region and the marks are long. Therefore, due to the influence of a layout difference or the like in the periphery of the pixel region, the accuracy of a mark measurement result to be the reference for forming the pixel region is low, and it is difficult to increase the quality of the pixel region.

Further, as each mark 35 is formed in the intermediate region 28, the space in which the marks are to be formed can be eliminated from the scribe region. In this case, the chip size can be reduced, and accordingly, an increase in the yield can be achieved. Also, the pixel region 12 can be made larger, and thus, the number of pixels can be increased. Furthermore, the circuit region 19 can be made larger, and thus, an increase in function and the like can be achieved.

Further, the line-width measurement marks formed at positions closer to the pixel region 12 are used during the process in which the pixels 18 cannot be directly measured after the exposure due to the influence of resist shrinkage. Thus, compensation accuracy can be increased.

Furthermore, as the marks 35 are formed at positions close to the pixel region 12, information about the positions close to the pixel region 12 can also be acquired at times of divided exposure, superimposed exposure, line-width measurement, and thickness measurement after processing. In this case, it is possible to increase the joining accuracy when latent images of the pixel region 12 are formed by divided exposure. It is possible to increase the superimposition accuracy when the pixel region 12 is generated by superimposed exposure. Also, as the line-width measurement and the thickness measurement are performed at positions close to the pixel region, it is possible to obtain measurement results closer to the quality of the pixel region. Thus, increases in the line width accuracy and the thickness accuracy can be expected.

Furthermore, as the marks 35 are formed at positions close to the pixel region 12, the number of divisions when divided exposure is performed on an exposure region can be reduced, and the number of times joining is performed can be reduced. Thus, the influence of the joint characteristics can be made smaller.

Also, as the marks 35 are formed in the intermediate region 28, the marks 35 do not interfere with the circuit design as much as in a case where the marks 35 are formed in the circuit region, for example.

Further, as the marks 35 are formed at positions close to the pixel region 12, the exposure region can be made significantly smaller, particularly in an exposure process for forming a latent image of only one layer of the pixel region 12.

The substrate 21 has a structure in which the semiconductor substrate 24 having the photoelectric conversion units 31 and the circuit region 19 formed therein, and the wiring layer 25 are stacked. The intermediate region 28 includes a first region between the photoelectric conversion units 31 and the circuit region 19 in the semiconductor substrate 24, and a second region corresponding to the first region in the wiring layer 25. The marks 35 are formed in the first region and/or the second region.

With this arrangement, it is possible to form the pixel region 12 and a region corresponding to the pixel region 12 in the wiring layer 25, on the basis of at least one mark of the marks 35 formed in the first region and/or the second region. Thus, it is possible to increase the quality of the pixel region 12 and the region corresponding to the pixel region 12 in the wiring layer 25.

The at least one mark may be a plurality of marks, and the plurality of marks may be formed along the outer periphery of the pixel region 12 in the first region.

With this arrangement, a plurality of marks of the same kind and/or a plurality of marks of different kinds can be efficiently formed in the intermediate region 28.

The at least one mark may be a plurality of marks, and the plurality of marks may be formed along the outer periphery of the region corresponding to the pixel region 12 in the wiring layer 25 in the second region.

With this arrangement, a plurality of marks of the same kind and/or a plurality of marks of different kinds can be efficiently formed in the intermediate region 28.

The present technology also provides an electronic apparatus (a camera 2000, for example) that includes the solid-state imaging device 11.

Including the solid-state imaging device 11 having the high-quality pixel region 12, the electronic apparatus in this case can improve the image quality of output images.

4. <Solid-State Imaging Devices According to First to Fourth Modifications of the First Embodiment of the Present Technology>

The solid-state imaging device 11 according to the first embodiment can be modified in various manners as described below.

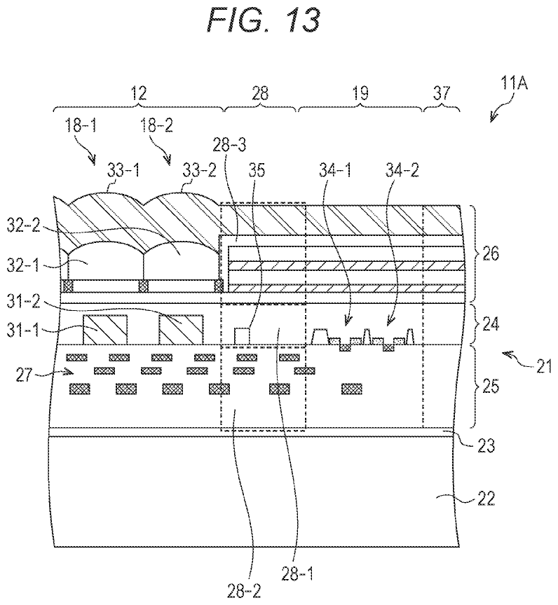

As in a solid-state imaging device 11A according to a first modification of the first embodiment shown in FIG. 13, marks 35 may be formed on the lower surface (front surface) side of the semiconductor substrate 24 in the first region 28-1, which is a region in the semiconductor substrate 24 in the intermediate region 28. Also, marks 35 may be formed at positions between the lower surface (front surface) and the upper surface (back surface) of the semiconductor substrate 24 in the first region 28-1 of the intermediate region 28.

In the solid-state imaging device 11 according to the first embodiment, the marks 35 are formed in the first region 28-1, which is a region in the semiconductor substrate 24 in the intermediate region 28. However, in addition to or instead of these marks 35, marks 35 may also be formed in at least either the second region 28-2, which is a region in the wiring layer 25 in the intermediate region 28, or the third region 28-3, which is a region in the light condensing layer 26 in the intermediate region 28.

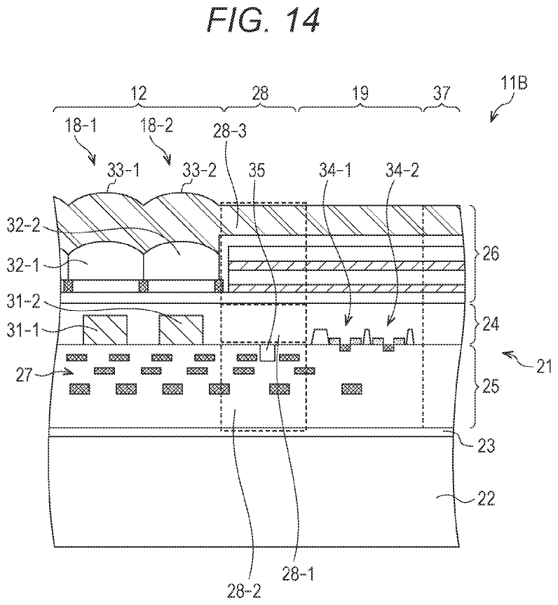

For example, as in a solid-state imaging device 11B according to a second modification of the first embodiment shown in FIG. 14, marks 35 may be formed in the second region 28-2 of the intermediate region 28.

In FIG. 13, the marks 35 are formed on the upper surface side of the wiring layer 25 in the second region 28-2. However, the marks 35 may be formed on the lower surface side of the wiring layer 25 in the second region 28-2, or may be formed at positions between the upper surface and the lower surface of the wiring layer 25 in the second region 28-2.

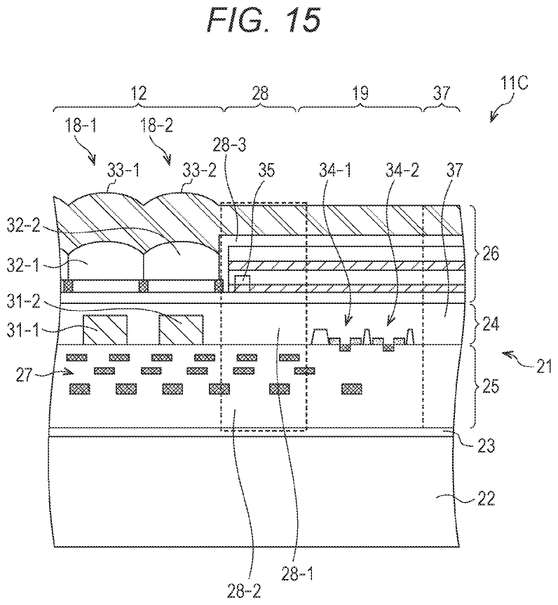

For example, as in a solid-state imaging device 11C according to a third modification of the first embodiment shown in FIG. 15, marks 35 may be formed in the color filter layer in the third region 28-3 of the intermediate region 28.

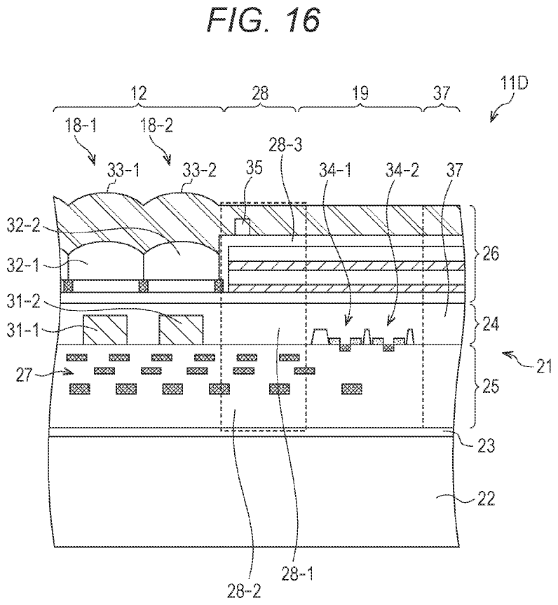

For example, as in a solid-state imaging device 11D according to a fourth modification of the first embodiment shown in FIG. 16, marks 35 may be formed in the lens layer in the third region 28-3 of the intermediate region 28.

It is also possible to provide a solid-state imaging device having a mark layout that is a combination of the mark layouts in the solid-state imaging devices of the above first embodiment and the above first to fourth modifications.

In a case where a plurality of marks 35 is formed in the second region 28-2 in the above modifications, the plurality of marks 35 may be formed side by side along the outer periphery of the region corresponding to the pixel region 12 in the wiring layer 25.

In a case where a plurality of marks 35 is formed in the third region 28-3, the plurality of marks 35 may be formed side by side along the outer periphery of the region corresponding to the pixel region 12 in the light condensing layer 26.

As described above, there are many patterns (combinations) of formation of the marks 35 in the layers of the intermediate region 28. However, the layer of the solid-state imaging device in which the marks 35 are to be formed can be appropriately changed as necessary.

Further, the plurality of marks 35 to be formed in the intermediate region 28 may be a plurality of marks 35 including alignment marks and line-width measurement marks. In the exposure process in this case, the exposure line width (the line width of exposure light) when the exposure region is exposed and/or when an exposure region on another material layer is exposed may be adjusted with reference to the line-width measurement marks.

Also, the plurality of marks 35 to be formed in the intermediate region 28 may be a plurality of marks including alignment marks, positional difference detection marks, and line-width measurement marks. In this case, after aligning of a reticle and the exposure region, and before the exposure process, a positional difference between the reticle and the exposure region may be detected on the basis of at least one of the positional difference detection marks formed in the intermediate region 28, and the positional difference between the reticle and the exposure region may be corrected. In the exposure process in this case, the exposure line width at the time of exposure of the exposure region and/or at the time of exposure of an exposure region on another material layer may be adjusted with reference to the line-width measurement marks.

In the description below, a plurality of other embodiments will be explained. However, in each embodiment described below, components having the same configurations and the functions as those of the solid-state imaging device 11 according to the first embodiment described above are denoted by the same reference numerals as those used in the first embodiment, and explanation thereof will not be repeated below. Instead, aspects that are different from the first embodiment described above will be explained mainly. The solid-state imaging devices according to the embodiments and the modifications described below can be manufactured by a manufacturing method similar to the above-described method for manufacturing the solid-state imaging device 11.

5. <Solid-State Imaging Device According to a Second Embodiment of the Present Technology>

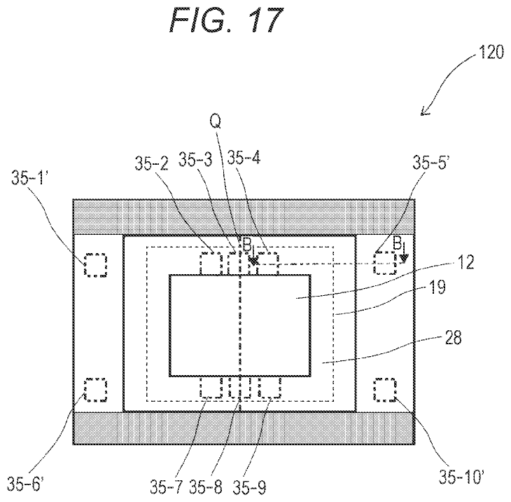

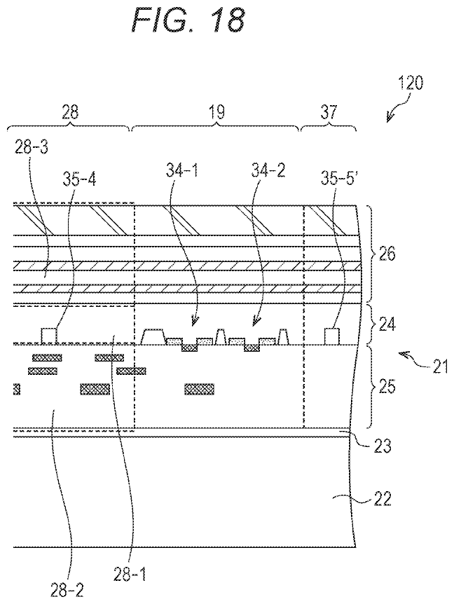

In the description below, a solid-state imaging device 120 according to a second embodiment is explained with reference to FIGS. 17 and 18. FIG. 17 is a plan view schematically showing the solid-state imaging device 120. FIG. 18 is a cross-sectional view taken along line B-B defined in FIG. 17.

The solid-state imaging device 120 has a configuration similar to that of the solid-state imaging device 11 of the first embodiment, except for the mark layout.

As shown in FIGS. 17 and 18, in the solid-state imaging device 120, a portion of the plurality of marks 35 is formed in the first region 28-1 of the intermediate region 28, and the other portions of the plurality of marks 35 are formed in the semiconductor substrate 24 in a scribe region 37.

Specifically, as shown in FIG. 17, the solid-state imaging device 120 has a mark layout in which, of the marks 35 formed along the outer periphery of the pixel region 12 of the solid-state imaging device 11 of the first embodiment shown in FIG. 2B, the alignment marks formed near the four corners of the pixel region 12 are moved into the scribe region 37, in a plan view.

More specifically, in the solid-state imaging device 120, four first alignment marks 35-1′, 35-2, 35-6′, and 35-7 are formed at the four vertices of a rectangle in the left-half region of an exposure region 150 in a plan view, as shown in FIG. 17, for example. Four second alignment marks 35-4, 35-5′, 35-9, and 35-10′ are formed at the four vertexes of a rectangle in the right-half region in a plan view.

In the solid-state imaging device 120, it is necessary to form marks also in the scribe region 37, and the exposure region at the time of the mark formation becomes larger accordingly (note that, in the example in FIG. 17, both ends of the chip in the lateral direction are non-exposure regions). However, marks 35 can be formed at the four corners of the left half and the four corners of the right half of the exposure region, and thus, the accuracy of alignment between reticles and the left and right halves of the exposure region can be further increased.

Note that the marks 35-1′, 35-5′, 35-6′, and 35-10′ are formed in the semiconductor substrate 24 in the scribe region 37, but may be formed in the wiring layer 25 in the scribe region 37 or in the light condensing layer 26 in the scribe region 37.

6. <Solid-State Imaging Device According to a Modification of the Second Embodiment of the Present Technology>

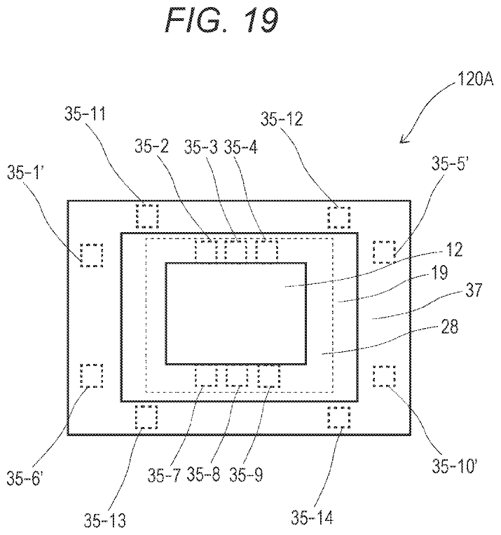

In the description below, a solid-state imaging device 120A according to a modification of the second embodiment is explained with reference to FIG. 19. FIG. 19 is a plan view schematically showing the solid-state imaging device 120A.

Although a cross section of the solid-state imaging device 120A is not shown in any drawing, in addition to the mark layout in the solid-state imaging device 120 of the second embodiment, a first alignment mark 35-11 is formed near one end of one long side of the circuit region 19 in the scribe region 37, and a second alignment mark 35-12 is formed near the other end of the one long side. Further, a first alignment mark 35-13 is formed near one end of the other long side of the circuit region 19 in the scribe region 37, and a second alignment mark 35-14 is formed near the other end of the other long side.

That is, alignment marks are formed so as to be located at vertexes of a hexagon in each of the left and right halves of the exposure region. Thus, the alignment accuracy between reticles and the left and right halves of the exposure region can be further increased.

Note that the marks 35-1′, 35-5′, 35-6′, 35-10′, 35-11, 35-12, 35-13, and 35-14 may be formed in any of the following layers: the semiconductor substrate 24 in the scribe region 37, the wiring layer 25 in the scribe region 37, and the light condensing layer 26 in the scribe region 37.

7. <Solid-State Imaging Device According to a Third Embodiment of the Present Technology>

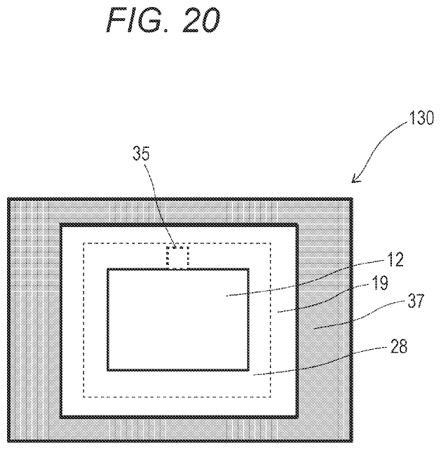

In the description below, a solid-state imaging device 130 according to a third embodiment is explained with reference to FIG. 20. FIG. 20 is a plan view schematically showing the solid-state imaging device 130.

The solid-state imaging device 130 of the third embodiment has a configuration similar to that of the solid-state imaging device 11 of the first embodiment, except for the mark layout (the same applies to modifications of the third embodiment).

In the solid-state imaging device 130, a single mark 35 is formed in one of the first region 28-1, the second region 28-2, and the third region 28-3 of the intermediate region 28 at a position extending over the right half and the left half of the exposure region (see FIGS. 13 to 18).

The chip size of the solid-state imaging device 130 may be a size capable of collective exposure (a smaller size than the exposure range of the exposure device; the same applies in the description below) or a size that requires divided exposure (a larger size than the exposure range of the exposure device; the same applies in the description below). In any case, in the solid-state imaging device 130, a mark 35 is formed only in the intermediate region 28. Thus, the alignment accuracy can be increased, and the exposure region can be made smaller. As a result, the quality of the pixel region 12 can be made higher. Further, in the solid-state imaging device 130, there is one mark 35, and accordingly, the mark formation pattern of a reticle can be simplified.

Furthermore, the mark 35 extends across the right half and the left half of the exposure region. Particularly, when divided exposure is performed on the right half and the left half of the exposure region, the exposure is performed so that the right half and the left half of the mark 35 can be accurately combined. Thus, the accuracy of joining between the right half and the left half of the exposure region can be increased.

8. <Solid-State Imaging Device According to a First Modification of the Third Embodiment of the Present Technology>

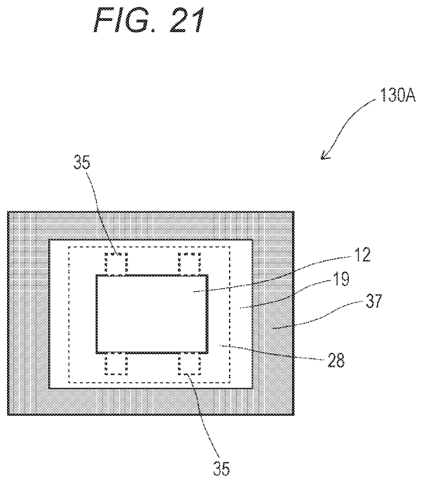

In the description below, a solid-state imaging device 130A according to the third embodiment is explained with reference to FIG. 21. FIG. 21 is a plan view schematically showing the solid-state imaging device 130A.

In the solid-state imaging device 130A, a plurality of (four, for example) marks 35 is formed in one of the first region 28-1, the second region 28-2, and the third region 28-3 of the intermediate region 28 (see FIGS. 13 to 16).

The chip size of the solid-state imaging device 130A may be a size capable of collective exposure (a small type, for example) or a size that requires divided exposure (a medium type or a large type, for example). In any case, in the solid-state imaging device 130A, a plurality of marks 35 is formed only in the intermediate region 28. Thus, the alignment accuracy can be further increased, and the exposure region can be made smaller. As a result, the quality of the pixel region 12 can be made higher. Furthermore, in the solid-state imaging device 130, the mark 35 is formed in the left half and the right half of the exposure region. Thus, the quality of the pixel region 12 can be further enhanced.

9. <Solid-State Imaging Device According to a Second Modification of the Third Embodiment of the Present Technology>

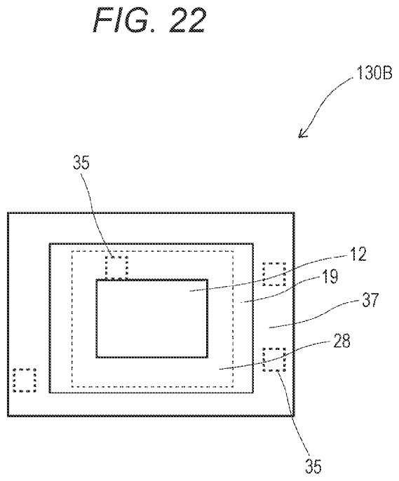

In the description below, a solid-state imaging device 130B according to a second modification of the third embodiment is explained with reference to FIG. 22. FIG. 22 is a plan view schematically showing the solid-state imaging device 130B.

In the solid-state imaging device 130B, a single mark 35 is formed in one of the first region 28-1, the second region 28-2, and the third region 28-3 of the intermediate region 28, and a plurality of (three, for example) marks 35 is formed in one of the semiconductor layer 24, the wiring layer 25, and the light condensing layer 26 in the scribe region 37. (See FIG. 18).

The chip size of the solid-state imaging device 130B may be a size capable of collective exposure or a size that requires divided exposure. In any case, in the solid-state imaging device 130B, marks 35 are formed in both the intermediate region 28 and the scribe region 37. Thus, the quality of the pixel region 12 can be further enhanced.

10. <Solid-State Imaging Device According to a Third Modification of the Third Embodiment of the Present Technology>

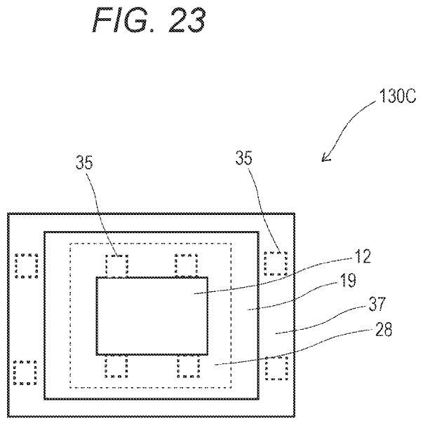

In the description below, a solid-state imaging device 130C according to a third modification of the third embodiment is explained with reference to FIG. 23. FIG. 23 is a plan view schematically showing the solid-state imaging device 130C.

In the solid-state imaging device 130C, a plurality of (four, for example) marks 35 is formed in one of the first region 28-1, the second region 28-2, and the third region 28-3 of the intermediate region 28, and a plurality of (four, for example) marks 35 is formed in one of the semiconductor layer 24, the wiring layer 25, and the light condensing layer 26 in the scribe region 37. (See FIG. 18).

The chip size of the solid-state imaging device 130C may be a size capable of collective exposure or may be a size that requires divided exposure. In any case, in the solid-state imaging device 130B, a plurality of marks 35 is formed in both the intermediate region 28 and the scribe region 37. Thus, the quality of the pixel region 12 can be further enhanced.

11. <Solid-State Imaging Device According to a Fourth Modification of the Third Embodiment of the Present Technology>

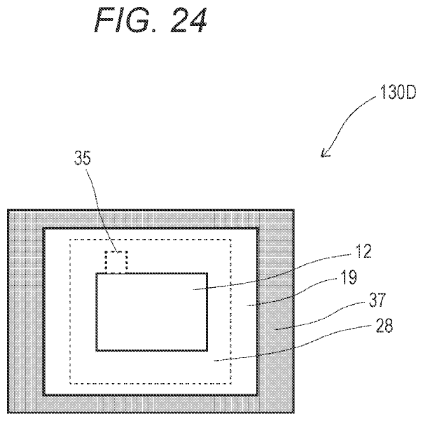

In the description below, a solid-state imaging device 130D according to a fourth modification of the third embodiment is explained with reference to FIG. 24. FIG. 24 is a plan view schematically showing the solid-state imaging device 130D.

In the solid-state imaging device 130D, a single mark 35 is formed in one of the first region 28-1, the second region 28-2, and the third region 28-3 of the intermediate region 28 in the left half or the right half (the left half in FIG. 24) of the exposure region (see FIGS. 13 to 16).

The chip size of the solid-state imaging device 130D may be a size capable of collective exposure or a size that requires divided exposure. In any case, in the solid-state imaging device 130D, a mark 35 is formed only in the intermediate region 28. Thus, the alignment accuracy can be increased, and the exposure region can be made smaller. As a result, the quality of the pixel region 12 can be made higher. Further, in the solid-state imaging device 130D, there is one mark 35, and accordingly, the mark formation pattern of a reticle can be simplified.

12. <Solid-State Imaging Device According to a Fourth Embodiment of the Present Technology>

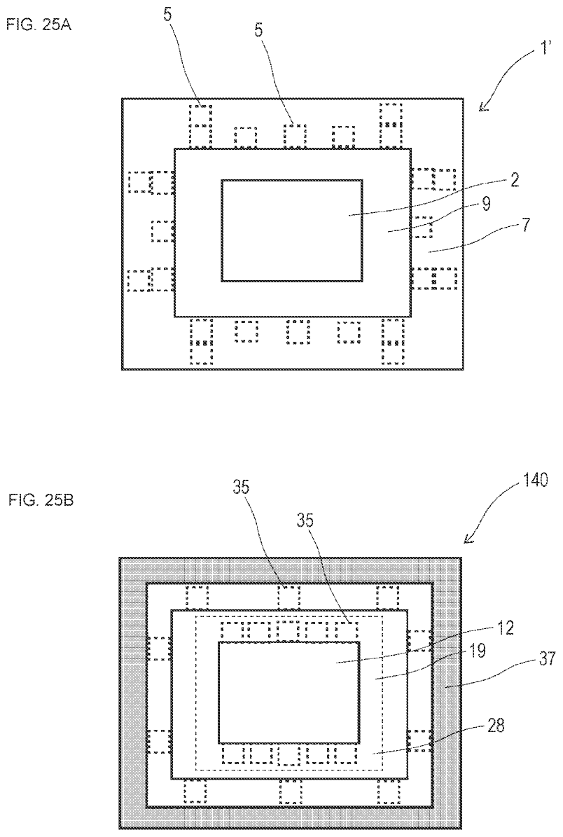

In the description below, a solid-state imaging device 140 according to a fourth embodiment is explained with reference to FIGS. 25A and 25B. FIG. 25A is a plan view schematically showing a solid-state imaging device 1′ according to a second comparative example. FIG. 25B is a plan view schematically showing the solid-state imaging device 140 according to the fourth embodiment.

The solid-state imaging device 140 of the fourth embodiment has a configuration similar to that of the solid-state imaging device 11 of the first embodiment, except for the mark layout.

As shown in FIG. 25A, in the solid-state imaging device 1′ of the second comparative example, marks 5 are formed in both the inner peripheral portion and the outer peripheral portion of the scribe region 7 in a plan view.

As shown in FIG. 25B, in the solid-state imaging device 140 according to the fourth embodiment, marks 35 are formed in the intermediate region 28 and the inner peripheral portion of the scribe region 37 in a plan view.

In the solid-state imaging device 1′, marks 5 are also formed in the outer peripheral portion of the scribe region 7. Therefore, the entire surface serves as the exposure region at least during the exposure process for forming the marks 35.

In the solid-state imaging device 140, on the other hand, no marks 35 are formed in the outer peripheral portion of the scribe region 37. Accordingly, the exposure region can be narrowed at least during the exposure process for forming the marks. Thus, the quality of the pixel region 12 can be enhanced.

13. <Solid-State Imaging Device According to a Fifth Embodiment of the Present Technology>

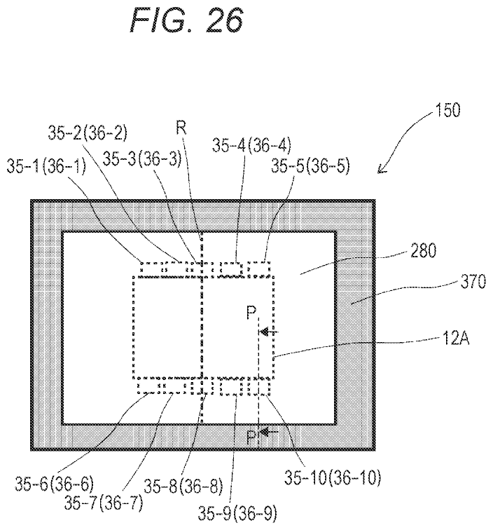

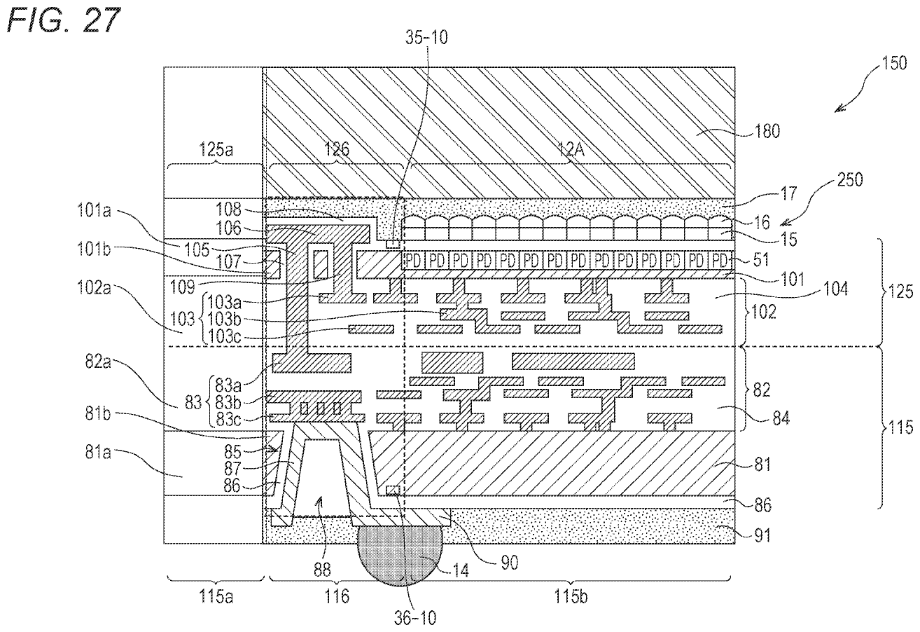

In the description below, a solid-state imaging device 150 according to a fifth embodiment is explained with reference to FIGS. 26 and 27. FIG. 26 is a plan view schematically showing the solid-state imaging device 150 according to the fifth embodiment. FIG. 27 is a plan view (a cross-sectional view taken along the line P-P defined in FIG. 25) showing part of a cross-section of the solid-state imaging device 150 according to the fifth embodiment.

As shown in FIG. 26, the solid-state imaging device 150 has an external shape and a mark layout that are similar to those of the solid-state imaging device 11 of the first embodiment in a plan view.

As shown in FIG. 27, the solid-state imaging device 150 includes a pixel sensor substrate 125 and a logic substrate 115.

The pixel sensor substrate 125 has a structure in which a semiconductor substrate 101 (a silicon substrate) having photoelectric conversion units 51 (PDs, for example) formed therein and a multilevel wiring layer 102 are stacked.

The logic substrate 115 has a structure in which a semiconductor substrate 81 (a silicon substrate) having a logic circuit formed therein and a multilevel wiring layer 82 are stacked. A control circuit may also be formed in the semiconductor substrate 81.

The solid-state imaging device 150 has a stack structure in which the multilevel wiring layer 102 of the pixel sensor substrate 150 and the multilevel wiring layer 82 of the logic substrate 115 are bonded together as a whole. In FIG. 27, the bonding surface between the multilevel wiring layer 82 of the logic substrate 115 and the multilevel wiring layer 102 of the pixel sensor substrate 125 is indicated by a dashed line extending in the in-plane direction.

As described above, the solid-state imaging device 150 is a stack-type image sensor in which two semiconductor substrates (the semiconductor substrate 101 and the semiconductor substrate 51) are stacked.

More specifically, the solid-state imaging device 150 is an image sensor having a so-called wafer-on-wafer (WOW) structure.

The multilevel wiring layer 82 includes a plurality of wiring layers 83 and an interlayer insulating film 84 formed between the respective wiring layers 83. The wiring layers 83 include an uppermost wiring layer 83a closest to the pixel sensor substrate 12, an intermediate wiring layer 83b, a lowermost wiring layer 83c closest to the semiconductor substrate 81, and the like.

The plurality of wiring layers 83 is formed with copper (Cu), aluminum (Al), tungsten (W), or the like, for example. The interlayer insulating film 84 is formed with a silicon oxide film, a silicon nitride film, or the like, for example. The plurality of wiring layers 83 and the interlayer insulating film 84 may be formed with the same material in all the layers, or may be formed with two or more materials in different layers.

The multilevel wiring layer 102 includes a plurality of wiring layers 103 and an interlayer insulating film 104 formed between the respective wiring layers 103. The wiring layers 103 include an uppermost wiring layer 103a closest to the semiconductor substrate 101, an intermediate wiring layer 103b, a lowermost wiring layer 103c closest to the logic substrate 115, and the like.

The material used for the plurality of wiring layers 103 and the interlayer insulating film 104 may be the same as the above-mentioned material of the wiring layers 83 and the interlayer insulating film 84. Also, the plurality of wiring layers 103 and the interlayer insulating film 104 may be formed with one or more materials, like the wiring layers 83 and the interlayer insulating film 84 described above.

Note that, in the example shown in FIG. 26, the multilevel wiring layer 102 of the pixel sensor substrate 12 is formed with three wiring layers 103, and the multilevel wiring layer 82 of the logic substrate 115 is formed with four wiring layers 83. However, the total number of wiring layers is not limited to this, and each multilevel wiring layer can be formed with any appropriate number of wiring layers.

At a predetermined position in the semiconductor substrate 81, a silicon through hole 85 penetrating through the semiconductor substrate 81 is formed, and a connection conductor 87 is buried in the inner wall of the silicon through hole 85 with an insulating film 86 interposed in between, to form a through silicon electrode (through silicon via: TSV) 88. The insulating film 86 may be formed with a SiO₂ film, a SiN film, or the like, for example.

Note that, in the through silicon electrode 88 shown in FIG. 27, the insulating film 86 and the connection conductor 87 are formed along the inner wall surface, and the inside of the silicon through hole 85 is hollow. However, the inside of the through silicon via 85 may be entirely filled with the connection conductor 87, depending on the inner diameter. In other words, the inside of the through hole may be filled with a conductor, or part of the through hole may be hollow. The same applies to a through chip electrode (through chip via: TCV) 105 and the like described later.

The connection conductor 87 of the through silicon electrode 88 is connected to a rewiring line 90 formed on the lower surface side of the semiconductor substrate 81, and the rewiring line 90 is connected to a solder ball 14. The connection conductor 87 and the rewiring line 90 may be formed with copper (Cu), tungsten (W), titanium (Ti), tantalum (Ta), titanium tungsten alloy (TiW), polysilicon, or the like, for example.

Further, on the lower surface side of the semiconductor substrate 81, a solder mask (solder resist) 91 is formed so as to cover the rewiring line 90 and the insulating film 86, except for the region where the solder ball 14 is formed.

Note that the solder ball 14 may be disposed on the side of the pixel sensor substrate 125.

In the semiconductor substrate 101, photodiodes 51 formed with PN junctions are formed for the respective pixels 250.

A through silicon electrode 109 connected to the wiring layer 103a of the pixel sensor substrate 125, and a through chip electrode 105 connected to the wiring layer 83a of the logic substrate 115 are formed at a predetermined position in the semiconductor substrate 101 at which no color filters 15 and no on-chip lenses 16 are formed.

The through chip electrode 105 and the through silicon electrode 109 are connected by a connection wiring line 106 formed in the upper surface of the semiconductor substrate 101. An insulating film 107 is also formed between each of the through silicon electrode 109 and the through chip electrode 105, and the semiconductor substrate 101. Further, on the upper surface of the semiconductor substrate 101, the color filters 15 and the on-chip lenses 16 are formed via an insulating film (a planarizing film) 108.

In the solid-state imaging device 150, each pixel 250 in the pixel region 12A includes a photoelectric conversion unit 51 (a photodiode, for example), a color filter 15, and an on-chip lens 16. The color filter layer in which a plurality of color filters 15 is formed, and the lens layer in which a plurality of on-chip lenses 16 is formed are also collectively referred to as the “light condensing layer”. The color filter 15 and the on-chip lens 16 of each pixel 250 are also collectively referred to as a “light condensing unit”.

Also, the wiring layers 103 of the pixel sensor substrate 125 and the wiring layers 83 of the logic substrate 115 are connected by two through electrodes that are the through silicon electrode 109 and the through chip electrode 105, and the wiring layers 83 of the logic substrate 115 and the solder ball (back electrode) 14 are connected by the through silicon electrode 88 and the rewiring line 90.

Further, the pixel sensor substrate 125 and a glass protective substrate 180 are bonded to each other with a glass sealing resin 17 in a cavity-free structure.

As described above, the mark layout in the solid-state imaging device 150 in a plan view is substantially similar to that of the first embodiment, as shown in FIG. 26. In the solid-state imaging device 150 in a plan view, a plurality of (ten, for example) marks 35 (35-1 to 35-10) is arrayed along the outer periphery of the pixel region 12A of the pixel sensor substrate 125, and a plurality of (ten, for example) marks 36 (36-1 to 36-10) is arrayed along the region corresponding to the pixel region 12A in the logic substrate 115. Here, the ten marks 35 and the ten marks 36 are arranged so as to overlap in a vertical direction.

Specifically, in the solid-state imaging device 150, as shown in FIG. 27, a plurality of (ten, for example) marks 35 (only the mark 35-10 is shown in FIG. 27) is formed in a first region 126 that is a region between a first scribe region 125a serving as a scribe region in the pixel sensor substrate 125 and the pixel region 12A having the photoelectric conversion units 51 formed therein. Also, in the solid-state imaging device 150, a plurality of (ten, for example) marks 36 (only the mark 36-10 is shown in FIG. 27) is formed in a second region 116 that is a region between a second scribe region 115a serving as a scribe region in the logic substrate 115 and a region 115b corresponding to the pixel region 12A in the logic substrate 115.

At least either wiring lines or circuit elements are formed in the first region 126.

Note that neither wiring lines nor circuit elements may be formed in the first region 126.

At least either wiring lines or circuit elements are formed in the second region 116.

Note that neither wiring lines nor circuit elements may be formed in the second region 116.

Each mark 35 is an alignment mark herein, but may be a positional difference detection mark or a line-width measurement mark.

Each mark 36 is an alignment mark herein, but may be a positional difference detection mark or a line-width measurement mark.

In the semiconductor substrate 101 in the solid-state imaging device 150, the plurality of marks 35 is formed in the first region 126 on the upper surface (back surface) side of the semiconductor substrate 101. As a result, with reference to the plurality of marks 35, the respective material layers are formed on the wafer that is the material of the semiconductor substrate 101, so that the elements (such as the photoelectric conversion units 51, the color filters 15, and the on-chip lenses 16) and the wiring lines 103 of the multilevel wiring layer 102 can be formed. Further, with reference to the plurality of marks 35, the pixel sensor substrate 125 and the logic substrate 115 can be bonded to each other.

Note that the plurality of marks 35 may be formed in the first region 126 between the upper surface (back surface) and the lower surface (front surface) of the semiconductor substrate 101. In this case, with reference to the plurality of marks 35, the material layers are formed on the wafer that is the material of the semiconductor substrate 101, so that the elements (such as part of the photoelectric conversion units 51, the color filters 15, and the on-chip lenses 16) and the wiring lines 103 of the multilevel wiring layer 102 can be formed. Further, with reference to the plurality of marks 35, the pixel sensor substrate 125 and the logic substrate 115 can be bonded to each other.

Alternatively, in the semiconductor substrate 101, the plurality of marks 35 may be formed in the first region 126 on the lower surface (front surface) side of the semiconductor substrate 101. In this case, with reference to the plurality of marks 35, the material layers are formed on the wafer that is the material of the semiconductor substrate 101, so that the elements (such as the color filters 15 and the on-chip lenses 16) and the wiring lines 103 of the multilevel wiring layer 102 can be formed. Further, with reference to the plurality of marks 35, the pixel sensor substrate 125 and the logic substrate 115 can be bonded to each other.

In the semiconductor substrate 81 in the solid-state imaging device 150, the plurality of marks 36 is formed in the second region 116 on the lower surface (front surface) side of the semiconductor substrate 81. As a result, with reference to the plurality of marks 35, the respective material layers are formed on the wafer that is the material of the semiconductor substrate 81, so that the elements (the circuit elements of the logic circuit) and the wiring lines 83 of the multilevel wiring layer 82 can be formed. Further, with reference to the plurality of marks 35, the pixel sensor substrate 125 and the logic substrate 115 can be bonded to each other.

Note that the plurality of marks 36 may be formed in the second region 116 between the upper surface (back surface) and the lower surface (front surface) of the semiconductor substrate 81. In this case, with reference to the plurality of marks 36, the material layers are formed on the wafer that is the material of the semiconductor substrate 81, so that the elements (part of the circuit elements of the logic circuit) and the wiring lines 83 of the multilevel wiring layer 82 can be formed. Further, with reference to the plurality of marks 36, the pixel sensor substrate 125 and the logic substrate 115 can be bonded to each other.

Alternatively, in the semiconductor substrate 81, the plurality of marks 36 may be formed in the second region 116 on the upper surface (back surface) side of the semiconductor substrate 81. In this case, with reference to the plurality of marks 36, the material layers are formed on the wafer that is the material of the semiconductor substrate 81, so that the wiring lines 103 of the multilevel wiring layer 102 can be formed. Further, with reference to the plurality of marks 36, the pixel sensor substrate 125 and the logic substrate 115 can be bonded to each other.

Each mark 35 is formed in the first region 126 at a position closer to the pixel region 12A than to the first scribe region 125a. With this arrangement, the quality of the pixel region 12 can be further enhanced.

Note that each mark 35 may be formed in the first region 126 at a position farther from the pixel region 12A than from the first scribe region 125a, or may be formed in the first region 126 at a position between the first scribe region 125a and the pixel region 12A.

Each mark 36 is formed in the second region 116 at a position closer to the region 115b corresponding to the pixel region 12A in the logic substrate 115, than to the second scribe region 115a.

Note that each mark 36 may be formed in the second region 116 at a position farther from the region 115b corresponding to the pixel region 12A than from the second scribe region 115a, or may be formed in the second region 116 at a position between the second scribe region 115a and the region 115b corresponding to the pixel region 12A.

The pixel region 12A includes the photoelectric conversion region in which the photoelectric conversion units 51 of the semiconductor substrate 101 are formed, and the region of the multilevel wiring layer 102 that corresponds to the photoelectric conversion region.

The first scribe region 125a includes a scribe region 101a of the semiconductor substrate 101 and a scribe region 102a of the multilevel wiring layer 102.

The second scribe region 115a is the scribe region corresponding to the first scribe region 125a (having the same position in the in-plane direction).

The second scribe region 115a includes a scribe region 81a of the semiconductor substrate 81 and a scribe region 82a of the multilevel wiring layer 82.

In the description below, a method for manufacturing the solid-state imaging device 150 is briefly explained. First, a plurality of pixel sensor substrates 125 is formed on one wafer by a manufacturing method substantially similar to the method for manufacturing the solid-state imaging device 11 described above, and is then cut along scribe lines and separated. Also, a plurality of logic substrates 115 is formed on one wafer by a manufacturing method substantially similar to the above-described method for manufacturing the solid-state imaging device 11, and is then cut along scribe lines and separated.

Next, the pixel sensor substrate 125 and the logic substrate 115 are bonded to each other so that the wiring layer 102 and the wiring layer 82 are joined to each other.

After that, processing such as annealing is performed, to obtain the chip-like solid-state imaging device 150.

Note that the plurality of pixel substrates 125 integrally formed in series on the wafer, and the plurality of logic substrates 115 integrally formed in series on the wafer may be bonded together, and be then separated into individual chip-like solid-state imaging devices 150.

Note that, in the solid-state imaging device 150, the marks are formed in both the pixel sensor substrate 125 and the logic substrate 115. However, the marks may be formed in only one of the substrates.

14. <Solid-State Imaging Device According to a First Modification of the Fifth Embodiment of the Present Technology>

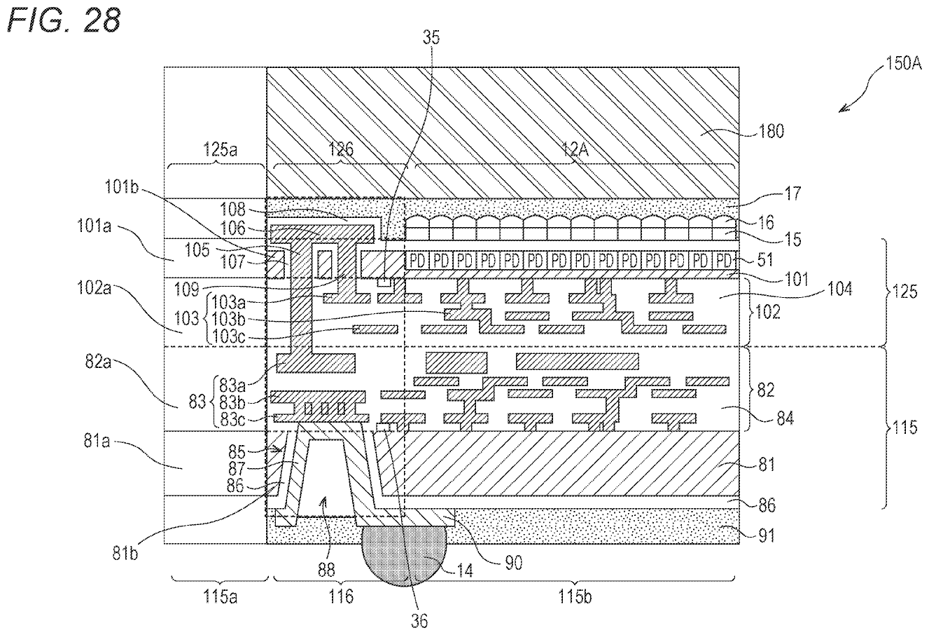

In the description below, a solid-state imaging device 150A according to a first modification of the fifth embodiment is explained with reference to FIG. 28. FIG. 28 is a view (corresponding to the P-P cross-sectional view in FIG. 27) showing part of a cross-section of the solid-state imaging device 150A according to the first modification of the fifth embodiment. The mark layout in a plan view of the solid-state imaging device 150A is similar to the mark layout in a plan view of the solid-state imaging device 150 (see FIG. 26).

The solid-state imaging device 150A has a configuration substantially similar to that of the solid-state imaging device 150, except for the mark layout in a cross-section.

In the solid-state imaging device 150A, marks 35 are formed in the multilevel wiring layer 102 in the first region 126, and marks 36 are formed in the multilevel wiring layer 82 in the second region 116. Each mark 35 is an alignment mark, a positional difference detection mark, or a line-width measurement mark.

Specifically, in the multilevel wiring layer 102, a plurality of marks 35 is formed in the first region 126 on the upper surface side of the multilevel wiring layer 102. As a result, with reference to the plurality of marks 35, the material layers are formed on the wafer that is the material of the semiconductor substrate 101, so that the wiring lines 103 of the multilevel wiring layer 102 can be formed. Further, with reference to the plurality of marks 35, the pixel sensor substrate 125 and the logic substrate 115 can be bonded to each other.

Alternatively, the plurality of marks 35 may be formed in the first region 126 between the upper surface and the lower surface of the multilevel wiring layer 102. In this case, with reference to the plurality of marks 35, the material layers are formed on the wafer that is the material of the semiconductor substrate 101, so that part of the multilevel wiring layer 102 can be formed. Further, with reference to the plurality of marks 35, the pixel sensor substrate 125 and the logic substrate 115 can be bonded to each other.

Alternatively, in the multilevel wiring layer 102, the plurality of marks 35 may be formed in the first region 126 on the lower surface side of the multilevel wiring layer 102. In this case, with reference to the plurality of marks 35, the pixel sensor substrate 125 and the logic substrate 115 can be bonded to each other.

Specifically, in the multilevel wiring layer 82, a plurality of marks 36 is formed in the second region 116 on the upper surface side of the multilevel wiring layer 82. As a result, with reference to the plurality of marks 36, the material layers are formed on the wafer that is the material of the semiconductor substrate 82, so that the wiring lines 83 of the multilevel wiring layer 82 can be formed. Further, with reference to the plurality of marks 36, the pixel sensor substrate 125 and the logic substrate 115 can be bonded to each other.

Alternatively, the plurality of marks 36 may be formed in the second region 116 between the upper surface and the lower surface of the multilevel wiring layer 82. In this case, with reference to the plurality of marks 36, the material layers are formed on the wafer that is the material of the semiconductor substrate 81, so that part of the multilevel wiring layer 82 can be formed. Further, with reference to the plurality of marks 36, the pixel sensor substrate 125 and the logic substrate 115 can be bonded to each other.

Alternatively, in the multilevel wiring layer 82, the plurality of marks 36 may be formed in the second region 116 on the lower surface side of the multilevel wiring layer 82. In this case, with reference to the plurality of marks 36, the pixel sensor substrate 125 and the logic substrate 115 can be bonded to each other.

The solid-state imaging device 150A can be manufactured by a manufacturing method substantially similar to the method for manufacturing the solid-state imaging device 150.

15. <Solid-State Imaging Device According to a Second Modification of the Fifth Embodiment of the Present Technology>

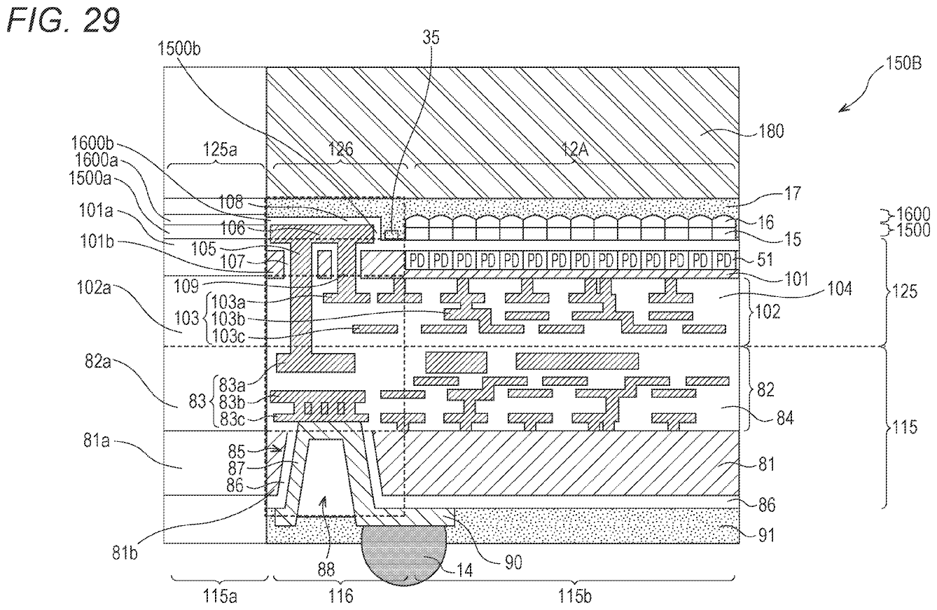

In the description below, a solid-state imaging device 150B according to a second modification of the fifth embodiment is explained with reference to FIG. 29. FIG. 29 is a view (corresponding to the P-P cross-sectional view in FIG. 27) showing part of a cross-section of the solid-state imaging device 150B according to the second modification of the fifth embodiment. The mark layout in a plan view of the solid-state imaging device 150B is similar to the mark layout in a plan view of the solid-state imaging device 150 (see FIG. 26).

The solid-state imaging device 150B has a configuration substantially similar to that of the solid-state imaging device 150, except for the mark layout in a cross-section.

In the solid-state imaging device 150B, marks 35 are formed in a region in a color filter layer 1500 in the first region 126, no color filters 15 being formed in the region, the color filter layer 1500 including the plurality of color filters 15. The marks 35 are alignment marks, positional difference detection marks, or line-width measurement marks.

In the solid-state imaging device 150B, with reference to a plurality of marks 35 formed in the color filter layer 1500, the pixel sensor substrate 125 and the logic substrate 115 can be bonded to each other.

The solid-state imaging device 150B can be manufactured by a manufacturing method substantially similar to the method for manufacturing the solid-state imaging device 150.

16. <Solid-State Imaging Device According to a Third Modification of the Fifth Embodiment of the Present Technology>

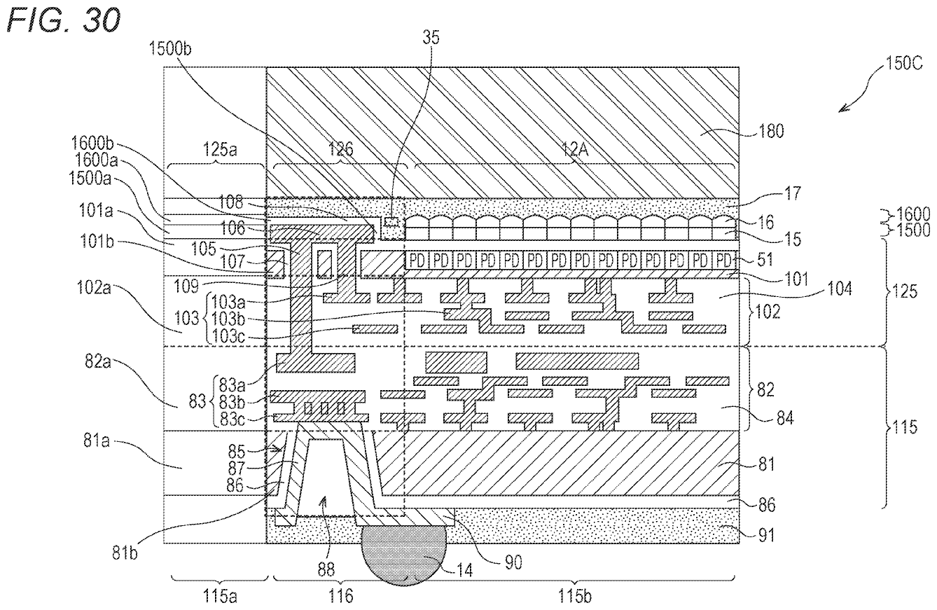

In the description below, a solid-state imaging device 150C according to a third modification of the fifth embodiment is explained with reference to FIG. 30. FIG. 30 is a view (corresponding to the P-P cross-sectional view in FIG. 27) showing part of a cross-section of the solid-state imaging device 150C according to the third modification of the fifth embodiment. The mark layout in a plan view of the solid-state imaging device 150C is similar to the mark layout in a plan view of the solid-state imaging device 150 (see FIG. 26).

The solid-state imaging device 150C has a configuration substantially similar to that of the solid-state imaging device 150, except for the mark layout in a cross-section.

In the solid-state imaging device 150C, a plurality of marks 35 is formed in a region in a lens layer 1600 in the first region 126, no on-chip lenses 16 being formed in the region, the lens layer 1600 including the plurality of on-chip lenses 16. Each mark of the plurality of marks 35 is an alignment mark, a positional difference detection mark, or a line-width measurement mark.

In the solid-state imaging device 150C, with reference to the plurality of marks 35 formed in the lens layer 1600, the pixel sensor substrate 125 and the logic substrate 115 can be bonded to each other.

The solid-state imaging device 150C can be manufactured by a manufacturing method substantially similar to the method for manufacturing the solid-state imaging device 150.

17. <Solid-State Imaging Device According to a Fourth Modification of the Fifth Embodiment of the Present Technology>

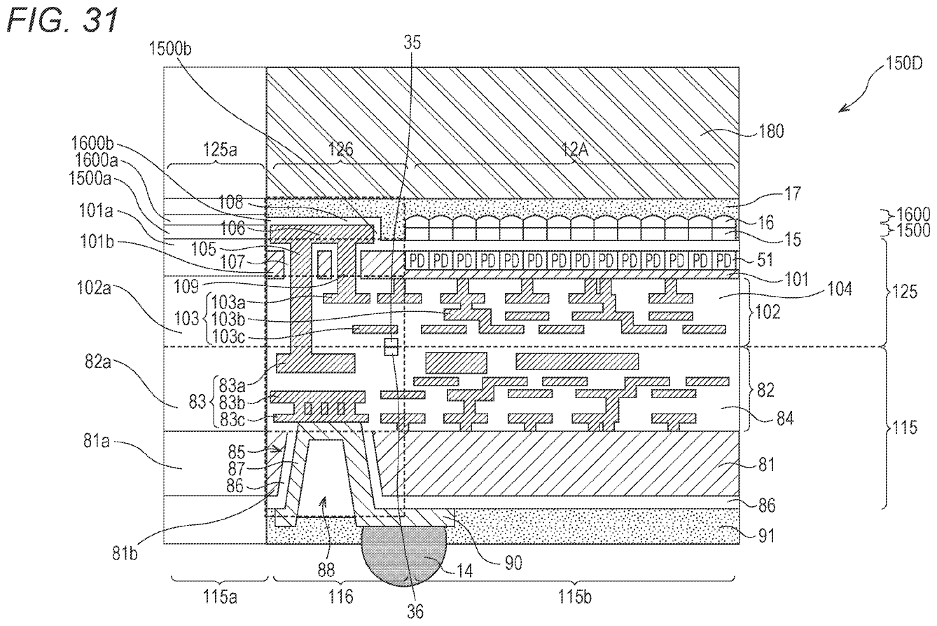

In the description below, a solid-state imaging device 150D according to a fourth modification of the fifth embodiment is explained with reference to FIG. 31. FIG. 31 is a view (corresponding to the P-P cross-sectional view in FIG. 27) showing part of a cross-section of the solid-state imaging device 150D according to the fourth modification of the fifth embodiment. The mark layout in a plan view of the solid-state imaging device 150D is similar to the mark layout in a plan view of the solid-state imaging device 150 (see FIG. 26).

The solid-state imaging device 150D has a configuration substantially similar to that of the solid-state imaging device 150, except for the mark layout in a cross-section.

In the solid-state imaging device 150D, a plurality of marks 35 is formed on the lower surface side of the multilevel wiring layer 102 in the first region 126 in the multilevel wiring layer 102, and a plurality of marks 36 is formed on the upper surface side of the multilevel wiring layer 82 in the second region 116 in the multilevel wiring layer 82.

Each mark of the plurality of marks 35 is an alignment mark, a positional difference detection mark, or a line-width measurement mark.

Each mark of the plurality of marks 36 is an alignment mark, a positional difference detection mark, or a line-width measurement mark.

In the solid-state imaging device 150C, the pixel sensor substrate 125 and the logic substrate 115 can be bonded to each other, with reference to the plurality of marks 35 formed in the multilevel wiring layer 102 and the plurality of marks 36 formed in the multilevel wiring layer 82. In this case, the bonding accuracy can be increased.

The solid-state imaging device 150D can be manufactured by a manufacturing method substantially similar to the method for manufacturing the solid-state imaging device 150.

18. <Solid-State Imaging Device According to a Fifth Modification of the Fifth Embodiment of the Present Technology>

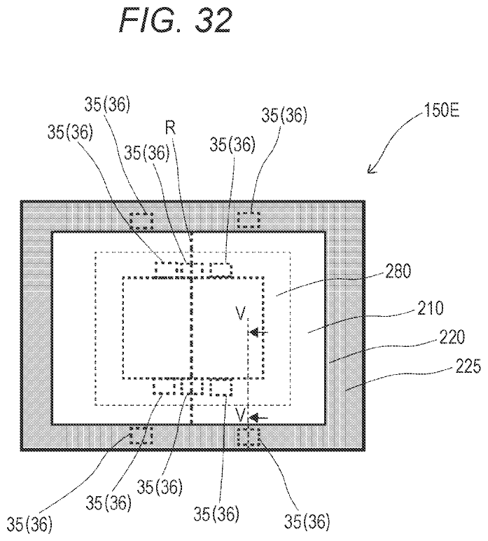

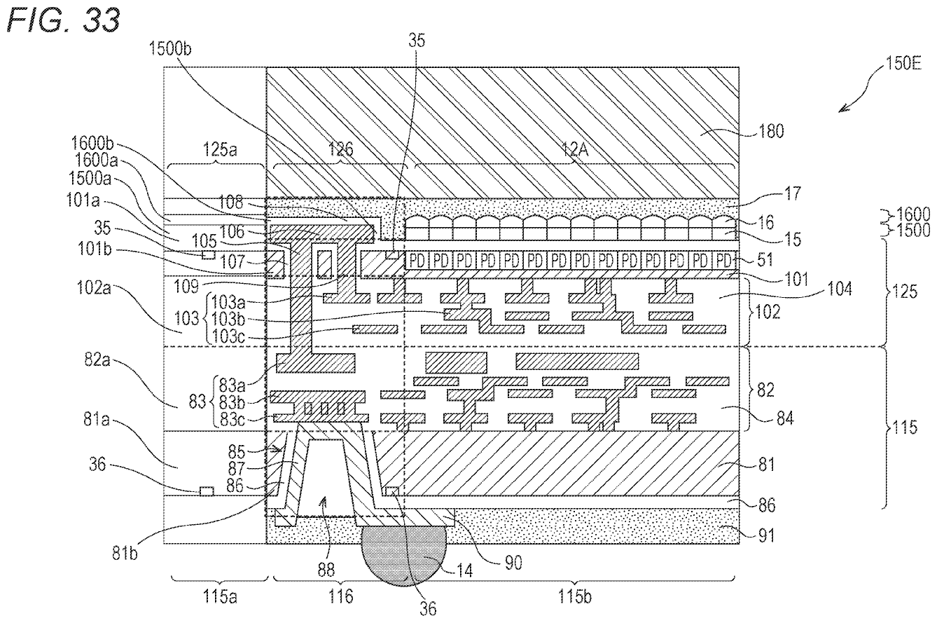

In the description below, a solid-state imaging device 150E according to a fifth modification of the fifth embodiment is explained with reference to FIGS. 32 and 33. FIG. 32 is a plan view schematically showing the solid-state imaging device 150E according to the fifth modification of the fifth embodiment. FIG. 33 is a view showing part of a cross-section (a cross-sectional view taken along the line V-V defined in FIG. 32) of the solid-state imaging device 150E according to the fifth modification of the fifth embodiment.

In the pixel sensor substrate 125 of the solid-state imaging device 150E, marks 35 are formed in the semiconductor substrate 101 in the first region 126, and in the semiconductor substrate 101 in the first scribe region 125a. With this arrangement, the quality of the pixel region 12A can be further enhanced.

In the logic substrate 115 of the solid-state imaging device 150E, marks 36 are formed in the semiconductor substrate 81 in the second region 116, and in the semiconductor substrate 81 in the second scribe region 115a. With this arrangement, the quality of the region 115b corresponding to the pixel region 12A can be further enhanced.

The solid-state imaging device 150E can be manufactured by a manufacturing method substantially similar to the method for manufacturing the solid-state imaging device 150.

19. <Solid-State Imaging Device According to a Sixth Modification of the Fifth Embodiment of the Present Technology>

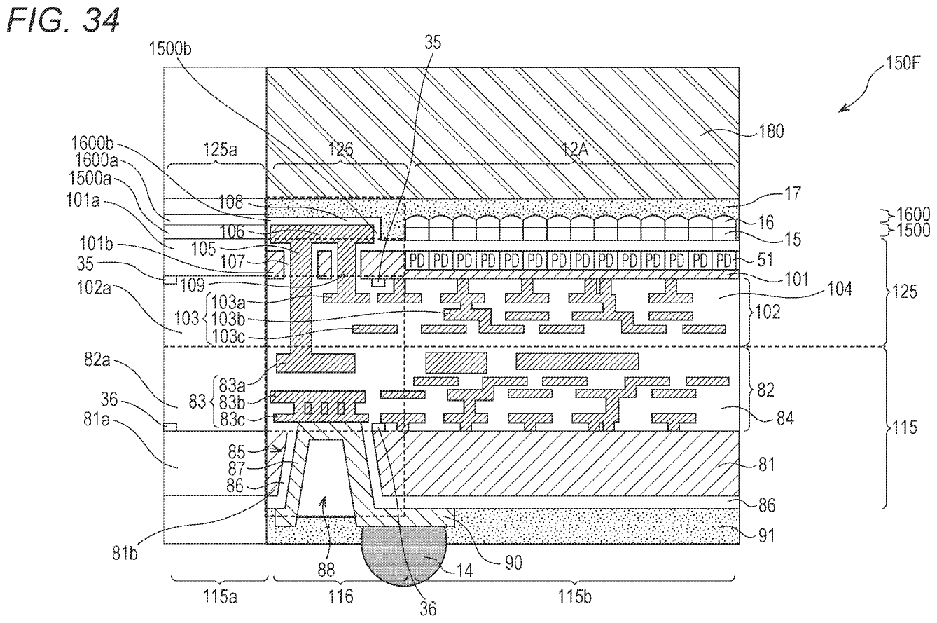

In the description below, a solid-state imaging device 150F according to a sixth modification of the fifth embodiment is explained with reference to FIG. 34. FIG. 34 is a plan view schematically showing the solid-state imaging device 150F according to the sixth modification of the fifth embodiment. FIG. 34 is a view (corresponding to the V-V cross-sectional view in FIG. 32) showing part of a cross-section of the solid-state imaging device 150F according to the sixth modification of the fifth embodiment.

In the pixel sensor substrate 125 of the solid-state imaging device 150F, marks 35 are formed in the multilevel wiring layer 102 in the first region 126, and in the multilevel wiring layer 102 in the first scribe region 125a. With this arrangement, the quality of the pixel region 12A can be further enhanced.

In the logic substrate 115 of the solid-state imaging device 150F, marks 36 are formed in the multilevel wiring layer 82 in the second region 116, and in the multilevel wiring layer 82 in the second scribe region 115a. With this arrangement, the quality of the region 115b corresponding to the pixel region 12A can be further enhanced.

The solid-state imaging device 150F can be manufactured by a manufacturing method substantially similar to the method for manufacturing the solid-state imaging device 150.

20. <Solid-State Imaging Device According to a Seventh Modification of the Fifth Embodiment of the Present Technology>

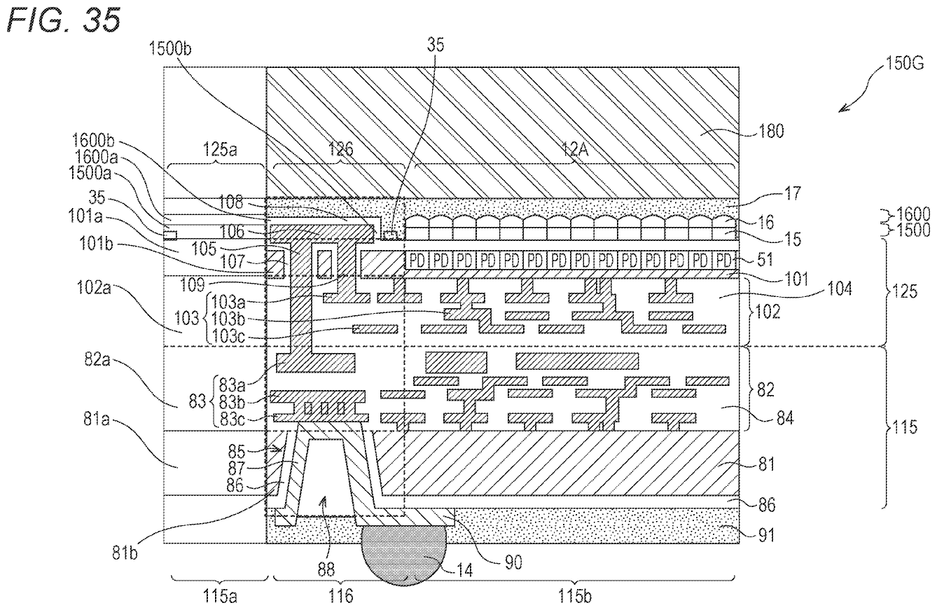

In the description below, a solid-state imaging device 150G according to a seventh modification of the fifth embodiment is explained with reference to FIG. 35. FIG. 35 is a view (corresponding to the V-V cross-sectional view in FIG. 32) showing part of a cross-section of the solid-state imaging device 150G according to the seventh modification of the fifth embodiment.

In the pixel sensor substrate 125 of the solid-state imaging device 150G, marks 35 are formed in the color filter layer 1500 in the first region 126, and in the color filter layer 1500 in the first scribe region 125a. With this arrangement, the quality of the pixel region 12A can be further enhanced.

The solid-state imaging device 150G can be manufactured by a manufacturing method substantially similar to the method for manufacturing the solid-state imaging device 150.

21. <Solid-State Imaging Device According to an Eighth Modification of the Fifth Embodiment of the Present Technology>

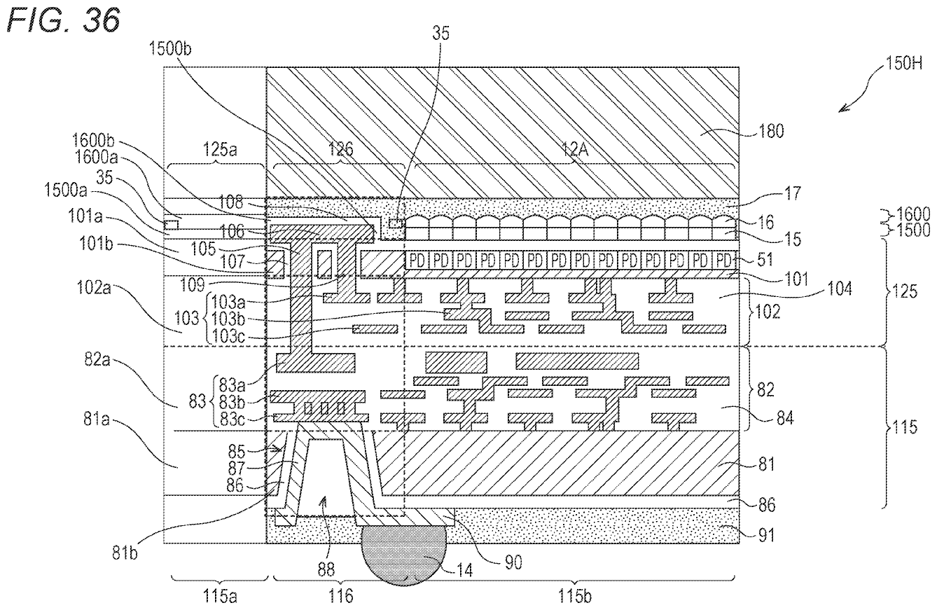

In the description below, a solid-state imaging device 150H according to an eighth modification of the fifth embodiment is explained with reference to FIG. 36. FIG. 36 is a view (corresponding to the V-V cross-sectional view in FIG. 32) showing part of a cross-section of the solid-state imaging device 150H according to the eighth modification of the fifth embodiment.

In the pixel sensor substrate 125 of the solid-state imaging device 150H, marks 35 are formed in the lens layer 1600 in the first region 126, and in the lens layer 1600 in the first scribe region 125a. With this arrangement, the quality of the pixel region 12A can be further enhanced.

The solid-state imaging device 150H can be manufactured by a manufacturing method substantially similar to the method for manufacturing the solid-state imaging device 150.

22. <Solid-State Imaging Device According to a Ninth Modification of the Fifth Embodiment of the Present Technology>

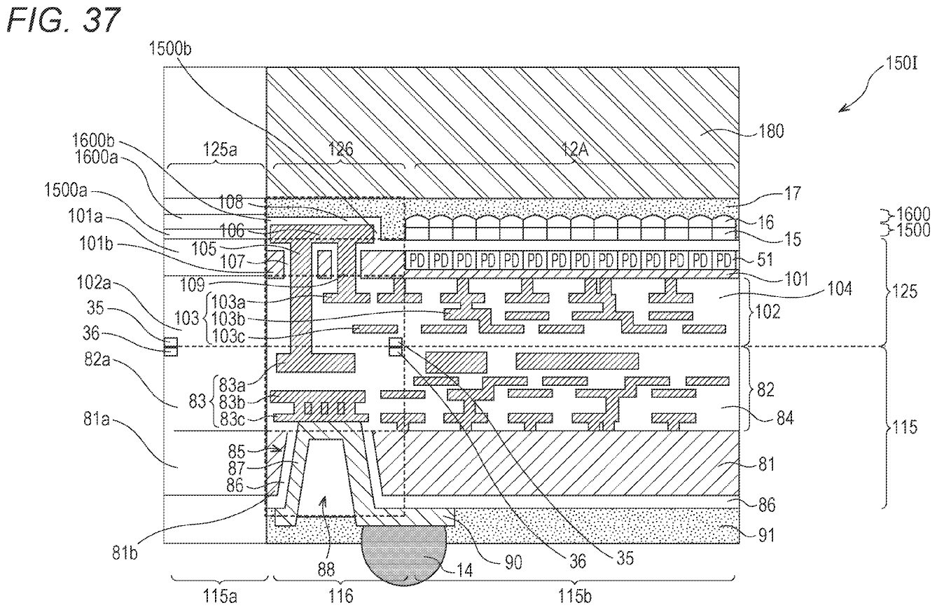

In the description below, a solid-state imaging device 150I according to a ninth modification of the fifth embodiment is explained with reference to FIG. 37. FIG. 37 is a view (corresponding to the V-V cross-sectional view in FIG. 32) showing part of a cross-section of the solid-state imaging device 150I according to the ninth modification of the fifth embodiment.

In the pixel sensor substrate 125 of the solid-state imaging device 150I, marks 35 are formed on the lower surface side of the multilevel wiring layer 102 in the first region 126 in the multilevel wiring layer 102, and on the lower surface side of the multilevel wiring layer 102 in the first scribe region 125a in the multilevel wiring layer 102.

In the logic substrate 115 of the solid-state imaging device 150I, marks 36 are formed on the upper surface side of the multilevel wiring layer 82 in the second region 116 in the multilevel wiring layer 82, and on the upper surface side in the second scribe region 115a in the multilevel wiring layer 82.

With this arrangement, the bonding accuracy between the pixel sensor substrate 125 and the logic substrate 115 can be remarkably increased.

The solid-state imaging device 150I can be manufactured by a manufacturing method substantially similar to the method for manufacturing the solid-state imaging device 150.

23. <Modifications Common to Each Embodiment of the Present Technology>

Changes can be made to the configuration of each of the first to fifth embodiments described above (including each modification of each embodiment; the same applies in the description below).

For example, the configurations of the solid-state imaging devices of the above-described respective embodiments may be combined with each other within a scope that is not technically contradictory.

For example, the solid-state imaging device of each of the above embodiments may be a linear image sensor (a line image sensor) in which a plurality of pixels is one-dimensionally and integrally arranged in series.

For example, the solid-state imaging device of each of the above embodiments may have a single-pixel structure that includes only one pixel.

For example, in the solid-state imaging device of each of the above embodiments, each pixel may include a plurality of photoelectric conversion units.

For example, in the solid-state imaging device of each of the above embodiments, one color filter may be provided for a plurality of photoelectric conversion units.

For example, in the solid-state imaging device of each of the above embodiments, one on-chip lens may be provided for a plurality of photoelectric conversion units.

For example, the solid-state imaging device of each of the above embodiments may not include at least either the color filters or the on-chip lenses. In a case where the solid-state imaging device is used to generate a black-and-white image, for example, the color filters may not be included. In a case where the solid-state imaging device is used for sensing such as distance measurement, for example, at least either the color filters or the on-chip lenses may not be included.

For example, the photoelectric conversion units of the solid-state imaging device of each of the above embodiments may single photon avalanche photodiodes (SPADs), avalanche photodiodes (APDs), PN photodiodes, PIN photodiodes, or the like that has an electron multiplication region, for example.

Alternatively, the photoelectric conversion units of the solid-state imaging device of each of the above embodiments may be photodiodes that are not of a back-illuminated type, or may be front-illuminated photodiodes on which light is incident from the surface side of the semiconductor substrate on the wiring layer side.

For example, a Ge substrate, a GaAs substrate, an InGaAs substrate, or the like may be used as a semiconductor substrate of the solid-state imaging device of each of the above embodiments.

For example, in the solid-state imaging device of each of the above embodiments, the semiconductor substrate of a pixel sensor substrate, a wiring layer, a wiring layer, and a semiconductor substrate are stacked in this order. However, instead of this, a structure in which semiconductor substrates and wiring layers are alternately stacked may be adopted.

For example, in a case where marks are formed in a plurality of layers in a solid-state imaging device, at least one mark may be formed in three or more layers.

For example, in a solid-state imaging device, in a case where marks are provided in a plurality of different layers, only one mark may be provided in at least one layer.

For example, the number of divisions when divided exposure is performed on an exposure region may be three or more.

For example, a solid-state imaging device may be manufactured through collective exposure, instead of divided exposure. In this case, the device formation process can be performed by procedures substantially similar to those shown in the flowcharts in FIGS. 5, 6, and 10 (however, the divided exposure process is replaced with a collective exposure process).

24. <Example of an Electronic Apparatus According to a Sixth Embodiment of the Present Technology>

An electronic apparatus of a seventh embodiment according to the present technology is an electronic apparatus on which a solid-state imaging device of a first aspect according to the present technology is mounted, and the solid-state imaging device of the first aspect according to the present technology is a solid-state imaging device that includes: a semiconductor substrate that has a first principal surface on the light incident side and a second principal surface on the side opposite from the first principal surface, light receiving elements being arranged two-dimensionally on the first principal surface; a light transmissive substrate disposed above the light receiving elements; a wiring layer formed on the second principal surface of the semiconductor substrate; a first rewiring line electrically connected to an internal electrode formed in the wiring layer; and a second rewiring line formed on the side of the second principal surface of the semiconductor substrate.

Alternatively, an electronic apparatus of the sixth embodiment according to the present technology is an electronic apparatus on which a solid-state imaging device of a second aspect according to the present technology is mounted, and the solid-state imaging device of the second aspect according to the present technology is a solid-state imaging device that includes: a sensor substrate that includes a first semiconductor substrate having a first principal surface on the light incident side and a second principal surface on the side opposite from the first principal surface, light receiving elements being formed and arranged two-dimensionally on the first principal surface, and a first wiring layer formed on the second principal surface of the first semiconductor substrate; a circuit substrate that includes a second semiconductor substrate having a third principal surface on the light incident side and a fourth principal surface on the side opposite from the third principal surface, and a second wiring layer formed on the third principal surface of the second semiconductor substrate; a light transmissive substrate disposed above the light receiving elements; a first rewiring line electrically connected to an internal electrode formed in the second wiring layer; and a second rewiring line formed on the side of the fourth principal surface of the second semiconductor substrate. In this solid-state imaging device, the first wiring layer of the sensor substrate and the second wiring layer of the circuit substrate are bonded to each other, to form a stack structure of the sensor substrate and the circuit substrate.

For example, an electronic apparatus of the sixth embodiment according to the present technology is an electronic apparatus in which a solid-state imaging device of one embodiment among the solid-state imaging devices of the first to fifth embodiments (including the modifications of the respective embodiments) according to the present technology is mounted.

25. <Examples of Use of Solid-State Imaging Devices to Which the Present Technology Is Applied>

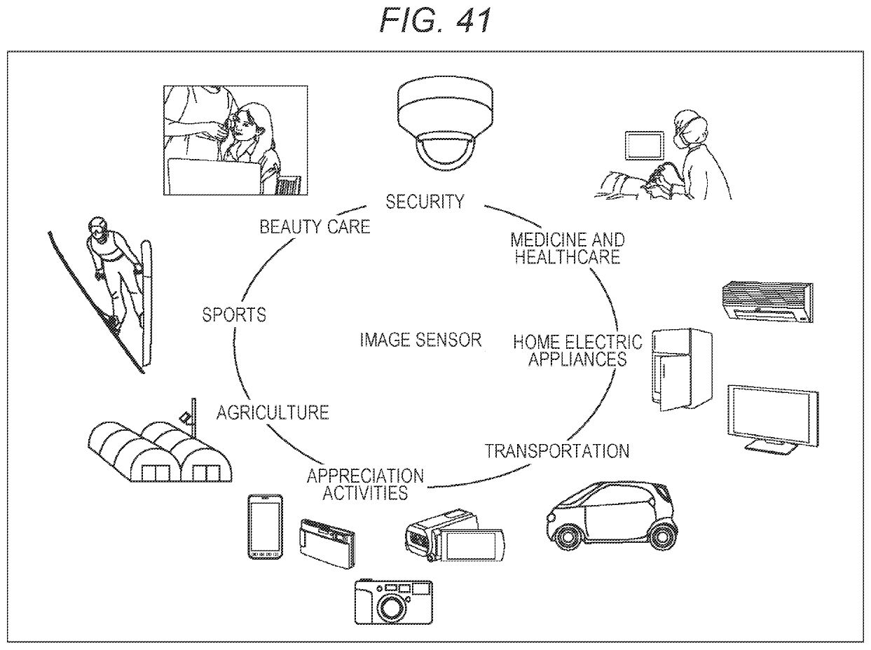

FIG. 41 is a diagram showing examples of use of solid-state imaging devices of the first to fifth embodiments (including the modifications of the respective embodiments) according to the present technology as image sensors.

Solid-state imaging devices of the first to fifth embodiments described above (including the modifications of the respective embodiments) can be used in various cases where light such as visible light, infrared light, ultraviolet light, or an X-ray is sensed, as described below, for example. That is, as shown in FIG. 41, solid-state imaging devices of any one of the first to fifth embodiments (including the modifications of the respective embodiments) can be used in apparatuses (such as the electronic apparatus of the sixth embodiment described above, for example) that are used in the appreciation activity field where images are taken and are used in appreciation activities, the field of transportation, the field of home electric appliances, the fields of medicine and healthcare, the field of security, the field of beauty care, the field of sports, the field of agriculture, and the like, for example.

Specifically, in the appreciation activity field, a solid-state imaging device of any one of the first to fifth embodiments (including the modifications of the respective embodiments) can be used in an apparatus for capturing images to be used in appreciation activities, such as a digital camera, a smartphone, or a portable telephone with a camera function, for example.

In the field of transportation, a solid-state imaging device of any one of the first to fifth embodiments (including the modifications of the respective embodiments) can be used in an apparatus for transportation use, such as a vehicle-mounted sensor designed to capture images of the front, the back, the surroundings, the inside, and the like of an automobile, to perform safe driving such as an automatic stop and recognize the driver's condition or the like, a surveillance camera for monitoring running vehicles and roads, or a ranging sensor for measuring distances between vehicles or the like, for example.

In the field of home electric appliances, a solid-state imaging device of any one of the first to fifth embodiments (including the modifications of the respective embodiments) can be used in an apparatus to be used as home electric appliances, such as a television set, a refrigerator, or an air conditioner, to capture images of gestures of users and operate the apparatus in accordance with the gestures, for example.

In the fields of medicine and healthcare, a solid-state imaging device of any one of the first to fifth embodiments (including the modifications of the respective embodiments) can be used in an apparatus for medical use or healthcare use, such as an endoscope or an apparatus for receiving infrared light for angiography, for example.

In the field of security, a solid-state imaging device of any one of the first to fifth embodiments (including the modifications of the respective embodiments) can be used in an apparatus for security use, such as a surveillance camera for crime prevention or a camera for personal authentication, for example.

In the field of beauty care, a solid-state imaging device of any one of the first to fifth embodiments (including the modifications of the respective embodiments) can be used in an apparatus for beauty care use, such as a skin measurement apparatus designed to capture images of the skin or a microscope for capturing images of the scalp, for example.

In the field of sports, a solid-state imaging device of any one of the first to fifth embodiments (including the modifications of the respective embodiments) can be used in an apparatus for sporting use, such as an action camera or a wearable camera for sports or the like, for example.

In the field of agriculture, a solid-state imaging device of any one of the first to fifth embodiments (including the modifications of the respective embodiments) can be used in an apparatus for agricultural use, such as a camera for monitoring conditions of fields and crops, for example.

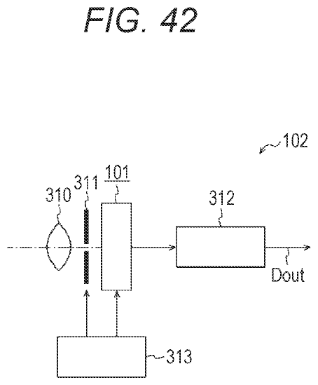

Next, examples of use of solid-state imaging devices of the first to fifth embodiments (including the modifications of the respective embodiments) according to the present technology are specifically described. For example, a solid-state imaging device of any one of the first to fifth embodiments described above (including the modifications of the respective embodiments) can be used as a solid-state imaging device 101 in an electronic apparatus of any type having an imaging function, such as a camera system like a digital still camera or a video camera, or a portable telephone having an imaging function. FIG. 42 shows a schematic configuration of an electronic apparatus 102 (a camera) as an example. This electronic apparatus 102 is a video camera capable of capturing a still image or a moving image, for example, and includes the solid-state imaging device 101, an optical system (an optical lens) 310, a shutter device 311, a drive unit 313 that drives the solid-state imaging device 101 and the shutter device 311, and a signal processing unit 312.

The optical system 310 guides image light (incident light) from the object to a pixel unit 101a of the solid-state imaging device 101. This optical system 310 may be formed with a plurality of optical lenses. The shutter device 311 controls the light irradiation period and the light blocking period for the solid-state imaging device 101. The drive unit 313 controls transfer operations of the solid-state imaging device 101 and shutter operations of the shutter device 311. The signal processing unit 312 performs various kinds of signal processing on a signal output from the solid-state imaging device 101. A video signal Dout subjected to the signal processing is stored into a storage medium such as a memory, or is output to a monitor or the like.

26. <Other Examples of Use of Solid-State Imaging Devices to Which the Present Technology Is Applied>

A solid-state imaging device of any one of the first to fifth embodiments (including the modifications of the respective embodiments) according to the present technology can also be applied to some other electronic apparatus that detects light, such as a time-of-flight (TOF) sensor, for example. In a case where a solid-state imaging device is applied to a TOF sensor, the solid-state imaging device can be applied to a distance image sensor that implements a direct TOF measurement method, or a distance image sensor that implements an indirect TOF measurement method. In the distance image sensor implementing the direct TOF measurement method, a photon arrival timing is directly calculated in the time domain in each pixel. Therefore, a light pulse having a short pulse width is transmitted, and an electrical pulse is generated by a receiver that responds at a high speed. The present disclosure can be applied to the receiver in that case. Further, in the indirect TOF method, a time of flight of light is measured using a semiconductor element structure in which the detection and the accumulation amount of carriers generated by light change with the arrival timing of light. The present disclosure can also be applied to such a semiconductor structure. In the case of application to a TOF sensor, a color filter layer and a lens layer as shown in FIG. 3 and others are provided as appropriate, and may not be provided.

27. <Example Applications to Mobile Structures>

The technology (the present technology) according to the present disclosure can be applied to various products. For example, the technology according to the present disclosure may be embodied as a device mounted on any type of mobile structure, such as an automobile, an electrical vehicle, a hybrid electrical vehicle, a motorcycle, a bicycle, a personal mobility device, an airplane, a drone, a vessel, or a robot.

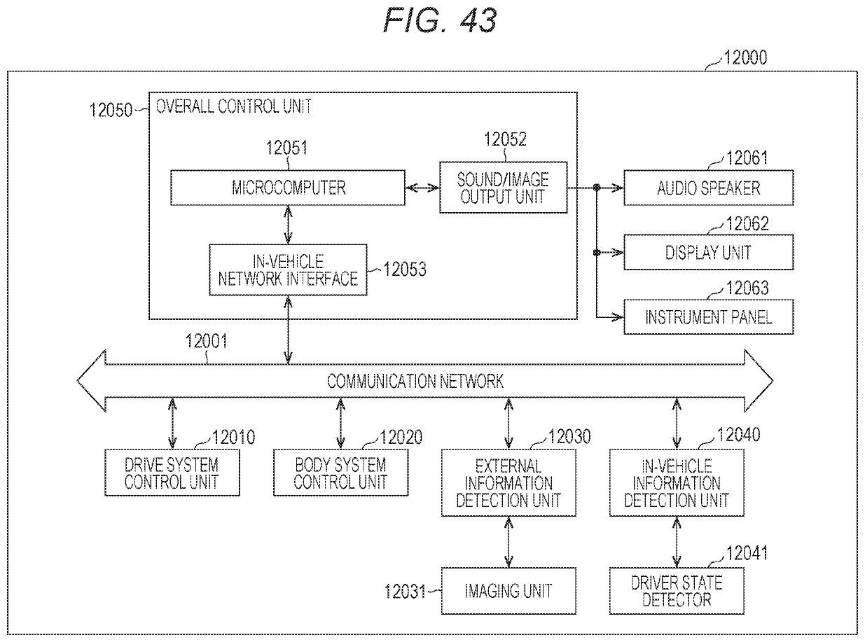

FIG. 43 is a block diagram schematically showing an example configuration of a vehicle control system that is an example of a mobile structure control system to which the technology according to the present disclosure may be applied.

A vehicle control system 12000 includes a plurality of electronic control units connected via a communication network 12001. In the example shown in FIG. 43, the vehicle control system 12000 includes a drive system control unit 12010, a body system control unit 12020, an external information detection unit 12030, an in-vehicle information detection unit 12040, and an overall control unit 12050. Further, a microcomputer 12051, a sound/image output unit 12052, and an in-vehicle network interface (I/F) 12053 are shown as the functional components of the overall control unit 12050.

The drive system control unit 12010 controls operations of the devices related to the drive system of the vehicle according to various programs. For example, the drive system control unit 12010 functions as control devices such as a driving force generation device for generating a driving force of the vehicle such as an internal combustion engine or a driving motor, a driving force transmission mechanism for transmitting the driving force to the wheels, a steering mechanism for adjusting the steering angle of the vehicle, and a braking device for generating a braking force of the vehicle.

The body system control unit 12020 controls operations of the various devices mounted on the vehicle body according to various programs. For example, the body system control unit 12020 functions as a keyless entry system, a smart key system, a power window device, or a control device for various lamps such as a headlamp, a backup lamp, a brake lamp, a turn signal lamp, a fog lamp, or the like. In this case, the body system control unit 12020 can receive radio waves transmitted from a portable device that substitutes for a key, or signals from various switches. The body system control unit 12020 receives inputs of these radio waves or signals, and controls the door lock device, the power window device, the lamps, and the like of the vehicle.

The external information detection unit 12030 detects information outside the vehicle equipped with the vehicle control system 12000. For example, an imaging unit 12031 is connected to the external information detection unit 12030. The external information detection unit 12030 causes the imaging unit 12031 to capture an image of the outside of the vehicle, and receives the captured image. On the basis of the received image, the external information detection unit 12030 may perform an object detection process for detecting a person, a vehicle, an obstacle, a sign, characters on the road surface, or the like, or perform a distance detection process.

The imaging unit 12031 is an optical sensor that receives light, and outputs an electrical signal corresponding to the amount of received light. The imaging unit 12031 can output an electrical signal as an image, or output an electrical signal as distance measurement information. Further, the light to be received by the imaging unit 12031 may be visible light, or may be invisible light such as infrared rays.

The in-vehicle information detection unit 12040 detects information about the inside of the vehicle. For example, a driver state detector 12041 that detects the state of the driver is connected to the in-vehicle information detection unit 12040. The driver state detector 12041 includes a camera that captures an image of the driver, for example, and, on the basis of detected information input from the driver state detector 12041, the in-vehicle information detection unit 12040 may calculate the degree of fatigue or the degree of concentration of the driver, or determine whether or not the driver is dozing off.

On the basis of the external/internal information acquired by the external information detection unit 12030 or the in-vehicle information detection unit 12040, the microcomputer 12051 can calculate the control target value of the driving force generation device, the steering mechanism, or the braking device, and output a control command to the drive system control unit 12010. For example, the microcomputer 12051 can perform cooperative control to achieve the functions of an advanced driver assistance system (ADAS), including vehicle collision avoidance or impact mitigation, follow-up running based on the distance between vehicles, vehicle velocity maintenance running, vehicle collision warning, vehicle lane deviation warning, or the like.

Further, the microcomputer 12051 can also perform cooperative control to conduct automatic driving or the like for autonomously running not depending on the operation of the driver, by controlling the driving force generation device, the steering mechanism, the braking device, or the like on the basis of information about the surroundings of the vehicle, the information having being acquired by the external information detection unit 12030 or the in-vehicle information detection unit 12040.

The microcomputer 12051 can also output a control command to the body system control unit 12020, on the basis of the external information acquired by the external information detection unit 12030. For example, the microcomputer 12051 controls the headlamp in accordance with the position of the leading vehicle or the oncoming vehicle detected by the external information detection unit 12030, and performs cooperative control to achieve an anti-glare effect by switching from a high beam to a low beam, or the like.

The sound/image output unit 12052 transmits an audio output signal and/or an image output signal to an output device that is capable of visually or audibly notifying the passenger(s) of the vehicle or the outside of the vehicle of information. In the example shown in FIG. 43, an audio speaker 12061, a display unit 12062, and an instrument panel 12063 are shown as output devices. The display unit 12062 may include an on-board display and/or a head-up display, for example.

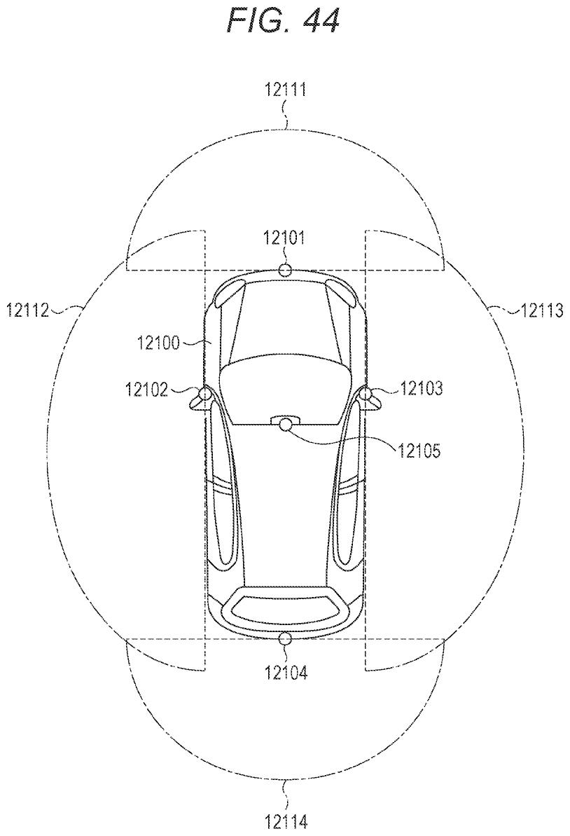

FIG. 44 is a diagram showing an example of installation positions of imaging units 12031.

In FIG. 44, a vehicle 12100 includes imaging units 12101, 12102, 12103, 12104, and 12105 as the imaging units 12031.

Imaging units 12101, 12102, 12103, 12104, and 12105 are provided at the following positions: the front end edge of a vehicle 12100, a side mirror, the rear bumper, a rear door, an upper portion of the front windshield inside the vehicle, and the like, for example. The imaging unit 12101 provided on the front end edge and the imaging unit 12105 provided on the upper portion of the front windshield inside the vehicle mainly capture images ahead of the vehicle 12100. The imaging units 12102 and 12103 provided on the side mirrors mainly capture images on the sides of the vehicle 12100. The imaging unit 12104 provided on the rear bumper or a rear door mainly captures images behind the vehicle 12100. The front images acquired by the imaging units 12101 and 12105 are mainly used for detection of a vehicle running in front of the vehicle 12100, a pedestrian, an obstacle, a traffic signal, a traffic sign, a lane, or the like.

Note that FIG. 44 shows an example of the imaging ranges of the imaging units 12101 to 12104. An imaging range 12111 indicates the imaging range of the imaging unit 12101 provided on the front end edge, imaging ranges 12112 and 12113 indicate the imaging ranges of the imaging units 12102 and 12103 provided on the respective side mirrors, and an imaging range 12114 indicates the imaging range of the imaging unit 12104 provided on the rear bumper or a rear door. For example, image data captured by the imaging units 12101 to 12104 are superimposed on one another, so that an overhead image of the vehicle 12100 viewed from above is obtained.

At least one of the imaging units 12101 to 12104 may have a function of acquiring distance information. For example, at least one of the imaging units 12101 to 12104 may be a stereo camera including a plurality of imaging devices, or may be an imaging device having pixels for phase difference detection.

For example, on the basis of distance information obtained from the imaging units 12101 to 12104, the microcomputer 12051 calculates the distances to the respective three-dimensional objects within the imaging ranges 12111 to 12114, and temporal changes in the distances (the velocities relative to the vehicle 12100). In this manner, the three-dimensional object that is the closest three-dimensional object on the traveling path of the vehicle 12100 and is traveling at a predetermined velocity (0 km/h or higher, for example) in substantially the same direction as the vehicle 12100 can be extracted as the vehicle running in front of the vehicle 12100. Further, the microcomputer 12051 can set beforehand an inter-vehicle distance to be maintained in front of the vehicle running in front of the vehicle 12100, and can perform automatic brake control (including follow-up stop control), automatic acceleration control (including follow-up start control), and the like. In this manner, it is possible to perform cooperative control to conduct automatic driving or the like to autonomously travel not depending on the operation of the driver.

For example, in accordance with the distance information obtained from the imaging units 12101 to 12104, the microcomputer 12051 can extract three-dimensional object data concerning three-dimensional objects under the categories of two-wheeled vehicles, regular vehicles, large vehicles, pedestrians, utility poles, and the like, and use the three-dimensional object data in automatically avoiding obstacles. For example, the microcomputer 12051 classifies the obstacles in the vicinity of the vehicle 12100 into obstacles visible to the driver of the vehicle 12100 and obstacles difficult to visually recognize. The microcomputer 12051 then determines collision risks indicating the risks of collision with the respective obstacles. If a collision risk is equal to or higher than a set value, and there is a possibility of collision, the microcomputer 12051 can output a warning to the driver via the audio speaker 12061 and the display unit 12062, or can perform driving support for avoiding collision by performing forced deceleration or avoiding steering via the drive system control unit 12010.

At least one of the imaging units 12101 to 12104 may be an infrared camera that detects infrared rays. For example, the microcomputer 12051 can recognize a pedestrian by determining whether or not a pedestrian exists in images captured by the imaging units 12101 to 12104. Such pedestrian recognition is carried out through a process of extracting feature points from the images captured by the imaging units 12101 to 12104 serving as infrared cameras, and a process of performing a pattern matching on the series of feature points indicating the outlines of objects and determining whether or not there is a pedestrian, for example. If the microcomputer 12051 determines that a pedestrian exists in the images captured by the imaging units 12101 to 12104, and recognizes a pedestrian, the sound/image output unit 12052 controls the display unit 12062 to display a rectangular contour line for emphasizing the recognized pedestrian in a superimposed manner. Further, the sound/image output unit 12052 may also control the display unit 12062 to display an icon or the like indicating the pedestrian at a desired position.

An example of a vehicle control system to which the technology (the present technology) according to the present disclosure may be applied has been described above. The technology according to the present disclosure can be applied to the imaging units 12031 and the like among the components described above, for example. Specifically, the solid-state imaging device 111 of the present disclosure can be applied to the imaging unit 12031. By applying the technique according to the present disclosure to the imaging unit 12031, it is possible to improve the yield and reduce the manufacturing costs.

28. <Example Application to an Endoscopic Surgery System>

The present technology can be applied to various products. For example, the technology (the present technology) according to the present disclosure may be applied to an endoscopic surgery system.

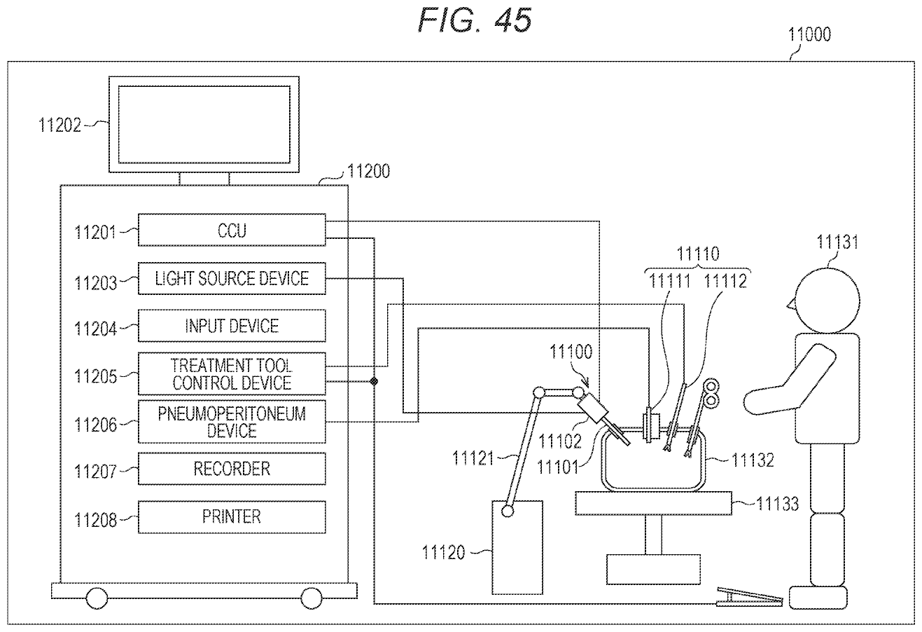

FIG. 45 is a diagram schematically showing an example configuration of an endoscopic surgery system to which the technology (the present technology) according to the present disclosure can be applied.

FIG. 45 shows a situation where a surgeon (a physician) 11131 is performing surgery on a patient 11132 on a patient bed 11133, using an endoscopic surgery system 11000. As shown in the drawing, the endoscopic surgery system 11000 includes an endoscope 11100, other surgical tools 11110 such as a pneumoperitoneum tube 11111 and an energy treatment tool 11112, a support arm device 11120 that supports the endoscope 11100, and a cart 11200 on which various kinds of devices for endoscopic surgery are mounted.

The endoscope 11100 includes a lens barrel 11101 that has a region of a predetermined length from the top end to be inserted into a body cavity of the patient 11132, and a camera head 11102 connected to the base end of the lens barrel 11101. In the example shown in the drawing, the endoscope 11100 is designed as a so-called rigid scope having a rigid lens barrel 11101. However, the endoscope 11100 may be designed as a so-called flexible scope having a flexible lens barrel.

At the top end of the lens barrel 11101, an opening into which an objective lens is inserted is provided. A light source device 11203 is connected to the endoscope 11100, and the light generated by the light source device 11203 is guided to the top end of the lens barrel by a light guide extending inside the lens barrel 11101, and is emitted toward the current observation target in the body cavity of the patient 11132 via the objective lens. Note that the endoscope 11100 may be a forward-viewing endoscope, an oblique-viewing endoscope, or a side-viewing endoscope.

An optical system and an imaging device are provided inside the camera head 11102, and reflected light (observation light) from the current observation target is converged on the imaging device by the optical system. The observation light is photoelectrically converted by the imaging device, and an electrical signal corresponding to the observation light, or an image signal corresponding to the observation image, is generated. The image signal is transmitted as RAW data to a camera control unit (CCU) 11201.

The CCU 11201 is formed with a central processing unit (CPU), a graphics processing unit (GPU), or the like, and collectively controls operations of the endoscope 11100 and a display device 11202. Further, the CCU 11201 receives an image signal from the camera head 11102, and subjects the image signal to various kinds of image processing, such as a development process (a demosaicing process), for example, to display an image based on the image signal.

Under the control of the CCU 11201, the display device 11202 displays an image based on the image signal subjected to the image processing by the CCU 11201.

The light source device 11203 is formed with a light source such as a light emitting diode (LED), for example, and supplies the endoscope 11100 with illuminating light for imaging the surgical site or the like.

An input device 11204 is an input interface to the endoscopic surgery system 11000. The user can input various kinds of information and instructions to the endoscopic surgery system 11000 via the input device 11204. For example, the user inputs an instruction or the like to change imaging conditions (such as the type of illuminating light, the magnification, and the focal length) for the endoscope 11100.

A treatment tool control device 11205 controls driving of the energy treatment tool 11112 for tissue cauterization, incision, blood vessel sealing, or the like. A pneumoperitoneum device 11206 injects a gas into a body cavity of the patient 11132 via the pneumoperitoneum tube 11111 to inflate the body cavity, for the purpose of securing the field of view of the endoscope 11100 and the working space of the surgeon. A recorder 11207 is a device capable of recording various kinds of information about the surgery. A printer 11208 is a device capable of printing various kinds of information relating to the surgery in various formats such as text, images, graphics, and the like.

Note that the light source device 11203 that supplies the endoscope 11100 with the illuminating light for imaging the surgical site can be formed with an LED, a laser light source, or a white light source that is a combination of an LED and a laser light source, for example. In a case where a white light source is formed with a combination of RGB laser light sources, the output intensity and the output timing of each color (each wavelength) can be controlled with high precision. Accordingly, the white balance of an image captured by the light source device 11203 can be adjusted. Alternatively, in this case, laser light from each of the RGB laser light sources may be emitted onto the current observation target in a time-division manner, and driving of the imaging device of the camera head 11102 may be controlled in synchronization with the timing of the light emission. Thus, images corresponding to the respective RGB colors can be captured in a time-division manner. According to the method, a color image can be obtained without any color filter provided in the imaging device.

Further, the driving of the light source device 11203 may also be controlled so that the intensity of light to be output is changed at predetermined time intervals. The driving of the imaging device of the camera head 11102 is controlled in synchronism with the timing of the change in the intensity of the light, and images are acquired in a time-division manner and are then combined. Thus, a high dynamic range image with no black portions and no white spots can be generated.

Further, the light source device 11203 may also be designed to be capable of supplying light of a predetermined wavelength band compatible with special light observation. In special light observation, light of a narrower band than the illuminating light (or white light) at the time of normal observation is emitted, with the wavelength dependence of light absorption in body tissue being taken advantage of, for example. As a result, so-called narrow band light observation (narrow band imaging) is performed to image predetermined tissue such as a blood vessel in a mucosal surface layer or the like, with high contrast. Alternatively, in the special light observation, fluorescence observation for obtaining an image with fluorescence generated through emission of excitation light may be performed. In fluorescence observation, excitation light is emitted to body tissue so that the fluorescence from the body tissue can be observed (autofluorescence observation). Alternatively, a reagent such as indocyanine green (ICG) is locally injected into body tissue, and excitation light corresponding to the fluorescence wavelength of the reagent is emitted to the body tissue so that a fluorescent image can be obtained, for example. The light source device 11203 can be designed to be capable of supplying narrow band light and/or excitation light compatible with such special light observation.

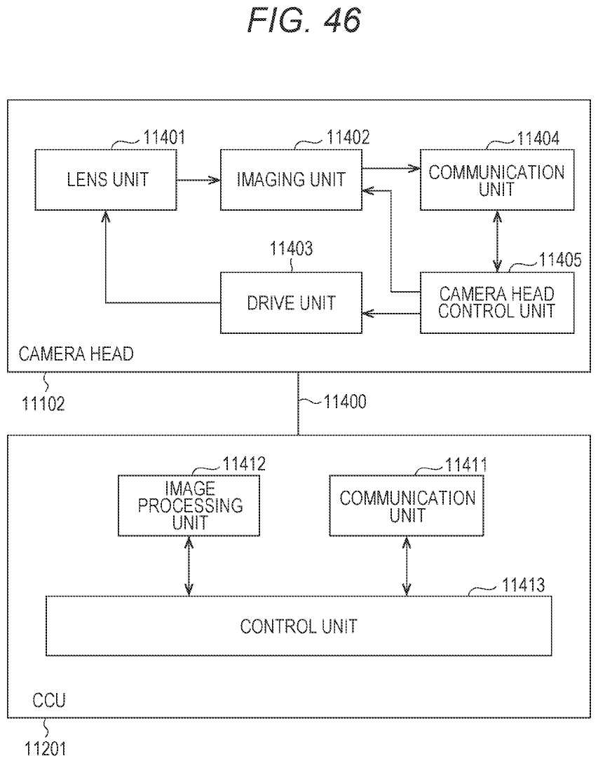

FIG. 46 is a block diagram showing an example of the functional configurations of the camera head 11102 and the CCU 11201 shown in FIG. 45.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are communicably connected to each other by a transmission cable 11400.

The lens unit 11401 is an optical system provided at the connecting portion with the lens barrel 11101. Observation light captured from the top end of the lens barrel 11101 is guided to the camera head 11102, and enters the lens unit 11401. The lens unit 11401 is formed with a combination of a plurality of lenses including a zoom lens and a focus lens.

The imaging unit 11402 is formed with an imaging device. The imaging unit 11402 may be formed with one imaging device (a so-called single-plate type), or may be formed with a plurality of imaging devices (a so-called multiple-plate type). In a case where the imaging unit 11402 is of a multiple-plate type, for example, image signals corresponding to the respective RGB colors may be generated by the respective imaging devices, and be then combined to obtain a color image. Alternatively, the imaging unit 11402 may be designed to include a pair of imaging devices for acquiring right-eye and left-eye image signals compatible with three-dimensional (3D) display. As the 3D display is conducted, the surgeon 11131 can grasp more accurately the depth of the body tissue at the surgical site. Note that, in a case where the imaging unit 11402 is of a multiple-plate type, a plurality of lens units 11401 is provided for the respective imaging devices.

Further, the imaging unit 11402 is not necessarily provided in the camera head 11102. For example, the imaging unit 11402 may be provided immediately behind the objective lens in the lens barrel 11101.

The drive unit 11403 is formed with an actuator, and, under the control of the camera head control unit 11405, moves the zoom lens and the focus lens of the lens unit 11401 by a predetermined distance along the optical axis. With this arrangement, the magnification and the focal point of the image captured by the imaging unit 11402 can be adjusted as appropriate.

The communication unit 11404 is formed with a communication device for transmitting and receiving various kinds of information to and from the CCU 11201. The communication unit 11404 transmits the image signal obtained as RAW data from the imaging unit 11402 to the CCU 11201 via the transmission cable 11400.

The communication unit 11404 also receives a control signal for controlling the driving of the camera head 11102 from the CCU 11201, and supplies the control signal to the camera head control unit 11405. The control signal includes information about imaging conditions, such as information for specifying the frame rate of captured images, information for specifying the exposure value at the time of imaging, and/or information for specifying the magnification and the focal point of captured images, for example.

Note that the above imaging conditions such as the frame rate, the exposure value, the magnification, and the focal point may be appropriately specified by the user, or may be automatically set by the control unit 11413 of the CCU 11201 on the basis of an acquired image signal. In the latter case, the endoscope 11100 has a so-called auto-exposure (AE) function, an auto-focus (AF) function, and an auto-white-balance (AWB) function.

The camera head control unit 11405 controls the driving of the camera head 11102, on the basis of a control signal received from the CCU 11201 via the communication unit 11404.

The communication unit 11411 is formed with a communication device for transmitting and receiving various kinds of information to and from the camera head 11102. The communication unit 11411 receives an image signal transmitted from the camera head 11102 via the transmission cable 11400.

Further, the communication unit 11411 also transmits a control signal for controlling the driving of the camera head 11102, to the camera head 11102. The image signal and the control signal can be transmitted through electrical communication, optical communication, or the like.

The image processing unit 11412 performs various kinds of image processing on an image signal that is RAW data transmitted from the camera head 11102.

The control unit 11413 performs various kinds of control relating to display of an image of the surgical portion or the like captured by the endoscope 11100, and a captured image obtained through imaging of the surgical site or the like. For example, the control unit 11413 generates a control signal for controlling the driving of the camera head 11102.

Further, the control unit 11413 also causes the display device 11202 to display a captured image showing the surgical site or the like, on the basis of the image signal subjected to the image processing by the image processing unit 11412. In doing so, the control unit 11413 may recognize the respective objects shown in the captured image, using various image recognition techniques. For example, the control unit 11413 can detect the shape, the color, and the like of the edges of an object shown in the captured image, to recognize the surgical tool such as forceps, a specific body site, bleeding, the mist at the time of use of the energy treatment tool 11112, and the like. When causing the display device 11202 to display the captured image, the control unit 11413 may cause the display device 11202 to superimpose various kinds of surgery aid information on the image of the surgical site on the display, using the recognition result. As the surgery aid information is superimposed and displayed, and thus, is presented to the surgeon 11131, it becomes possible to reduce the burden on the surgeon 11131, and enable the surgeon 11131 to proceed with the surgery in a reliable manner.

The transmission cable 11400 connecting the camera head 11102 and the CCU 11201 is an electrical signal cable compatible with electric signal communication, an optical fiber compatible with optical communication, or a composite cable thereof.

Here, in the example shown in the drawing, communication is performed in a wired manner using the transmission cable 11400. However, communication between the camera head 11102 and the CCU 11201 may be performed in a wireless manner.

An example of an endoscopic surgery system to which the technique according to the present disclosure can be applied has been described above. The technology according to the present disclosure may be applied to the endoscope 11100, (the imaging unit 11402 of) the camera head 11102, and the like in the configuration described above. Specifically, the solid-state imaging device 111 of the present disclosure can be applied to the imaging unit 10402. By applying the technique according to the present disclosure to the endoscope 11100, (the imaging unit 11402) of the camera head 11102, and the like, it is possible to improve the yield and reduce the manufacturing costs.

Although the endoscopic surgery system has been described as an example herein, the technology according to the present disclosure may be applied to a microscopic surgery system or the like, for example.

The present technique can also be embodied in the configurations described below.

(1) A semiconductor device including:

a first substrate in which a pixel region including a pixel having a photoelectric conversion unit is formed; and

a second substrate in which a logic circuit that processes a signal output from the pixel region is formed,

in which the first substrate and the second substrate are stacked, and

at least one of marks including a mark to be used in an exposure process during manufacture of the semiconductor device and/or a mark to be used in an inspection process for the semiconductor device is formed in a first region that is a region between a first scribe region that is a peripheral portion of the first substrate and the pixel region and/or in a second region that is a region between a second scribe region that is a peripheral portion of the second substrate and a region corresponding to the pixel region in the second substrate.

(2) The semiconductor device according to (1), in which the first substrate has a structure in which a semiconductor substrate and a wiring layer are stacked, the semiconductor substrate including a first semiconductor region in which the photoelectric conversion unit is formed and a second semiconductor region in which the photoelectric conversion unit is not formed, and the at least one of the marks is formed in the second semiconductor region and/or in the wiring layer in the first region.

(3) The semiconductor device according to (1) or (2), in which the first substrate has a structure in which a semiconductor substrate and a light condensing layer are stacked, the semiconductor substrate including a first semiconductor region in which the photoelectric conversion unit is formed and a second semiconductor region in which the photoelectric conversion unit is not formed, the light condensing layer including a region in which a light condensing unit that condenses light onto the photoelectric conversion unit is formed and a region in which the light condensing unit is not formed, and the at least one of the marks is formed in the second semiconductor region and/or in a region of the light condensing layer in which the light condensing unit is not formed, in the first region.

(4) The semiconductor device according to (3), in which the light condensing layer includes at least one of a lens layer, or a color filter layer disposed between the lens layer and the semiconductor substrate.

(5) The semiconductor device according to any one of (1) to (4), in which the second substrate has a structure in which a semiconductor substrate and a wiring layer are stacked, the logic circuit being formed in the semiconductor substrate, and the at least one of the marks is formed in the semiconductor substrate and/or in the wiring layer in the second region.

(6) The semiconductor device according to any one of (1) to (5), in which the at least one of the marks is formed at a position closer to the pixel region than to the first scribe region in the first region.

(7) The semiconductor device according to any one of (1) to (6), in which the at least one of the marks is formed at a position closer to the region corresponding to the pixel region than to the second scribe region in the second region.

(8) The semiconductor device according to any one of (1) to (7), in which at least one of a wiring line or a circuit element is formed in the first region, and

the at least one of the marks is formed in a region between the at least one of the wiring line or the circuit element and the pixel region in the first region.

(9) The semiconductor device according to any one of (1) to (8), in which at least one of a wiring line or a circuit element is formed in the second region, and the at least one of the marks is formed in a region between the at least one of the wiring line or the circuit element and a region corresponding to the pixel region in the second region.

(10) The semiconductor device according to any one of (1) to (9), in which the at least one of the marks includes a plurality of marks, and the plurality of marks is arrayed along an outer periphery of the pixel region.

(11) The semiconductor device according to any one of (1) to (10), in which the at least one of the marks includes a plurality of marks, and the plurality of marks is arrayed along an outer periphery of a region corresponding to the pixel region.

(12) The semiconductor device according to any one of (1) to (11), in which at least one of marks including a mark to be used in an exposure process during manufacture of the semiconductor device and/or a mark to be used in an inspection process for the semiconductor device is formed in the first scribe region.

(13) The semiconductor device according to (12), in which the at least one of the marks is formed at a position on an inner peripheral side of the first scribe region.

(14) The semiconductor device according to any one of (1) to (13), in which at least one of marks including a mark to be used in an exposure process during manufacture of the semiconductor device and/or a mark to be used in an inspection process for the semiconductor device is formed in the second scribe region.

(15) The semiconductor device according to (14), in which the at least one of the marks is formed at a position on an inner peripheral side of the second scribe region.

(16) The semiconductor device according to any one of (1) to (15), in which the at least one of the marks includes at least one of an alignment mark, a positional difference detection mark, or a line-width measurement mark.

(17) An electronic apparatus including the semiconductor device according to any one of (1) to (16).

(18) A semiconductor device including

a substrate that includes:

a pixel region including a pixel having a photoelectric conversion unit; and

a circuit region formed around the pixel region,

in which at least one of marks including a mark to be used in an exposure process during manufacture of the semiconductor device and/or a mark to be used in an inspection process for the semiconductor device is formed in an intermediate region that is a region between the pixel region and the circuit region.

(19) The semiconductor device according to (18), in which the substrate has a structure in which a semiconductor substrate and a wiring layer are stacked, the photoelectric conversion unit and a circuit element of the circuit region being formed in the semiconductor substrate, and

the at least one of the marks is formed in a first region and/or in a second region in the intermediate region, the first region being a region in which the photoelectric conversion unit and the circuit element in the semiconductor substrate are not formed, the second region being a region in the wiring layer in the intermediate region.

(20) The semiconductor device according to (19), in which the at least one of the marks is formed at a position closer to the pixel region than to the circuit region in the first region.

(21) The semiconductor device according to (19) or (20), in which the at least one of the marks is formed at a position closer to the pixel region than to the circuit region in the second region.

(22) The semiconductor device according to any one of (19) to (21), in which the at least one of the marks includes a plurality of marks, and

the plurality of marks is arrayed along an outer periphery of the pixel region in the first region.

(23) The semiconductor device according to any one of (19) to (22), in which the at least one of the marks includes a plurality of marks, and

the plurality of marks is arrayed along an outer periphery of the pixel region in the second region.

(24) The semiconductor device according to any one of (18) to (23), in which the at least one of the marks includes a plurality of marks, a portion of the plurality of marks is formed in the intermediate region, and the other portion of the plurality of marks is formed in a scribe region that is a peripheral portion of the substrate.

(25) The semiconductor device according to (24), in which the other portion of the plurality of marks is formed in an inner peripheral portion of the scribe region.

(26) An electronic apparatus including the semiconductor device according to (18).

(27) A method for manufacturing a semiconductor device including a substrate that includes:

a pixel region in which pixels including photoelectric conversion units are arrayed; and

a circuit region formed around the pixel region,

the method including a divided exposure process of dividing an exposure region on a semiconductor substrate as part of the substrate or on a layer stacked on the semiconductor substrate into a plurality of regions, and individually exposing each divided region,

the divided exposure process including:

a first exposure process of exposing one region of the plurality of regions, using a first reticle having a first mark formation pattern for forming at least one first mark in an intermediate region between the pixel region and the circuit region;

an aligning process of aligning a second reticle with another region of the plurality of regions with reference to at least a portion of the first mark, the second reticle having a second mark formation pattern for forming at least one second mark in the intermediate region between the pixel region and the circuit region; and

a second exposure process of exposing the another region, using the second reticle.

(28) The method for manufacturing the semiconductor device according to (27), in which the first reticle has a pattern for forming a portion of the pixel region and/or a portion of the circuit region, and

the second reticle has a pattern for forming the other portion of the pixel region and/or the other portion of the circuit region.

(29) A method for manufacturing a semiconductor device including a substrate that includes:

a pixel region in which pixels including photoelectric conversion units are arrayed; and

a circuit region formed around the pixel region,

the method including:

a first exposure process of exposing an exposure region on a semiconductor substrate as part of the substrate or on a layer stacked on the semiconductor substrate, using a first reticle having a mark formation pattern for forming a mark in an intermediate region between the pixel region and the circuit region;

a process of stacking another layer on the semiconductor substrate or the layer;

an aligning process of aligning a second reticle with an exposure region on the another layer with reference to at least a portion of the mark, the second reticle having a pattern for forming a portion of the pixel region and/or a portion of the circuit region, the exposure region on the another layer corresponding to the exposure region; and

a second exposure process of exposing the exposure region on the another material layer, using the second reticle.

(30) The method for manufacturing the semiconductor device according to (29), in which the first reticle has a pattern for forming the other portion of the pixel region and/or the other portion of the circuit region.

(31) A method for manufacturing a semiconductor device including a substrate in which a pixel region is formed, pixels including photoelectric conversion units being arrayed in the pixel region,

the method including a divided exposure process of dividing an exposure region on a semiconductor substrate as part of the substrate or on a layer stacked on the semiconductor substrate into a plurality of regions, and individually exposing each divided region,

the divided exposure process including:

a first exposure process of exposing one region of the plurality of regions, using a first reticle having a first mark formation pattern for forming at least one first mark in a region between the pixel region and a scribe region that is a peripheral portion of the substrate;

an aligning process of aligning a second reticle with another region of the plurality of regions with reference to at least a portion of the first mark, the second reticle having a second mark formation pattern for forming at least one second mark in the region between the pixel region and the scribe region that is the peripheral portion of the substrate; and a second exposure process of exposing the another region, using the second reticle.

(32) The method for manufacturing the semiconductor device according to (31), in which the first reticle has a pattern for forming a portion of the pixel region, and the second reticle has a pattern for forming the other portion of the pixel region.

(33) A method for manufacturing a semiconductor device including a substrate in which a pixel region is formed, pixels including photoelectric conversion units being arrayed in the pixel region,

the method including:

a first exposure process of exposing an exposure region on a semiconductor substrate as part of the substrate or on a layer stacked on the semiconductor substrate, using a first reticle having a mark formation pattern for forming a mark in a region between the pixel region and a scribe region that is a peripheral portion of the substrate;

a process of stacking another layer on the semiconductor substrate or the layer;

an aligning process of aligning a second reticle with an exposure region on the another layer with reference to at least a portion of the mark, the second reticle having a pattern for forming a portion of the pixel region, the exposure region on the another layer corresponding to the exposure region; and

a second exposure process of exposing the exposure region on the another layer, using the second reticle.

(34) The method for manufacturing the semiconductor device according to (33), in which the first reticle has a pattern for forming the other portion of the pixel region.

### REFERENCE SIGNS LIST

11, 11A, 11B, 11C, 11D, 120, 120A, 130, 130A, 130B, 130C, 130D, 140, 150, 150A, 150B, 150C, 150D, 150E, 150F, 150G, 150H, 150I, 160, 160A, 160B, 160C, 160D Solid-state imaging device (semiconductor device)
12, 12A, 12B Pixel region
31, 51 Photoelectric conversion unit
18, 250 Pixel
21 Substrate
125, 190 First substrate
115, 180 Second substrate
35, 36 Mark
28 Intermediate region
19 Circuit region
125a, 280b First scribe region
115a, 380b Second scribe region
126, 280a First region
116, 380a Second scribe region

1. A semiconductor device comprising:
a first substrate in which a pixel region including a pixel having a photoelectric conversion unit is formed; and
a second substrate in which a logic circuit that processes a signal output from the pixel region is formed,
wherein the first substrate and the second substrate are stacked, and
at least one of marks including a mark to be used in an exposure process during manufacture of the semiconductor device and/or a mark to be used in an inspection process for the semiconductor device is formed in a first region that is a region between a first scribe region that is a peripheral portion of the first substrate and the pixel region and/or in a second region that is a region between a second scribe region that is a peripheral portion of the second substrate and a region corresponding to the pixel region in the second substrate.

2. The semiconductor device according to claim 1, wherein the first substrate has a structure in which a semiconductor substrate and a wiring layer are stacked, the semiconductor substrate including a first semiconductor region in which the photoelectric conversion unit is formed and a second semiconductor region in which the photoelectric conversion unit is not formed, and
the at least one of the marks is formed in the second semiconductor region and/or in the wiring layer in the first region.

3. The semiconductor device according to claim 1, wherein the first substrate has a structure in which a semiconductor substrate and a light condensing layer are stacked, the semiconductor substrate including a first semiconductor region in which the photoelectric conversion unit is formed and a second semiconductor region in which the photoelectric conversion unit is not formed, the light condensing layer including a region in which a light condensing unit that condenses light onto the photoelectric conversion unit is formed and a region in which the light condensing unit is not formed, and
the at least one of the marks is formed in the second semiconductor region and/or in a region of the light condensing layer in which the light condensing unit is not formed, in the first region.

4. The semiconductor device according to claim 3, wherein
the light condensing layer includes
at least one of
a lens layer, or
a color filter layer disposed between the lens layer and the semiconductor substrate.

5. The semiconductor device according to claim 1, wherein the second substrate has a structure in which a semiconductor substrate and a wiring layer are stacked, the logic circuit being formed in the semiconductor substrate, and
the at least one of the marks is formed in the semiconductor substrate and/or in the wiring layer in the second region.

6. The semiconductor device according to claim 1, wherein the at least one of the marks is formed at a position closer to the pixel region than to the first scribe region in the first region.

7. The semiconductor device according to claim 1, wherein the at least one of the marks is formed at a position closer to the region corresponding to the pixel region than to the second scribe region in the second region.

8. The semiconductor device according to claim 1, wherein at least one of a wiring line or a circuit element is formed in the first region, and
the at least one of the marks is formed in a region between the at least one of the wiring line or the circuit element and the pixel region in the first region.

9. The semiconductor device according to claim 1, wherein at least one of a wiring line or a circuit element is formed in the second region, and
the at least one of the marks is formed in a region between the at least one of the wiring line or the circuit element and a region corresponding to the pixel region in the second region.

10. The semiconductor device according to claim 1, wherein the at least one of the marks includes a plurality of marks, and
the plurality of marks is arrayed along an outer periphery of the pixel region.

11. The semiconductor device according to claim 1, wherein the at least one of the marks includes a plurality of marks, and
the plurality of marks is arrayed along an outer periphery of a region corresponding to the pixel region.

12. The semiconductor device according to claim 1, wherein at least one of marks including a mark to be used in an exposure process during manufacture of the semiconductor device and/or a mark to be used in an inspection process for the semiconductor device is formed in the first scribe region.

13. The semiconductor device according to claim 12, wherein the at least one of the marks is formed at a position on an inner peripheral side of the first scribe region.

14. The semiconductor device according to claim 1, wherein at least one of marks including a mark to be used in an exposure process during manufacture of the semiconductor device and/or a mark to be used in an inspection process for the semiconductor device is formed in the second scribe region.

15. The semiconductor device according to claim 14, wherein the at least one of the marks is formed at a position on an inner peripheral side of the second scribe region.

16. The semiconductor device according to claim 1, wherein the at least one of the marks includes at least one of an alignment mark, a positional difference detection mark, or a line-width measurement mark.

17. A semiconductor device comprising
a substrate that includes:
a pixel region including a pixel having a photoelectric conversion unit; and
a circuit region formed around the pixel region,
wherein at least one of marks including a mark to be used in an exposure process during manufacture of the semiconductor device and/or a mark to be used in an inspection process for the semiconductor device is formed in an intermediate region that is a region between the pixel region and the circuit region.

18. The semiconductor device according to claim 17, wherein the substrate has a structure in which a semiconductor substrate and a wiring layer are stacked, the photoelectric conversion unit and a circuit element of the circuit region being formed in the semiconductor substrate, and
the at least one of the marks is formed in a first region and/or in a second region in the intermediate region, the first region being a region in which the photoelectric conversion unit and the circuit element in the semiconductor substrate are not formed, the second region being a region in the wiring layer in the intermediate region.

19. The semiconductor device according to claim 18, wherein the at least one of the marks is formed at a position closer to the pixel region than to the circuit region in the first region.

20. The semiconductor device according to claim 18, wherein the at least one of the marks is formed at a position closer to the pixel region than to the circuit region in the second region.

21. The semiconductor device according to claim 18, wherein the at least one of the marks includes a plurality of marks, and
the plurality of marks is arrayed along an outer periphery of the pixel region in the first region.

22. The semiconductor device according to claim 18, wherein the at least one of the marks includes a plurality of marks, and
the plurality of marks is arrayed along an outer periphery of the pixel region in the second region.

23. The semiconductor device according to claim 17, wherein the at least one of the marks includes a plurality of marks,
a portion of the plurality of marks is formed in the intermediate region, and
the other portion of the plurality of marks is formed in a scribe region that is a peripheral portion of the substrate.

24. The semiconductor device according to claim 23, wherein the other portion of the plurality of marks is formed in an inner peripheral portion of the scribe region.

25. An electronic apparatus comprising the semiconductor device according to claim 1.

26. An electronic apparatus comprising the semiconductor device according to claim 17.
